(19) United States
(12) Patent Application Publication
(10) Pub. No.: US 2023/0178583 A1
(43) Pub. Date: Jun. 8, 2023

(54) DISPLAY DEVICE AND METHOD OF FABRICATING THE SAME

(71) Applicant: Samsung Display Co., LTD., Yongin-si (KR)

(72) Inventors: Jeong Hyun LEE, Asan-si (KR); Jin Woo LEE, Suwon-si (KR); Zu Seok OH, Cheonan-si (KR); Kyung Ah CHOI, Asan-si (KR)

(21) Appl. No.: 18/056,628

(22) Filed: Nov. 17, 2022

(30) Foreign Application Priority Data
Dec. 3, 2021 (KR) 10-2021-0171757

(51) Int. Cl. H01L 27/15; G02B 5/02; H01L 33/00; H01L 33/24; H01L 33/44; H01L 33/50

(52) U.S. Cl. CPC H01L 27/156; G02B 5/0242; G02B 5/0278; H01L 33/005; H01L 33/24; H01L 33/44; H01L 33/50; H01L 2933/0091; H01L 2933/0041

(57) ABSTRACT

A display device includes a pixel including a first sub-pixel configured to emit a first color light and a second sub-pixel configured to emit a second color light that is different from the first color light. The display includes a substrate including an emission area and a non-emission area surrounding the emission area, a bank in the non-emission area on the substrate, a first electrode and a second electrode in each of the first sub-pixel and the second sub-pixel on the substrate, a light emitting element between the first electrode and the second electrode in the emission area, a wavelength conversion layer on the light emitting element in the emission area, and a protection layer on the substrate. The protection layer includes a first area in the emission area and located between the wavelength conversion layer and the light emitting element, and a second area in the non-emission area.

### CROSS-REFERENCE TO RELATED APPLICATION

This application claims priority to and the benefit of Korean Patent Application No. 10-2021-0171757 filed on Dec. 3, 2021, in the Korean Intellectual Property Office (KIPO), the entire content of which is incorporated herein by reference.

### BACKGROUND

### 1. Field

Aspects of embodiments of the present disclosure relate to a display device and a method of fabricating the same.

### 2. Description of the Related Art

The importance of display devices has steadily increased with the development of multimedia technology. In response thereto, various types of display devices such as an organic light emitting diode (OLED) display, a liquid crystal display (LCD) and the like have been used.

A display device is a device for displaying an image, and includes a display panel, such as a light emitting display panel or a liquid crystal display panel. The display panel may include a light emitting element, and the light emitting element may be a light emitting diode (LED). The light emitting diode includes an organic light emitting diode (OLED) that uses an organic material as a light emitting material, and an inorganic light emitting diode that uses an inorganic material as a light emitting material.

### SUMMARY

Aspects of embodiments of the present disclosure include a display device having an improved display quality and capable of preventing a wavelength conversion layer from being damaged by light energy emitted from a light emitting element or thermal energy generated from the light emitting element by disposing a protection layer between the light emitting element and the wavelength conversion layer.

Aspects of embodiments of the present disclosure include a method of fabricating the display device capable of forming the protection layer of a first emission area of a first sub-pixel and the protection layer of a second emission area of a second sub-pixel at the same time by forming the passage spatially connecting the first emission area to the second emission area between the first emission area and the second emission area and spraying an ink forming the protection layer only to the first emission area in an inkjet process of forming the protection layer. Accordingly, it is possible to provide the method of fabricating a display device in which an inkjet process time for forming the protection layer is reduced.

Aspects of embodiments of the present disclosure include a method of fabricating the display device in which a passage is formed without an additional process to reduce an inkjet process time without adding the fabrication process of a display device by forming a pattern for forming the passage on the same layer as an alignment line used in an alignment process of light emitting elements and made of the same material as the pattern and then removing the pattern and the alignment line together in a process of disconnecting the alignment line.

However, embodiments of the present disclosure are not limited to those set forth herein. The above and other embodiments of the present disclosure will become more apparent to one of ordinary skill in the art to which the present disclosure pertains by referencing the detailed description of the present disclosure given below.

According to one or more embodiments of the present disclosure, a display device includes a pixel including a first sub-pixel configured to emit a first color light and a second sub-pixel configured to emit a second color light different from the first color light. The display includes a substrate including an emission area and a non-emission area surrounding the emission area, a bank in the non-emission area on the substrate, a first electrode and a second electrode in each of the first sub-pixel and the second sub-pixel on the substrate, a light emitting element between the first electrode and the second electrode in the emission area, a wavelength conversion layer on the light emitting element in the emission area, and a protection layer on the substrate. The protection layer includes a first area in the emission area and located between the wavelength conversion layer and the light emitting element, and a second area in the non-emission area and located between the substrate and the bank.

According to one or more embodiments, the emission area may include a first emission area of the first sub-pixel and a second emission area of the second sub-pixel. The non-emission area may include a first non-emission area between the first emission area and the second emission area. The first area of the protection layer may include a first portion in the first emission area and a second portion in the second emission area. The second area of the protection layer may be in the first non-emission area.

According to one or more embodiments, the second area of the protection layer may be located between the first portion of the protection layer and the second portion of the protection layer. The second area of the protection layer may connect the first portion of the protection layer to the second portion of the protection layer.

According to one or more embodiments, the wavelength conversion layer may include a first wavelength conversion pattern in the first emission area and a second wavelength conversion pattern in the second emission area.

According to one or more embodiments, the pixel may further include a third sub-pixel configured to emit a third color light that is different from the first color light and the second color light. The emission area may further include a third emission area of the third sub-pixel. The non-emission area may further include a second non-emission area between the third emission area and the second emission area. The protection layer may not be located in the second non-emission area.

According to one or more embodiments, the display device may further include a light transmission pattern in the third emission area. The light transmission pattern may include a same material as that of the protection layer.

According to one or more embodiments, the first area of the protection layer and the second area of the protection layer may be integrated.

According to one or more embodiments, the protection layer may include a base resin and scatterers dispersed in the base resin. The scatterer may have a refractive index different from that of the base resin.

According to one or more embodiments of the present disclosure, a display device includes a substrate including an emission area and a non-emission area, the emission area including a first emission area and a second emission area, and the non-emission area including a first non-emission area between the first emission area and the second emission area, a first electrode and a second electrode located in each of the first emission area and the second emission area and spaced from each other on the substrate, a plurality of light emitting elements in each of the first emission area and the second emission area and located between the first electrode and the second electrode, a bank in the non-emission area and including an opening exposing each of the first emission area and the second emission area, a first wavelength conversion pattern on the light emitting element in the first emission area, a second wavelength conversion pattern on the light emitting element in the second emission area, a first protection layer between the light emitting element and the first wavelength conversion pattern in the first emission area, a second protection layer between the light emitting element and the second wavelength conversion pattern in the second emission area, and a third protection layer spatially connecting the first emission area to the second emission area and in a passage located in the first non-emission area.

According to one or more embodiments, the first protection layer, the second protection layer, and the third protection layer may include a same material.

According to one or more embodiments, the first protection layer, the second protection layer, and the third protection layer may be integrated.

According to one or more embodiments, each of the first protection layer, the second protection layer and the third protection layer may include a base resin and scatterers dispersed in the base resin. The scatterer may have a refractive index different from that of the base resin.

According to embodiments, the third protection layer may connect the first protection layer to the second protection layer.

According to one or more embodiments, the passage includes a plurality of passages in the first non-emission area.

According to one or more embodiments, the passage may be defined as a separation space between the substrate and the bank.

According to one or more embodiments, the third protection layer may overlap a bottom surface of the bank. The first protection layer and the second protection layer may not overlap the bottom surface of the bank.

According to one or more embodiments of the present disclosure, a method of fabricating a display device including a first sub-pixel configured to emit a first color light and a second sub-pixel configured to emit a second color light, the method includes preparing a substrate including an emission area and a non-emission area, the emission area including a first emission area of the first sub-pixel and a second emission area of the second sub-pixel, and the non-emission area surrounding the emission area and including a first non-emission area between the first emission area and the second emission area, forming a first pattern in the first non-emission area, forming a bank in the non-emission area, and removing the first pattern. The bank in the first non-emission area may be configured to expose both ends of the first pattern.

According to one or more embodiments, the removing of the first pattern, a passage that is a separation space between the substrate and the bank may be formed.

According to one or more embodiments, the passage spatially may connect the first emission area to the second emission area.

According to one or more embodiments, the method may further include forming a protection layer in each of the first emission area and the second emission area. The forming of the protection layer in each of the first emission area and the second emission area may include spraying an ink onto the first emission area.

According to one or more embodiments, the ink sprayed onto the first emission area may flow to the second emission area through the passage.

According to the aforementioned and other embodiments of the present disclosure, the display device may have an improved display quality and prevent a wavelength conversion layer from being damaged by light energy emitted from a light emitting element or thermal energy generated from the light emitting element by disposing a protection layer between the light emitting element and the wavelength conversion layer.

According to the aforementioned and other embodiments of the present disclosure, it is possible to form the protection layer of the first emission area of the first sub-pixel and the protection layer of the second emission area of the second sub-pixel at the same time by forming the passage spatially connecting the first emission area to the second emission area between the first emission area and the second emission area and spraying an ink forming the protection layer only to the first emission area in the inkjet process of forming the protection layer. Accordingly, it is possible to provide the method of fabricating a display device in which the inkjet process time for forming the protection layer is reduced.

According to the aforementioned and other embodiments of the present disclosure, it is possible to form the passage connecting the first emission area to the second emission area without an additional process by forming the pattern for forming the passage on the same layer as the alignment line used in the alignment process of light emitting elements and made of the same material as the pattern and then removing the pattern and the alignment line together in the process of disconnecting the alignment line. Accordingly, the inkjet process time may be reduced without adding the fabrication process of the display device by forming the passage spatially connecting the first emission area to the second emission area without an additional process.

### BRIEF DESCRIPTION OF THE DRAWINGS

The above and other aspects and features of embodiments according to the present disclosure will become more apparent by describing aspects of some embodiments thereof with reference to the attached drawings, in which:

FIG. 1 is a plan view of a display device according to one or more embodiments;

FIG. 2 is a schematic layout view showing a pixel arrangement of a display device according to one or more embodiments;

FIG. 3 is a layout view of emission areas and non-emission areas of one pixel of a display device according to one or more embodiments;

FIG. 4 is a schematic plan layout view of one pixel of a display device according to one or more embodiments;

FIG. 5 is a plan view illustrating relative arrangement between a first bank, a second bank, and a passage included in a display device according to one or more embodiments;

FIG. 6 is a cross-sectional view illustrating an example of a display device taken along the line I-I′ of FIGS. 4 and 5;

FIG. 7 is a cross-sectional view illustrating an example of a display device taken along the line II-II′ of FIGS. 4 and 5;

FIG. 8 is a partial cross-sectional view illustrating an example of a display device taken along the line III-III′ of FIG. 4;

FIG. 9 is a schematic perspective cutaway view of a light emitting element according to one or more embodiments;

FIG. 10 is an enlarged cross-sectional view illustrating an example of area A of FIG. 8;

FIG. 11 is an enlarged cross-sectional view illustrating another example of area A of FIG. 8;

FIG. 12 is an enlarged cross-sectional view illustrating an example of a first emission area, a second emission area, and a first non-emission area, according to one or more embodiments;

FIG. 13 is a cross-sectional view illustrating an example taken along the line IV-IV′ of FIG. 5;

FIG. 14 is a cross-sectional view illustrating an example taken along the line V-V′ of FIG. 5;

FIGS. 15 to 56 are plan layout views and cross-sectional views illustrating individual process steps of a method of fabricating a display device according to one or more embodiments;

FIG. 57 is a cross-sectional view illustrating an example of a display device taken along the line I-I′ of FIGS. 4 and 5; and

FIG. 58 is an enlarged cross-sectional view illustrating another example of the first emission area, the second emission area, and the first non-emission area, according to one or more embodiments.

### DETAILED DESCRIPTION

Aspects of some embodiments of the present disclosure and methods of accomplishing the same may be understood more readily by reference to the detailed description of embodiments and the accompanying drawings. Hereinafter, aspects of some embodiments will be described in more detail with reference to the accompanying drawings. The described embodiments, however, may be embodied in various different forms, and should not be construed as being limited to only the illustrated embodiments herein. Rather, these embodiments are provided as examples so that this disclosure will be thorough and complete, and will fully convey the aspects of the present disclosure to those skilled in the art. Accordingly, processes, elements, and techniques that are not necessary to those having ordinary skill in the art for a complete understanding of the aspects of some embodiments of the present disclosure might not be described.

Unless otherwise noted, like reference numerals, characters, or combinations thereof denote like elements throughout the attached drawings and the written description, and thus, descriptions thereof will not be repeated. Further, parts not related to the description of some embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the particular illustrated shapes of regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of embodiments according to the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form in order to avoid unnecessarily obscuring various embodiments.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions such as “at least one of,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, YZ, and ZZ, or any variation thereof. Similarly, the expression such as “at least one of A and B” may include A, B, or A and B. As used herein, the term “and/or” includes any and all combinations of one or more of the associated listed items. For example, the expression such as “A and/or B” may include A, B, or A and B.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

The electronic or electric devices and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of some embodiments of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

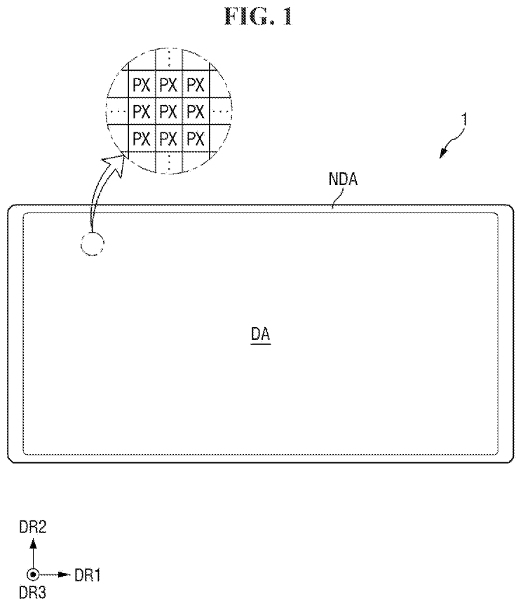

FIG. 1 is a plan view of a display device according to one embodiments.

Referring to FIG. 1, a display device 1 displays a moving image or a still image. The display device 1 may refer to any electronic device providing a display screen. Examples of the display device 1 may include a television, a laptop computer, a monitor, a billboard, an Internet-of-Things (IoT) device, a mobile phone, a smartphone, a tablet personal computer (PC), an electronic watch, a smart watch, a watch phone, a head-mounted display, a mobile communication terminal, an electronic notebook, an electronic book, a portable multimedia player (PMP), a navigation device, a game machine, a digital camera, a camcorder and the like, which provide a display screen.

The display device 1 includes a display panel that provides a display screen. Examples of the display panel may include an inorganic light emitting diode display panel, an organic light emitting display panel, a quantum dot light emitting display panel, a plasma display panel and a field emission display panel. In the following description, a case where an inorganic light emitting diode display panel is applied as a display panel will be exemplified, but the present disclosure is not limited thereto, and other display panels may be applied within the same scope of technical spirit.

Hereinafter, a first direction DR1, a second direction DR2, and a third direction DR3 are defined in drawings of an embodiment describing the display device 1. The first direction DR1 and the second direction DR2 may be directions perpendicular to each other in one plane. The third direction DR3 may be a direction perpendicular to a plane on which the first direction DR1 and the second direction DR2 are located. The third direction DR3 is perpendicular to each of the first direction DR1 and the second direction DR2. In the embodiment describing the display device 1, the third direction DR3 indicates a thickness direction of the display device 1.

The display device 1 may have a rectangular shape including long and short sides such that the side in the first direction DR1 is longer than the side in the second direction DR2 in a plan view. A corner portion where the long side and the short side of the display device 1 meet may have a right angle in a plan view. However, the present disclosure is not limited thereto, and the corner portion may be rounded to have a curved shape. The planar shape of the display device 1 is not limited to the illustrated example, and may be other shapes such as a square shape, a quadrilateral shape with rounded corners (e.g., vertices), other polygonal shapes and a circular shape.

A display surface of the display device 1 may be disposed on one side of the third direction DR3 that is the thickness direction. In embodiments describing the display device 1, unless otherwise noted, the term “upward” refers to one side of the third direction DR3, which is the display direction, and the term “top surface” refers to a surface toward the one side of the third direction DR3. Further, the term “downward” refers to the other side of the third direction DR3, which is an opposite direction to the display direction, and the term “bottom surface” refers to a surface toward the other side of the third direction DR3. Furthermore, “left”, “right”, “upper” and “lower” indicate directions when the display device 1 is viewed from above. For example, “right side” indicates one side of the first direction DR1, “left side” indicates the other side of the first direction DR1, “upper side” indicates one side of the second direction DR2, and “lower side” indicates the other side of the second direction DR2.

The display device 1 may include a display area DA and a non-display area NDA. The display area DA is an area where an image can be displayed, and the non-display area NDA is an area where no image is displayed.

The shape of the display area DA may follow the shape of the display device 1. For example, the shape of the display area DA may have a rectangular shape similar to the overall shape of the display device 1 in a plan view. The display area DA may substantially occupy the center (e.g., a central region) of the display device 1.

The display area DA may include a plurality of pixels PX. The plurality of pixels PX may be arranged in a matrix. For example, the plurality of pixels may be arranged along rows and columns of a matrix. The shape of each pixel PX may be a rectangular or square shape in a plan view. However, the shape of each pixel PX is not limited thereto, and may be a rhombus shape in which each side is inclined with respect to one direction. The pixels PX may be alternately disposed in a stripe type or a PENTILE® arrangement structure, but the present disclosure is not limited thereto. This PENTILE® arrangement structure may be referred to as an RGBG matrix structure (e.g., a PENTILE® matrix structure or an RGBG structure (e.g., a PENTILE® structure)). PENTILE® is a registered trademark of Samsung Display Co., Ltd., Republic of Korea.

The non-display area NDA may be disposed around the display area DA along the edge or periphery of the display area DA. The non-display area NDA may completely or partially surround the display area DA. In one or more embodiments, the display area DA may have a rectangular shape, and the non-display area NDA may be disposed adjacent to four sides of the display area DA. The non-display area NDA may form a bezel of the display device 1. In the non-display area NDA, wires and circuit drivers belonging to the display device 1, or pad portions on which an external device is mounted may be disposed.

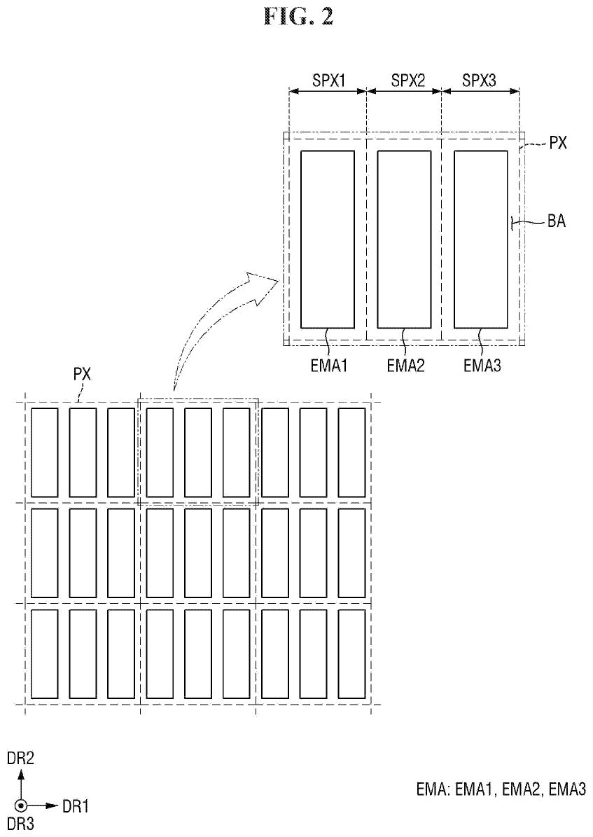

FIG. 2 is a schematic layout view showing a pixel arrangement of a display device according to one or more embodiments.

Referring to FIG. 2, the display area DA of the display device 1 may include a plurality of pixels PX. The pixel PX represents the smallest unit of repetition for display. In order to achieve full-color display, each pixel PX may include a plurality of sub-pixels SPX emitting different colors. For example, each pixel PX may include a first sub-pixel SPX1 responsible for light emission of a first color, a second sub-pixel SPX2 responsible for light emission of a second color, and a third sub-pixel SPX3 responsible for light emission of a third color. For example, the first color may be red, the second color may be green, and the third color may be blue. On the other hand, although the drawing illustrates that one pixel PX includes three sub-pixels SPX, the present disclosure is not limited thereto. For example, one pixel PX may include a larger number of sub-pixels SPX.

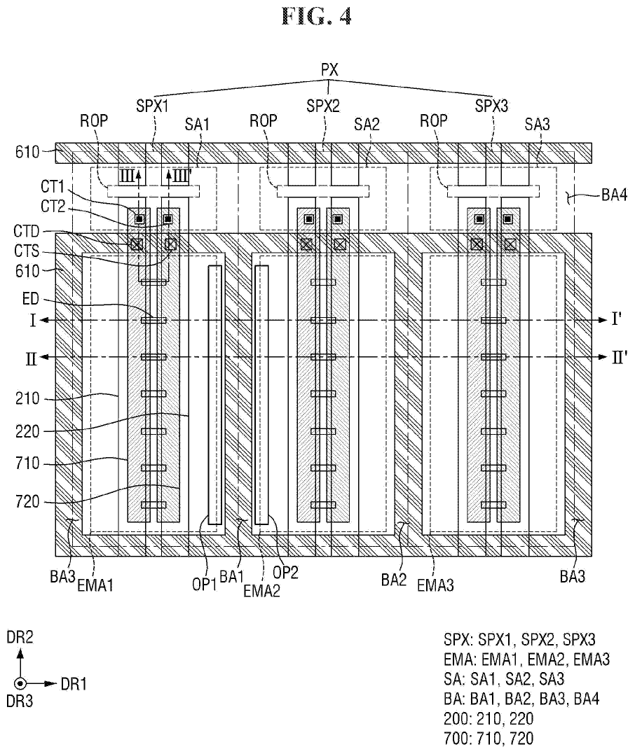

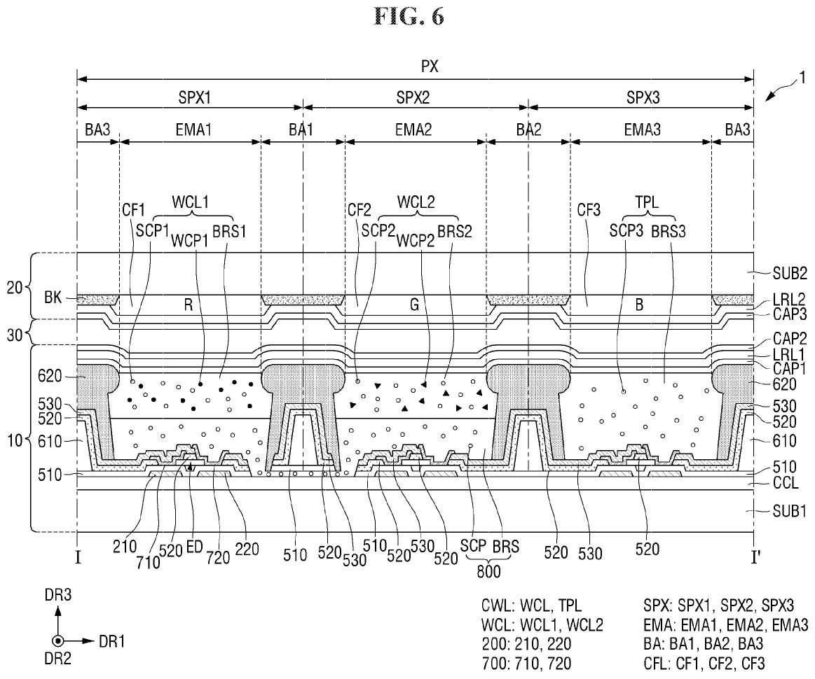

Each sub-pixel SPX may include an emission area EMA and a non-emission area BA. The emission area EMA may be an area where a light emitting element ED (see FIG. 4) is disposed, and light emitted from the light emitting element ED is provided to the outside while being transmitted through a wavelength control layer CWL (see FIG. 6) or a color filter layer CFL (see FIG. 6), and the non-emission area BA may be an area through which the light emitted from the light emitting elements ED does not transmit.

The emission area EMA may include a first emission area EMA1, a second emission area EMA2, and a third emission area EMA3. The first emission area EMA1 may be the emission area EMA of the first sub-pixel SPX1, the second emission area EMA2 may be the emission area EMA of the second sub-pixel SPX2, and the third emission area EMA3 may be the emission area EMA of the third sub-pixel SPX3. The first emission area EMA1 may emit light of the first color, the second emission area EMA2 may emit light of the second color, and the third emission area EMA3 may emit light of the third color. For example, the first color may be red, the second color may be green, and the third color may be blue. The first to third emission areas EMA1, EMA2, and EMA3 may be arranged in order repetitively along the first direction DR1 in the display area DA.

The non-emission area BA may be positioned around the emission area EMA. For example, the non-emission area BA may be disposed to surround the first emission area EMA1, the second emission area EMA2, and the third emission area EMA3. The first emission area EMA1, the second emission area EMA2, and the third emission area EMA3 may be divided (e.g., be separated) by the non-emission area BA.

The non-emission area BA of one sub-pixel SPX is in contact with the non-emission area BA of the neighboring sub-pixel SPX (regardless of whether or not it is the sub-pixel SPX in the same pixel PX). The non-emission areas BA of the adjacent sub-pixels SXP may be integrated. Furthermore, the non-emission areas BA of all the sub-pixels SXP may be integrated, but the present disclosure is not limited thereto. The emission areas EMA of the adjacent sub-pixels SPX may be distinguished (e.g., be separated) by the non-emission area BA.

In one or more embodiments, the adjacent sub-pixels SPX may be interpreted as being in contact. Even in such a case, the boundary between the sub-pixels SPX may be placed in the non-emission area BA that is integrally connected, and thus may not be physically distinguished. The boundary between the sub-pixels SPX may be located at an intermediate point (or an intermediate point of the non-emission area BA in a width direction) of a space between the emission areas EMA of the adjacent sub-pixels SPX. The overall shape of the sub-pixel SPX may be similar to that of the emission area EMA of the corresponding sub-pixel SPX, but the present disclosure is not limited thereto.

The pixels PX including the plurality of sub-pixels SPX may be alternately arranged in a matrix. The shape and arrangement of the sub-pixels SPX may be the same for each pixel PX, but are not limited thereto. The overall shape of each pixel PX including the plurality of sub-pixels SPX may be a substantially square shape. However, the present disclosure is not limited thereto, and the shape of each pixel PX may be variously modified, such as a rhombus or a rectangle.

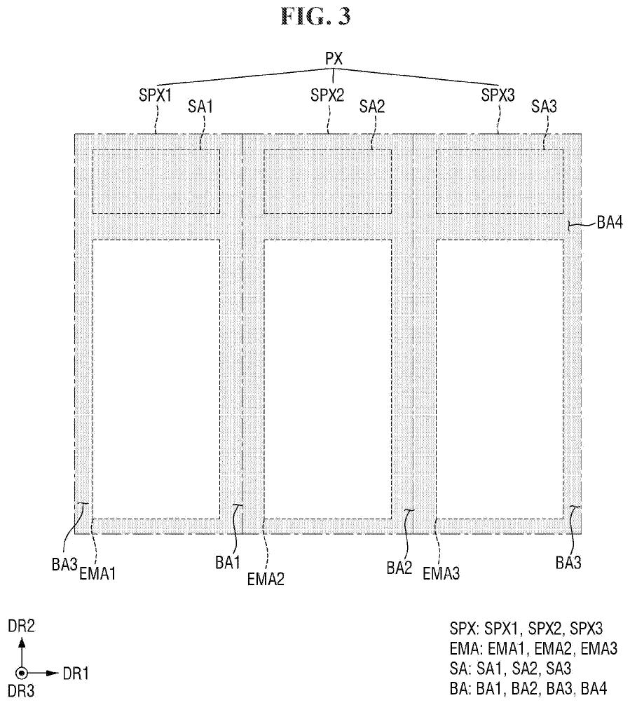

FIG. 3 is a layout view of emission areas and non-emission areas of one pixel of a display device according to one or more embodiments.

Referring to FIG. 3, the non-emission area BA may include a first non-emission area BA1, a second non-emission area BA2, a third non-emission area BA3, and a fourth non-emission area BA4.

The first non-emission area BA1 may be positioned between the first emission area EMA1 and the second emission area EMA2 along the first direction DR1, the second non-emission area BA2 may be positioned between the second emission area EMA2 and the third emission area EMA3 along the first direction DR1, and the third emission area BA3 may be positioned between the first emission area EMA1 and the third emission area EMA3 along the first direction DR1. The first to third non-emission areas BA1, BA2, and BA3 may prevent colors of lights emitted from the first to third emission areas EMA1, EMA2, and EMA3 from being mixed.

The fourth non-emission area BA4 may be positioned on one side or the other side of the first to third emission areas EMA1, EMA2, and EMA3 and the first to third non-emission areas BA1, BA2, and BA3 in the second direction DR2. For example, the fourth non-emission area BA4 may be positioned above the first to third emission areas EMA1, EMA2, and EMA3 and the first to third non-emission areas BA1, BA2, and BA3 in a plan view. However, the present disclosure is not limited thereto, and the fourth non-emission area BA4 may be positioned under the first to third emission areas EMA1, EMA2, and EMA3 and the first to third non-emission areas BA1, BA2, and BA3.

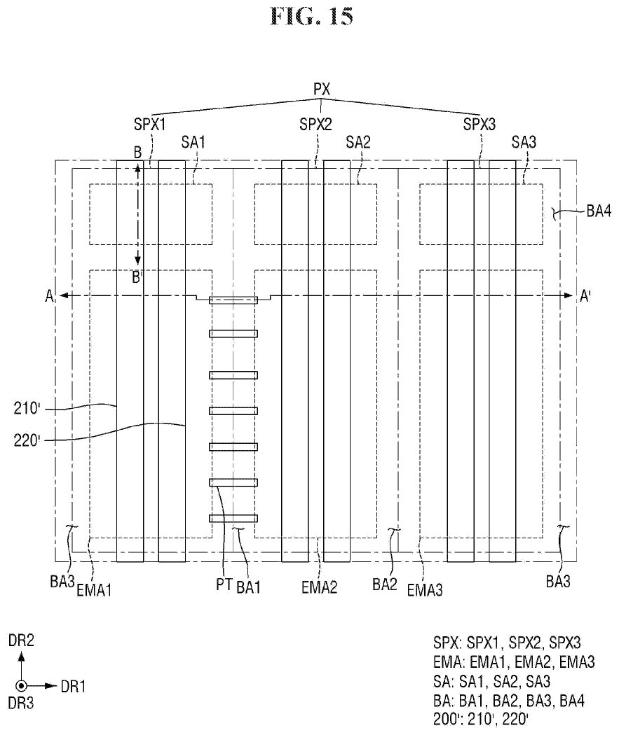

A sub-region SA of each sub-pixel SPX may be disposed in the fourth non-emission area BA4. The sub-region SA may be an area where the light emitting element ED is not disposed and an alignment line 200′ (see FIG. 15) used in the alignment process of the light emitting elements ED during the fabrication process of the display device 1 is separated. This will be described in detail later.

The sub-region SA may include a first sub-region SA1, a second sub-region SA2, and a third sub-region SA3. The first sub-region SA1 may be the sub-region SA of the first sub-pixel SPX1, the second sub-region SA2 may be the sub-region SA of the second sub-pixel SPX2, and the third sub-region SA3 may be the sub-region SA of the third sub-pixel SPX3.

The sub-region SA may be disposed above (or on one side in the second direction DR2) the emission area EMA. For example, the first sub-region SA1 may be disposed above the first emission area EMA1, the second sub-region SA2 may be disposed above the second emission area EMA2, and the third sub-region SA3 may be disposed above the third emission area EMA3. That is, the sub-region SA may be disposed between the emission areas EMA of the sub-pixels SPX adjacent in the second direction DR2.

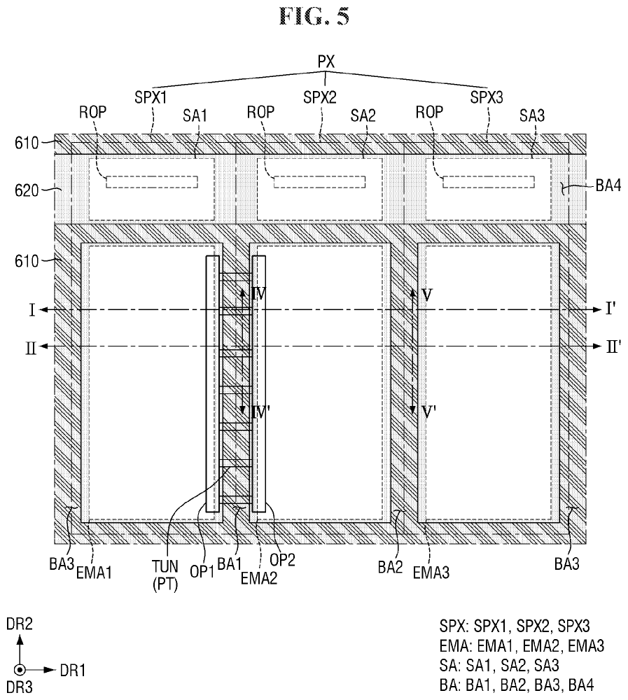

FIG. 4 is a schematic plan layout view of one pixel of a display device according to one or more embodiments. FIG. 5 is a plan view illustrating relative arrangement between a first bank, a second bank, and a passage included in a display device according to one or more embodiments.

Referring to FIGS. 4 and 5, the display device 1 may include an electrode layer 200, a contact electrode 700, a first bank 610, a plurality of light emitting elements ED, and a second bank 620. The electrode layer 200, the contact electrode 700, and the plurality of light emitting elements ED may be disposed in each sub-pixel SPX, and the first bank 610 and the second bank 620 may be disposed at the boundaries of the sub-pixels SPX.

The electrode layer 200 may be disposed across the emission area EMA and the sub-region SA of each sub-pixel SPX. For example, the electrode layer 200 may be disposed across the first emission area EMA1 and the first sub-region SA1 of the first sub-pixel SPX1, may be disposed across the second emission area EMA2 and the second sub-region SA2 of the second sub-pixel SPX2, and may be disposed across the third emission area EMA3 and the third sub-region SA3 of the third sub-pixel SPX3.

The electrode layers 200 may extend in the second direction DR2 and may include a plurality of electrodes spaced from each other in the first direction DR1. For example, the electrode layer 200 may include a first electrode 210 and a second electrode 220.

The first electrode 210 and the second electrode 220 may be disposed across the emission area EMA and the sub-region SA of each sub-pixel SPX, and may be spaced from the first electrode 210 and the second electrode 220 of the sub-pixel SA adjacent thereto in the second direction DR2 at a separation portion ROP positioned in the sub-region SA.

For example, the first electrode 210 and the second electrode 220 included in the first sub-pixel SPX1 may extend in the second direction DR2 in a plan view, and may be respectively spaced from the first electrode 210 and the second electrode 220 included in the first sub-pixel SPX1 adjacent thereto in the second direction DR2 at the separation portion ROP positioned in the first sub-region SA1. Similarly, the first electrode 210 and the second electrode 220 included in the second sub-pixel SPX2 may extend in the second direction DR2 in a plan view, and may be respectively spaced from the first electrode 210 and the second electrode 220 included in the second sub-pixel SPX2 adjacent thereto in the second direction DR2 at the separation portion ROP positioned in the second sub-region SA2. The first electrode 210 and the second electrode 220 included in the third sub-pixel SPX3 may extend in the second direction DR2 in a plan view, and may be respectively spaced from the first electrode 210 and the second electrode 220 included in the third sub-pixel SPX3 adjacent thereto in the second direction DR2 at the separation portion ROP positioned in the third sub-region SA3.

The first electrodes 210 and the second electrodes 220 separated at the separation portion ROP of each sub-pixel SPX may be formed after the process of aligning the plurality of light emitting elements ED during the fabrication process of the display device 10. For example, in the process of aligning the plurality of light emitting elements ED during the fabrication process of the display device 10, an electric field may be generated using the alignment line 200′ (see FIG. 15) extending in the second direction DR2, and the plurality of light emitting elements ED may be aligned by a dielectrophoretic force induced by the electric field generated on the alignment line 200′ (see FIG. 15). After the process of forming the second bank 620 subsequent to the alignment process of the light emitting elements ED, the region of the alignment line 200′ overlapping the separation portion ROP may be removed together with a passage pattern PT (see FIG. 15). Accordingly, as shown in FIG. 4, the first electrodes 210 and the second electrodes 220 separated at the separation portion ROP of each sub-pixel SPX may be formed.

The first electrode 210 may be electrically connected to the circuit element layer through a first electrode contact hole CTD. The second electrode 220 may be electrically connected to the circuit element layer through a second electrode contact hole CTS.

Since the first electrode 210 is electrically connected to the circuit element layer through the first electrode contact hole CTD and the second electrode 220 is electrically connected to the circuit element layer through the second electrode contact hole CTS, the electrical signal applied to the circuit element layer may be transmitted to both ends of the light emitting element ED through the first electrode 210 and the second electrode 220. On the other hand, although it is illustrated in the drawing that the first and second electrode contact holes CTD and CTS are disposed to overlap the first bank 610 in the third direction DR3, the positions of the first and second electrode contact holes CTD and CTS are not limited thereto.

The first bank 610 may be disposed in the non-emission area BA. The first bank 610 may include the first to third non-emission areas BA1, BA2, and BA3, and may be disposed in a part of the fourth non-emission area BA4. The first bank 610 may be disposed to surround the first to third emission areas EMA1, EMA2, and EMA3 to partition the first to third emission areas EMA1, EMA2, and EMA3. Further, the first bank 610 may be further disposed between the emission area EMA and the sub-region SA to divide the emission area EMA and the sub-region SA.

The first bank 610 may be disposed to divide (e.g., to separate) the sub-region SA and the emission area EMA, and may guide ink in which the light emitting elements ED are dispersed to be stably sprayed to the emission area EMA without being sprayed to the sub-region SA in an inkjet printing process of aligning the plurality of light emitting elements ED during the fabrication process of the display device 1.

The plurality of light emitting elements ED may be disposed in the emission area EMA of each sub-pixel SPX. For example, the plurality of light emitting elements ED may be disposed in each of the first to third emission areas EMA1, EMA2 and EMA3 that are respectively the emission areas EMA of the first to third sub-pixels SPX1, SPX2, and SPX3. The plurality of light emitting elements ED may not be disposed in the sub-region SA. As described above, because the first bank 610 is disposed to partition the sub-regions SA of the sub-pixels SPX, the ink in which the plurality of light emitting elements ED are dispersed may be sprayed only to the emission area EMA and, thus, the plurality of light emitting elements ED may be disposed in the emission area EMA and may not be disposed in the sub-region SA.

The plurality of light emitting elements ED may be disposed between the first electrode 210 and the second electrode 220 in the emission area EMA. Each light emitting element ED may have a shape extending in one direction, and the extension direction of the light emitting element ED may be substantially perpendicular to the extension direction of the first electrode 210 and the second electrode 220. However, the present disclosure is not limited thereto, and the light emitting elements ED may be arranged to extend in a direction oblique to the extension direction of the first electrode 210 and the second electrode 220. The light emitting element ED may be disposed such that at least one of both ends is located on the first electrode 210 or the second electrode 220.

The plurality of light emitting elements ED may be spaced from each other. The plurality of light emitting elements ED may be disposed to be spaced from each other in the second direction DR2 between the first electrode 210 and the second electrode 220. The plurality of light emitting elements ED may be arranged in one column between the first electrode 210 and the second electrode 220, and distances between the light emitting elements ED that are adjacent to each other in the second direction DR2 may be different from each other (e.g., be random).

The contact electrode 700 may be disposed across the emission area EMA and the sub-region SA of each sub-pixel SPX. For example, the contact electrode 700 may be disposed across the first emission area EMA1 and the first sub-region SA1 of the first sub-pixel SPX1, may be disposed across the second emission area EMA2 and the second sub-region SA2 of the second sub-pixel SPX2, and may be disposed across the third emission area EMA3 and the third sub-region SA3 of the third sub-pixel SPX3.

The contact electrode 700 may extend in the second direction DR2 and may include a plurality of contact electrodes spaced from each other in the first direction DR1. For example, the contact electrode 700 may include a first contact electrode 710 and a second contact electrode 720.

The first contact electrode 710 may be disposed to overlap the first electrode 210 in the third direction DR3 in the emission area EMA and the sub-region SA of each sub-pixel SPX. The first contact electrode 710 may be disposed to overlap one ends of the plurality of light emitting elements ED in the emission area EMA of each sub-pixel SPX.

The first contact electrode 710 may be in contact with the first electrode 210 through a first contact portion CT1 in the sub-region SA of each sub-pixel SPX, and may be in contact with one ends of the light emitting elements ED in the emission area EMA of each sub-pixel SPX. Because the first contact electrode 710 is in contact with each of the first electrode 210 and one end of the light emitting element ED, the first contact electrode 710 may serve to electrically connect one end of the light emitting element ED to the first electrode 210. On the other hand, although it is illustrated in the drawing that the first contact electrode 710 is in contact with the first electrode 210 in the sub-region SA of each sub-pixel SPX, the present disclosure is not limited thereto. For example, the first contact electrode 710 may be in contact with the first electrode 210 in the emission area EMA of each sub-pixel SPX.

The second contact electrode 720 may be disposed to overlap the second electrode 220 in the third direction DR3 in the emission area EMA and the sub-region SA of each sub-pixel SPX. The second contact electrode 720 may be disposed to overlap the other ends of the plurality of light emitting elements ED in the emission area EMA of each sub-pixel SPX.

The second contact electrode 720 may be in contact with the second electrode 220 through a second contact portion CT2 in the sub-region SA of each sub-pixel SPX, and may be in contact with the other ends of the light emitting elements ED in the emission area EMA of each sub-pixel SPX. Because the second contact electrode 720 is in contact with each of the second electrode 220 and the other end of the light emitting element ED, the second contact electrode 720 may serve to electrically connect the second electrode 220 to the other end of the light emitting element ED. On the other hand, although it is illustrated in the drawing that the second contact electrode 720 is in contact with the second electrode 220 in the sub-region SA of each sub-pixel SPX, the present disclosure is not limited thereto. For example, the second contact electrode 720 may be in contact with the second electrode 220 in the emission area EMA of each sub-pixel SPX.

The first contact electrode 710 and the second contact electrode 720 disposed in the first sub-pixel SPX1 may be in contact with the first electrodes 210 and the second electrode 220 in the first sub-region SA1 disposed above the first emission area EMA1, respectively. Similarly, the first contact electrode 710 and the second contact electrode 720 disposed in the second sub-pixel SPX2 may be in contact with the first electrode 210 and the second electrode 220 in the second sub-region SA2 disposed above the second emission area EMA2, respectively. Similarly, the first contact electrode 710 and the second contact electrode 720 disposed in the third sub-pixel SPX3 may be in contact with the first electrode 210 and the second electrode 220 in the third sub-region SA3 disposed above the third emission area EMA3, respectively.

The first contact electrode 710 and the second contact electrode 720 may be spaced from each other in the first direction DR1. The gap between the first contact electrode 710 and the second contact electrode 720 may be smaller than the length in the extension direction of the light emitting element ED. Therefore, the first contact electrode 710 and the second contact electrode 720 may be spaced from each other in the first direction DR1, and may be in contact with both ends of the light emitting element ED.

The second bank 620 may be disposed in the non-emission area BA. The second bank 620 may be disposed in the first to fourth non-emission areas BA1, BA2, BA3, and BA4. The second bank 620 may be disposed to surround the sub-region SA and the emission area EMA to divide (e.g., to separate) the sub-region SA and the emission area EMA. Therefore, the second bank 620 may not overlap the sub-region SA and the emission area EMA in a plan view.

The width in the first direction DR1 of the second bank 620 disposed in the first to third non-emission areas BA1, BA2, and BA3 may be greater than the width in the first direction DR1 of the first bank 610 overlapping the second bank 620, but the present disclosure is not limited thereto. Accordingly, the second bank 620 disposed in the first to third non-emission areas BA1, BA2, and BA3 may completely cover the first bank 610.

The display device 1 according to one or more embodiments may include a passage TUN disposed in the first non-emission area BA1. The passage TUN may overlap the first bank 610 and the second bank 620 disposed in the first non-emission area BA1. The passage TUN may be disposed between the first emission area EMA1 of the first sub-pixel SPX1 responsible for light emission of a first color and the second emission area EMA2 of the second sub-pixel SPX2 responsible for light emission of a second color to spatially connect them.

The passage TUN may not be disposed in the second non-emission area BA2 and the third non-emission area BA3. The passage TUN may not overlap the first bank 610 and the second bank 620 disposed in the second non-emission area BA2 and the third non-emission area BA3. Accordingly, the second emission area EMA2 and the third emission area EMA3 may not be spatially connected to each other by a passage in the first bank 610 and the second bank 620, and the first emission area EMA1 and the third emission area EMA3 may not be spatially connected to each other by a passage in the first bank 610 and the second bank 620.

The passage TUN may have a planar shape extending in the first direction DR1. A plurality of passages TUN may be provided, and the plurality of passages TUN may be disposed to be spaced from each other along the second direction DR2.

The passage TUN may be disposed between the first emission area EMA1 and the second emission area EMA2 to spatially connect them, and may guide an ink forming a protection layer 800 (see FIG. 6) to flow to the second emission area EMA2 even when the ink is sprayed only to the first emission area EMA1 in the process of forming the protection layer 800 during the fabrication process of the display device 1. Accordingly, the ink forming the protection layer 800 sprayed only to the first emission area EMA1 is shared in the second emission area EMA2, so that the number of times of ejection (e.g., spraying) of the ink for forming the protection layer 800 is reduced, which may shorten the fabrication process time of the display device 1.

Openings may be positioned at both ends of the passage TUN. For example, a first opening OP1 may be positioned at the left end of the passage TUN, and a second opening OP2 may be positioned at the right end of the passage TUN. The first opening OP1 and the second opening OP2 may be openings exposing both ends of a passage pattern PT disposed to form the passage TUN during the fabrication process of the display device 1 to be described later. Both ends of the passage pattern PT are removed by a chemical material for removing the passage pattern PT and connected to the first and second openings OP1 and OP2, thereby forming the passage TUN.

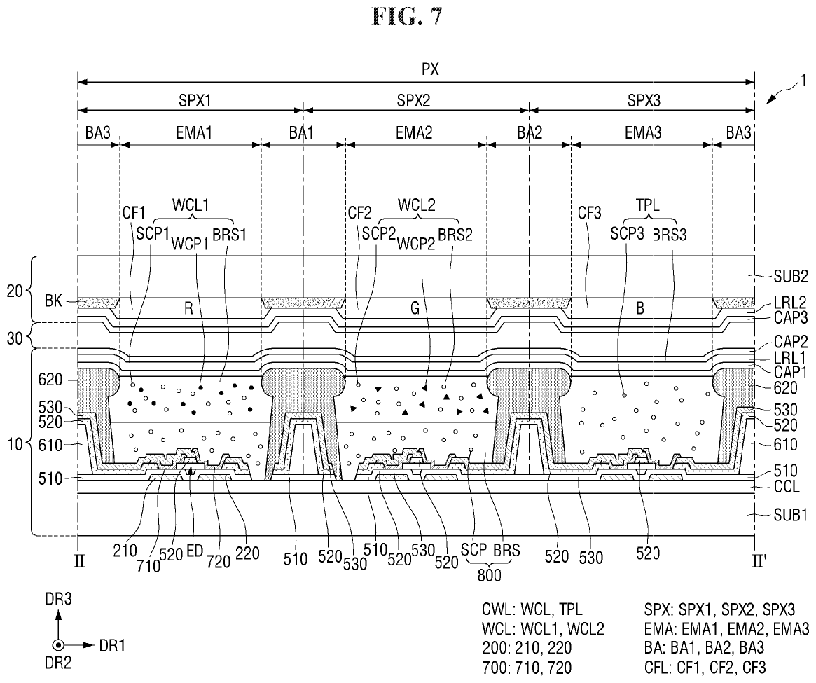

FIG. 6 is a cross-sectional view illustrating an example of a display device taken along the line I-I′ of FIGS. 4 and 5. FIG. 7 is a cross-sectional view illustrating an example of a display device taken along the line II-II′ of FIGS. 4 and 5.

Referring to FIGS. 4 to 7, the display device 1 may include a first display substrate 10 and a second display substrate 20 facing (e.g., opposing) the first display substrate 10. The display device 1 may include a filling layer 30 filling the space between the first display substrate 10 and the second display substrate 20.

The first display substrate 10 may include elements and circuits for displaying an image. For example, the first display substrate 10 may include a pixel circuit such as a switching element or the like, the first bank 610 or the second bank 620 defining the emission area and the non-emission area of the display area DA, a self-light emitting element, the protection layer 800, and the wavelength control layer CWL.

Examples of the self-light emitting element may include at least one of an organic light emitting diode, a quantum dot light emitting diode, an inorganic micro light emitting diode (e.g., micro LED), or an inorganic nano light emitting diode (e.g., nano LED). Hereinafter, a case where the self-light emitting element is an inorganic diode will be described as an example.

The first display substrate 10 may include a first substrate SUB1, a circuit element layer CCL disposed on the first substrate SUB1, a light emitting element layer disposed on the circuit element layer CCL, and the protection layer 800 and the wavelength control layer CWL disposed on the light emitting element layer.

The first substrate SUB1 may be a base substrate or a base member, and may be made of an insulating material such as a polymer resin. The first substrate SUB1 may be made of an insulating material such as glass, quartz, or polymer resin. The first substrate SUB1 may be a rigid substrate, but may also be a flexible substrate that can be bent, folded or rolled.

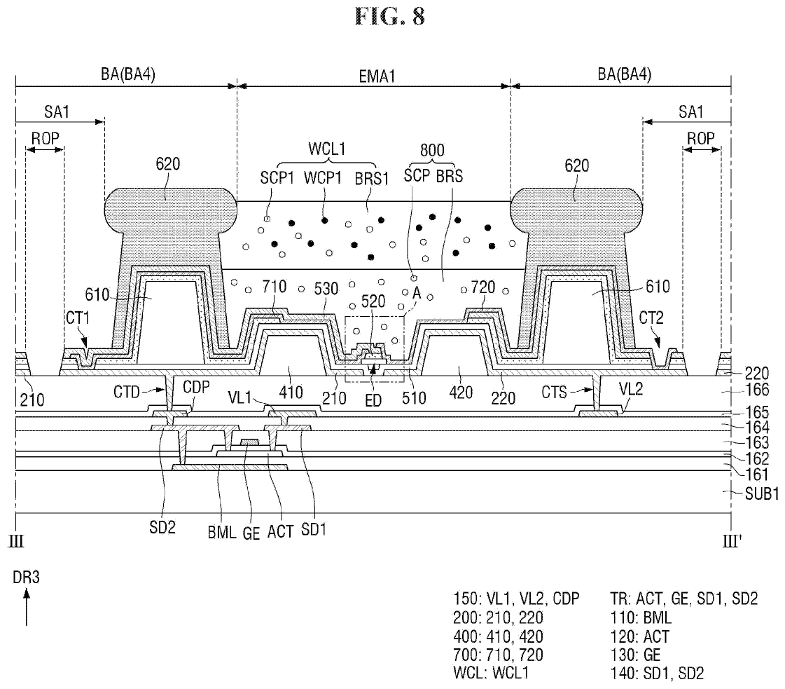

The circuit element layer CCL may be disposed on the first substrate SUB1. The circuit element layer CCL may be disposed on one surface of the first substrate SUB1 to drive a plurality of pixels PX or a plurality of sub-pixels SPX. The circuit element layer CCL may include at least one transistor and the like to drive the light emitting element layer. The circuit element layer CCL will be described in detail later with reference to FIG. 8.

The light emitting element layer may be disposed on the circuit element layer CCL. The light emitting element layer may include pixels including a first electrode, a light emitting layer, and a second electrode. In one or more embodiments, the light emitting layer may include an inorganic light emitting diode. However, the present disclosure is not limited thereto and in one or more embodiments, the light emitting layer may include an organic light emitting diode.

The light emitting element layer may include the electrode layer 200, a first insulating layer 510, the first bank 610, the plurality of light emitting elements ED, a second insulating layer 520, and the contact electrode 700. The light emitting element layer may further include a third insulating layer 530.

The electrode layer 200 may be disposed on the circuit element layer CCL. The first electrode 210 and the second electrode 220 of the electrode layer 200 may be spaced from each other on one surface of the circuit element layer CCL.

The first insulating layer 510 may be disposed on one surface of the circuit element layer CCL on which the electrode layer 200 is formed. The first insulating layer 510 may be disposed on the first electrode 210 and the second electrode 220, and may cover the first electrode 210 and the second electrode 220. The first insulating layer 510 may insulate the first electrode 210 and the second electrode 220 from each other.

In one or more embodiments, the first insulating layer 510 may include an opening forming the first opening OP1 (see FIGS. 4 and 5) exposing one surface of the circuit element layer CCL in the boundary region between the first emission area EMA1 and the first non-emission area BA1. The first insulating layer 510 may further include an opening forming the second opening OP2 (see FIGS. 4 and 5) exposing one surface of the circuit element layer CCL in the boundary region between the second emission area EMA2 and the first non-emission area BA1.

The first insulating layer 510 may completely cover one surface of the circuit element layer CCL in the boundary region between the second emission area EMA2 and the second non-emission area BA2 and in the boundary region between the third emission area EMA3 and the second non-emission area BA2. Similarly, the first insulating layer 510 may completely cover one surface of the circuit element layer CCL in the boundary region between the third emission area EMA3 and the third non-emission area BA3 (e.g., the right side of the third emission area EMA3 in FIG. 6) and in the boundary region between the first emission area EMA1 and the third non-emission area BA3 (e.g., the left side of the first emission area EMA1 in FIG. 6). That is, the first insulating layer 510 may substantially cover the first to third emission areas EMA1, EMA2, and EMA3 and the first to third non-emission areas BA1, BA2, and BA3, and may include an opening exposing the right side and the left side of at least the first non-emission area BA1 in the boundary region of the first sub-pixel SPX1 and the second sub-pixel SPX2.

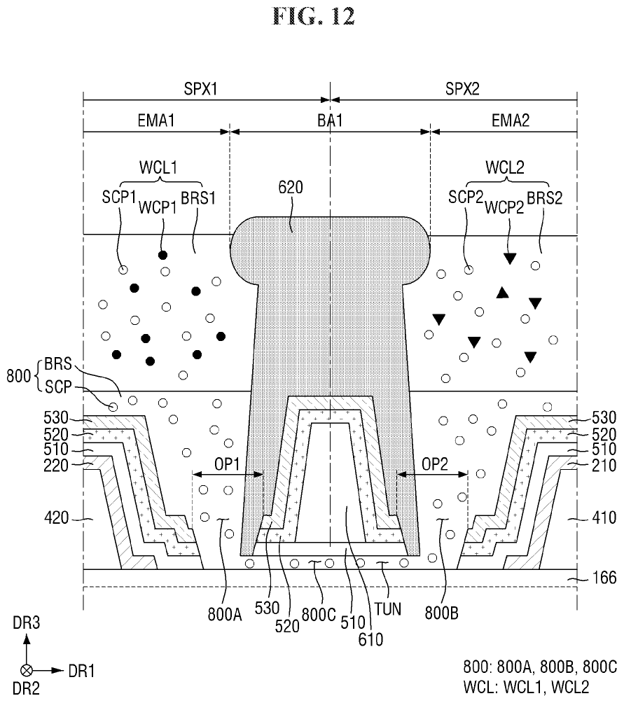

In the region where the passage TUN is formed, the first insulating layer 510 may be spaced from one surface of the circuit element layer CCL. For example, as shown in FIG. 6, in the first insulating layer 510 overlapping the passage TUN in the first non-emission area BA1, the bottom surface of the first insulating layer 510 may face one surface of the circuit element layer CCL while being spaced therefrom. Because the bottom surface of the first insulating layer 510 faces one surface of the circuit element layer CCL while being spaced therefrom in the first non-emission area BA1, the region where the first insulating layer 510 and one surface of the circuit element layer CCL face each other while being spaced from each other may form the passage TUN (see FIG. 12).

In the region where the passage TUN is not formed, the first insulating layer 510 may be directly disposed on one surface of the circuit element layer CCL. For example, as shown in FIG. 7, in the first insulating layer 510 that does not overlap the passage TUN in the first non-emission area BA1, the bottom surface of the first insulating layer 510 may be in direct contact with one surface of the circuit element layer CCL. In addition, as shown in FIGS. 6 and 7, in the second non-emission area BA2 and the third non-emission area BA3 where the passage TUN is not formed, the bottom surface of the first insulating layer 510 may be disposed to be in direct contact with one surface of the circuit element layer CCL.

The first bank 610 may be disposed on the first insulating layer 510. The first bank 610 may be disposed in the non-emission area BA surrounding the first to third emission areas EMA1, EMA2, and EMA3. The first bank 610 may overlap the first to third non-emission areas BA1, BA2, and BA3.

The first bank 610 may include an opening exposing the plurality of light emitting elements ED disposed in each of the first to third emission areas EMA1, EMA2, and EMA3. The opening included in the first bank 610 may partially expose the first electrode 210 and the second electrode 220 disposed in the first to third emission areas EMA1, EMA2, and EMA3.

The first bank 610 may be disposed to divide (e.g., to separate) the first to third emission areas EMA1, EMA2, and EMA3 and prevent the ink in which the plurality of light emitting elements ED are dispersed from being mixed to the emission area EMA of the adjacent sub-pixel SPX in the inkjet process of aligning the plurality of light emitting elements ED during the fabrication process of the display device 1. Accordingly, the first bank 610 may serve to make the number of light emitting elements ED aligned in the emission area EMA of each sub-pixel SPX uniform.

The plurality of light emitting elements ED may be disposed on the first insulating layer 510 between the first electrode 210 and the second electrode 220. The light emitting element ED may be disposed such that at least one of both ends is placed on the first electrode 210 or the second electrode 220.

The plurality of light emitting elements ED may be provided in each of the sub-pixels SPX1, SPX2, and SPX3. The plurality of light emitting elements ED may be disposed in each of the emission areas EMA1, EMA2, and EMA3 of the first to third sub-pixels SPX1, SPX2, and SPX3. The plurality of light emitting elements ED may be disposed between the first electrode 210 and the second electrode 220 exposed by the opening partitioned by the first bank 610.

Each of the plurality of light emitting elements ED may emit light of a specific wavelength band. For example, the light emitting element ED may emit the third color light or the blue light having a peak wavelength in the range of 480 nm or less, preferably a peak wavelength in the range of 445 nm to 480 nm. However, the present disclosure is not limited thereto, and the light emitting element ED may emit green light or red light.

The second insulating layer 520 may be disposed on the first insulating layer 510 on which the light emitting element ED is disposed and the first bank 610. The second insulating layer 520 may be disposed at least on the light emitting element ED in the emission area EMA of each sub-pixel SPX, and may include an opening exposing both ends of the light emitting element ED.

Further, the second insulating layer 520 may include the opening forming the first opening OP1 (see FIGS. 4 and 5) exposing one surface of the circuit element layer CCL in the boundary region between the first emission area EMA1 and the first non-emission area BA1 together with the first insulating layer 510. The second insulating layer 520 may further include the opening forming the second opening OP2 (see FIGS. 4 and 5) exposing one surface of the circuit element layer CCL in the boundary region between the second emission area EMA2 and the first non-emission area BA1.

The second insulating layer 520 may completely cover one surface of the circuit element layer CCL on the first bank 610 in the boundary region between the second emission area EMA2 and the second non-emission area BA2 and the boundary region between the third emission area EMA3 and the second non-emission area BA2. Similarly, the second insulating layer 520 may completely cover one surface of the circuit element layer CCL on the first bank 610 in the boundary region between the third emission area EMA3 and the third non-emission area BA3 (e.g., the right side of the third emission area EMA3 in FIG. 6) and the boundary region between the first emission area EMA1 and the third non-emission area BA3 (e.g., the left side of the first emission area EMA1 in FIG. 6). That is, similarly to the first insulating layer 510, the second insulating layer 520 may substantially cover the first to third emission areas EMA1, EMA2, and EMA3 and the first to third non-emission areas BA1, BA2 and BA3, and may include an opening exposing the right side and the left side of at least the first non-emission area BA1 in the boundary region between the first sub-pixel SPX1 and the second sub-pixel SPX2.

The contact electrode 700 may be disposed on the second insulating layer 520 and the light emitting element ED.

For example, the first contact electrode 710 may be disposed on the second insulating layer 520, and may overlap the first electrode 210 and one end of the light emitting element ED. The first contact electrode 710 may be in contact with one end of the light emitting element ED exposed by the second insulating layer 520 in the emission area EMA of each sub-pixel SPX.

The third insulating layer 530 may be disposed on the second insulating layer 520 on which the first contact electrode 710 is formed. The third insulating layer 530 may be disposed on the first contact electrode 710 to completely cover the first contact electrode 710. The third insulating layer 530 may be disposed on the second insulating layer 520 to completely cover the sidewall of the second insulating layer 520 positioned on one end side of the light emitting element ED. The third insulating layer 530 may be disposed on the second insulating layer 520 and aligned with the sidewall of the second insulating layer 520 positioned on the other end side of the light emitting element ED to expose the other end of the light emitting element ED.

Further, the third insulating layer 530 may include the opening forming the first opening OP1 (see FIGS. 4 and 5) exposing one surface of the circuit element layer CCL in the boundary region between the first emission area EMA1 and the first non-emission area BA1 together with the first insulating layer 510 and the second insulating layer 520. The third insulating layer 530 may further include the opening forming the second opening OP2 (see FIGS. 4 and 5) exposing one surface of the circuit element layer CCL in the boundary region between the second emission area EMA2 and the first non-emission area BA1.

The third insulating layer 530 may completely cover one surface of the circuit element layer CCL on the second insulating layer 520 in the boundary region between the second emission area EMA2 and the second non-emission area BA2 and the boundary region between the third emission area EMA3 and the second non-emission area BA2. Similarly, the third insulating layer 530 may completely cover one surface of the circuit element layer CCL on the second insulting layer 520 in the boundary region between the third emission area EMA3 and the third non-emission area BA3 (e.g., the right side of the third emission area EMA3 in FIG. 6) and the boundary region between the first emission area EMA1 and the third non-emission area BA3 (e.g., the left side of the first emission area EMA1 in FIG. 6). That is, similarly to the first insulating layer 510 and the second insulating layer 520, the third insulating layer 530 may substantially cover the first to third emission areas EMA1, EMA2, and EMA3 and the first to third non-emission areas BA1, BA2, and BA3, and may include the opening exposing the right side and the left side of at least the first non-emission area BA1 in the boundary region between the first sub-pixel SPX1 and the second sub-pixel SPX2.

The second bank 620 may be disposed on the third insulating layer 530.

The second bank 620 may be disposed in the non-emission area BA. The second bank 620 may overlap the first to third non-emission areas BA1, BA2, and BA3 surrounding the first to third emission areas EMA1, EMA2, and EMA3.

The second bank 620 may serve to block lights emitted from the plurality of light emitting elements ED from being mixed to the emission area EMA of the adjacent sub-pixel SPX. The second bank 620 may include an organic material. The second bank 620 may include a light absorbing material that absorbs light in a visible light wavelength band. For example, the second bank 620 may be formed of a material used as a black matrix of the display device 1. The second bank 620 may be a type of light blocking member.

The second bank 620 may include the opening exposing the plurality of light emitting elements ED disposed in each of the first to third emission areas EMA1, EMA2, and EMA3. Further, the second bank 620 may be disposed to overlap the first bank 610 in the first to third non-emission areas BA1, BA2, and BA3, and may be formed to have a height greater than that of the first bank 610. Because the second bank 620 has the height greater than that of the first bank 610 and includes the opening corresponding to the emission area EMA of each sub-pixel SPX, the second bank 620 may provide the space where the protection layer 800 and the wavelength control layer CWL are formed. That is, the second bank 620 may also serve as a partition wall for stably spraying the ink including a material forming the protection layer 800 or the wavelength control layer CWL to the emission area EMA of each sub-pixel SPX in the inkjet printing process of forming the protection layer 800 and/or the wavelength control layer CWL during the fabrication process of the display device 1.

The wavelength control layer CWL may be disposed on the light emitting element layer. The wavelength control layer CWL may be disposed above the plurality of light emitting elements ED. The wavelength control layer CWL may overlap the plurality of light emitting elements ED in the third direction DR3. The wavelength control layer CWL may be disposed on the light emitting element ED to transmit the light emitted from the light emitting element ED and incident on the wavelength control layer CWL while converting or maintaining the wavelength of the light.

The wavelength control layer CWL may include a wavelength conversion layer WCL for converting the wavelength of the light incident on the wavelength control layer CWL, and a light transmission pattern TPL for transmitting the light incident on the wavelength control layer CWL while maintaining the wavelength of the light.

The wavelength conversion layer WCL or the light transmission pattern TPL may be disposed to be separated for each of the first to third sub-pixels SPX1, SPX2, and SPX3. The wavelength conversion layer WCL or the light transmission pattern TPL may be formed in the emission areas, i.e., the first to third emission areas EMA1, EMA2, and EMA3, of the first to third sub-pixels SPX1, SPX2, and SPX3, and the wavelength conversion layers WCL and/or the light transmission patterns TPL adjacent to each other may be spaced from each other by the second bank 620 disposed in the non-emission area BA.

The wavelength conversion layer WCL may be disposed in the sub-pixel SPX that needs to convert the wavelength of incident light emitted from the light emitting element ED because the incident light emitted from the light emitting element ED has light that exhibits a color different from the color of the corresponding sub-pixel SPX. The light transmission pattern TPL may be disposed in the sub-pixel SPX in which incident light emitted from the light emitting element ED exhibits the same color as the color of the corresponding sub-pixel SPX. In the illustrated embodiment, the wavelength conversion layer WCL may be disposed in each of the first sub-pixel SPX1 and the second sub-pixel SPX2, and the light transmission pattern TPL may be disposed in the third sub-pixel SPX3.

The wavelength conversion layer WCL may include a first wavelength conversion pattern WCL1 disposed on the first sub-pixel SPX1 and a second wavelength conversion pattern WCL2 disposed on the second sub-pixel SPX2.

The first wavelength conversion pattern WCL1 may be disposed in the first emission area EMA1 partitioned by the second bank 620 in the first sub-pixel SPX1. The first wavelength conversion pattern WCL1 may be disposed on the protection layer 800 to be described later in the first emission area EMA1 partitioned by the second bank 620. The first wavelength conversion pattern WCL1 may be in contact with one surface of the protection layer 800 disposed in the first emission area EMA1. That is, the protection layer 800 may be disposed between the plurality of light emitting elements ED and the first wavelength conversion pattern WCL1 in the first emission area EMA1.

The first wavelength conversion pattern WCL1 may convert incident light emitted from the light emitting element ED into first color light and then emit the light. For example, the first wavelength conversion pattern WCL1 may convert incident light emitted from the light emitting element ED into red light and then emit the light.

The first wavelength conversion pattern WCL1 may include a first base resin BRS1 and a first wavelength conversion material WCP1 dispersed in the first base resin BRS1. The first wavelength conversion pattern WCL1 may further include first scatterers SCP1 dispersed in the first base resin BRS1.

The second wavelength conversion pattern WCL2 may be disposed in the second emission area EMA2 partitioned by the second bank 620 in the second sub-pixel SPX2. The second wavelength conversion pattern WCL2 may be disposed on the protection layer 800 to be described later in the second emission area EMA2 partitioned by the second bank 620. The second wavelength conversion pattern WCL2 may be in contact with one surface of the protection layer 800 disposed in the second emission area EMA2. That is, the protection layer 800 may be disposed between the plurality of light emitting elements ED and the second wavelength conversion pattern WCL2 in the second emission area EMA2.

The second wavelength conversion pattern WCL2 may convert incident light emitted from the light emitting element ED into second color light and then emit the light. For example, the second wavelength conversion pattern WCL2 may convert incident light emitted from the light emitting element ED into green light and then emit the light.

The second wavelength conversion pattern WCL2 may include a second base resin BRS2 and a second wavelength conversion material WCP2 dispersed in the second base resin BRS2. The second wavelength conversion pattern WCL2 may further include second scatterers SCP2 dispersed in the second base resin BRS2.

The light transmission pattern TPL may be disposed in the third emission area EMA3 partitioned by the second bank 620 in the third sub-pixel SPX3. The light transmission pattern TPL may be disposed on the third insulating layer 530 in the third emission area EMA3 partitioned by the second bank 620. That is, the protection layer 800 may not be disposed in the third emission area EMA3 of the third sub-pixel SXP3. The light transmission pattern TPL may be in direct contact with the light emitting element layer disposed in the third emission area EMA3.

The light transmission pattern TPL may maintain the wavelength of incident light emitted from the light emitting element ED and allow the light to emit. For example, the light transmission pattern TPL may maintain incident light emitted from the light emitting element ED as blue light and then emit the light.

The light transmission pattern TPL may contain a third base resin BRS3. The light transmission pattern TPL may further contain third scatterers SCP3 dispersed in the third base resin BRS3.

The first to third base resins BRS1, BRS2, and BRS3 may include a light transmitting organic material. For example, the first to third base resins BRS1, BRS2, and BRS3 may include an epoxy resin, an acrylic resin, a cardo resin, an imide resin, or the like. The first to third base resins BRS1, BRS2 and BRS3 may be formed of the same material, but the present disclosure is not limited thereto.

The first to third scatterers SCP1, SCP2 and SCP3 may have a refractive index different from that of the first to third base resins BRS1, BRS2, and BRS3. The first to third scatterers SCP1, SCP2, and SCP3 may include metal oxide particles or organic particles. Examples of the metal oxide may include titanium oxide (TiO₂), zirconium oxide (ZrO₂), aluminum oxide (Al₂O₃), indium oxide (In₂O₃), zinc oxide (ZnO), tin oxide (SnO₂), and the like. Examples of a material of the organic particles may include acrylic resin and urethane resin, and the like. The first to third scatterers SCP1, SCP2, and SCP3 may all be formed of the same material, but are not limited thereto.

The first wavelength conversion material WCP1 may convert the light of the third color into the light of the first color, and the second wavelength conversion material WCP2 may convert the light of the third color into the light of the second color. For example, the first wavelength conversion material WCP1 may be a material that converts blue light into red light. In addition, the second wavelength conversion material WCP2 may be a material that converts blue light into green light. The first wavelength conversion material WCP1 and the second wavelength conversion material WCP2 may be quantum dots (QD), quantum bars, fluorescent materials, or phosphorescent materials. Examples of the quantum dot may include Group IV nanocrystal, Group II-VI compound nanocrystal, Group III-V compound nanocrystal, Group IV-VI nanocrystal, and a combination thereof.

The protection layer 800 may be disposed between the wavelength conversion layer WCL and the light emitting element layer. For example, the protection layer 800 may be disposed between the light emitting element layer and the first wavelength conversion pattern WCL1 in the first emission area EMA1 of the first sub-pixel SPX1, and may be disposed between the light emitting element layer and the second wavelength conversion pattern WCL2 in the second emission area EMA2 of the second sub-pixel SPX2. The protection layer 800 may not be disposed in the third emission area EMA3 of the third sub-pixel SXP3. The protection layer 800 may be disposed above the plurality of light emitting elements ED to cover the plurality of light emitting elements ED.

The protection layer 800 disposed in the first emission area EMA1 of the first sub-pixel SPX1 and the protection layer 800 disposed in the second emission area EMA2 of the second sub-pixel SPX2 may be connected to each other through a tunnel TUN disposed in the non-emission area BA1. Accordingly, the protection layer 800 may also be disposed in a part of the first non-emission area BA1.

The protection layer 800 may include a base resin BRS and scatterers SCP dispersed in the base resin BRS.

The base resin BRS may contain a transparent organic material. For example, the base resin BRS may contain epoxy resin, acrylic resin, cardo resin, or imide resin. The base resin BRS may be formed of the same material as the third base resin BRS3 of the light transmission pattern TPL disposed in the third sub-pixel SPX3, but the present disclosure is not limited thereto.

The scatterer SCP may have a refractive index different from that of the base resin BRS. The scatterer SCP may include a metal oxide particle or an organic particle. Examples of the metal oxide may include titanium oxide (TiO₂), zirconium oxide (ZrO₂), aluminum oxide (Al₂O₃), indium oxide (In₂O₃), zinc oxide (ZnO), tin oxide (SnO₂), and the like. Examples of a material of the organic particles may include acrylic resin and urethane resin, and the like. The scatterer SCP may be made of the same material as the third scatterer SCP3 of the light transmission pattern TPL disposed in the third sub-pixel SPX3, but the present disclosure is not limited thereto.

Because the protection layer 800 is disposed between the light emitting element ED of the light emitting element layer and the wavelength conversion layer WCL and includes the scatterers SCP for scattering light, the light emitted from the light emitting element ED may be dispersed and prevented from being concentrated. That is, the protection layer 800 may serve to disperse the lights emitted from the plurality of light emitting elements ED and incident on the wavelength conversion layer WCL and provide the lights emitted from the plurality of light emitting elements ED at a uniform luminance to the wavelength conversion layer WCL in a plan view. Accordingly, it is possible to improve the luminance uniformity of the light emitted from the light emitting element ED and incident on the wavelength conversion layer WCL. Accordingly, it is possible to prevent the wavelength conversion layer WCL from being damaged by the light energy of the light due to the decrease in the amount of light incident on the wavelength conversion layer WCL per area. In addition, the protection layer 800 may be disposed between the light emitting element ED of the light emitting element layer and the wavelength conversion layer WCL to prevent the wavelength conversion layer WCL from being damaged by thermal energy that may be generated when light is emitted from the light emitting element ED.

The first display substrate 10 may further include a first capping layer CAP1, a first low refractive layer LRL1, and a second capping layer CAP2.

The first capping layer CAP1 may be disposed on the wavelength control layer CWL and the second bank 620. The first capping layer CAP1 may be disposed on the wavelength control layer CWL and the second bank 620 to cover them. For example, the first capping layer CAP1 may encapsulate the first wavelength conversion pattern WCL1, the second wavelength conversion pattern WCL2, the light transmission pattern TPL, and the second bank 620 to prevent damage or contamination of the first wavelength conversion pattern WCL1, the second wavelength conversion pattern WCL2, and the light transmission pattern TPL.

The first capping layer CAP1 may contain an inorganic material. For example, the first capping layer CAP1 may contain at least one of silicon nitride, aluminum nitride, zirconium nitride, titanium nitride, hafnium nitride, tantalum nitride, silicon oxide, aluminum oxide, titanium oxide, tin oxide, cerium oxide, or silicon oxynitride. Although it is illustrated in the drawing that the first capping layer CAP1 is formed as a single layer, the present disclosure is not limited thereto.

The first low refractive layer LRL1 may be disposed on the first capping layer CAP1. The first low refractive layer LRL1 may be disposed along the entire surface of the first display substrate 10. The first low refractive layer LRL1 may prevent total reflection of light incident from the wavelength control layer CWL on the filling layer 30 or the color filter layer CFL. The first low refractive layer LRL1 may have a refractive index lower than that of the wavelength control layer CWL.

The second capping layer CAP2 may be disposed on the first low refractive layer LRL1. The second capping layer CAP2 may be disposed on the first low refractive layer LRL1 to cover it. The second capping layer CAP2 may contain inorganic materials. The second capping layer CAP2 may include at least one of the materials exemplified in association with the material of the first capping layer CAP1.

The second display substrate 20 may be located above the first display substrate 10 to face (e.g., to oppose) the first display substrate 10. The second display substrate 20 may include a second substrate SUB2, a color filter layer CFL, a second low refractive layer LRL2, and a third capping layer CAP3.

Although FIGS. 6 and 7 illustrate that the color filter layer CFL is formed as a separate substrate from the first display substrate 10, the present disclosure is not limited thereto. For example, in some other embodiments, the second display substrate 20 may be omitted and the color filter layer CFL may be directly disposed on the first low refractive layer LRL1.

The second display substrate 20 may be disposed above the first low refractive layer LRL1 to face (e.g., to oppose) the first low refractive layer LRL1. When sequentially describing the cross-sectional structure of the second display substrate 20, a second substrate SUB2 of the second display substrate 20 may include a transparent material. The second substrate SUB2 may be a base substrate or a base member, and may be made of a transparent insulating material such as a polymer resin. The second substrate SUB2 may be made of a transparent insulating material such as glass, quartz, or polymer resin. The second substrate SUB2 may be a rigid substrate, but may also be a flexible substrate that can be bent, folded or rolled.

The second substrate SUB2 may be the same substrate as the first substrate SUB1, but may have a different material, thickness, transmittance and the like. For example, the second substrate SUB2 may have a higher transmittance than the first substrate SUB1. The second substrate SUB2 may be thicker or thinner than the first substrate SUB1.

A light blocking member BK may be disposed on one surface of the second substrate SUB2 facing (e.g., opposing) the first substrate SUB1 along the boundaries of the sub-pixels SPX. The light blocking member BK may overlap the first bank 610 and/or the second bank 620 of the first display substrate 10, and may be positioned in the non-emission area BA. The light blocking member BK may include the opening of the second substrate SUB2 overlapping the emission area EMA. The light blocking member BK may serve to block emission of light from the display device 1, and may also serve to suppress reflection of external light. The light blocking member BK may be formed in a grid shape in a plan view.

The light blocking member BK may include a light absorbing material that absorbs light in a visible light wavelength band. For example, the light blocking member BK may be formed of a material used as a black matrix of the display device 1.

In one or more embodiments, the light blocking member BK may absorb light of a specific wavelength band from among visible wavelengths, and may transmit light of another specific wavelength band. For example, the light blocking member BK may include the same material as one of color filter layers CFL. For example, the light blocking member BK may be formed of the same material as a third color filter CF3 of a blue color. In one or more embodiments, the light blocking member BK may be formed integrally with the third color filter CF3. The light blocking member BK may be omitted.

The color filter layer CFL may be disposed on one surface of the second substrate SUB2 on which the light blocking member BK is disposed. The color filter layer CFL may include a first color filter CF1, a second color filter CF2, and a third color filter CF3.

The first color filter CF1 may be disposed in the first emission area EMA1 of the first sub-pixel SPX1, the second color filter CF2 may be disposed in the second emission area EMA2 of the second sub-pixel SPX2, and the third color filter CF3 may be disposed in the third emission area EMA3 of the third sub-pixel SPX3.

The first to third color filters CF1, CF2, and CF3 may include a colorant such as a dye or pigment that absorbs a wavelength other than a corresponding color wavelength. The first color filter CF1 may selectively allow the first color light (e.g., red light) to pass therethrough, and block or absorb the second color light (e.g., green light) and the third color light (e.g., blue light). The second color filter CF2 may selectively allow the second color light (e.g., green light) to pass therethrough, and block or absorb the first color light (e.g., red light) and the third color light (e.g., blue light). The third color filter CF3 may selectively allow the third color light (e.g., blue light) to pass therethrough, and block or absorb the first color light (e.g., red light) and the second color light (e.g., green light). For example, the first color filter CF1 may be a red color filter, the second color filter CF2 may be a green color filter, and the third color filter CF3 may be a blue color filter.

The first to third color filters CF1, CF2, and CF3 may absorb a part of the light coming from the outside of the display device 1 to reduce the reflected light of the external light. Thus, the first to third color filters CF1, CF2, and CF3 can prevent color distortion caused by the reflection of the external light.

A second low refractive layer LRL2 may be disposed on one surface of the color filter layer CFL facing (or opposing) the first display substrate 10. The second low refractive layer LRL2 may be disposed along the entire surface of the second display substrate 20. The second low refractive layer LRL2 may be disposed between the color filter layer CFL and the filling layer 30. The second low refractive layer LRL2 may prevent total reflection of light incident from the filling layer 30 on the color filter layer CFL.

A third capping layer CAP3 may be disposed on one surface of the second low refractive layer LRL2 facing (or opposing) the first display substrate 10. The third capping layer CAP3 may be disposed on the second low refractive layer LRL1 to cover it. The third capping layer CAP3 may include an inorganic material. The third capping layer CAP3 may include at least one of the materials exemplified in association with the first capping layer CAP1.

The filling layer 30 may fill the space between the first display substrate 10 and the second display substrate 20. For example, the filling layer 30 may be interposed between the second capping layer CAP2 of the first display substrate 10 and the third capping layer CAP3 of the second display substrate 20. The filling layer 30 may be made of a material that can transmit light. The filling layer 30 may include an organic material. For example, the filling layer 30 may be formed of a Si-based organic material, an epoxy-based organic material, or the like, but is not limited thereto. The filling layer 30 may be omitted.

FIG. 8 is a partial cross-sectional view illustrating an example of a display device taken along the line III-III′ of FIG. 4.

FIG. 8 illustrates the structure of the circuit element layer of the first sub-pixel SPX1 and the light emitting element layer disposed on the circuit element layer. The structure of the circuit element layer and the light emitting element layer disposed in the first sub-pixel SPX1 may be equally applied to the second sub-pixel SPX2 and the third sub-pixel SPX3. Therefore, the description of the structure of the circuit element layers and the light emitting element layers disposed in the second sub-pixel SPX2 and the third sub-pixel SPX3 will be replaced with the description of the structure of the circuit element layer and the light emitting element layer disposed in the first sub-pixel SPX1.

Referring to FIGS. 4, 6, and 8, the circuit element layer CCL may be disposed on the first substrate SUB1. The circuit element layer CCL may include a lower metal layer 110, a semiconductor layer 120, a first conductive layer 130, a second conductive layer 140, a third conductive layer 150, and a plurality of insulating layers.

The lower metal layer 110 is disposed on the substrate SUB. The lower metal layer 110 may include a light blocking pattern BML. The light blocking pattern BML may be disposed to cover at least the channel region of the active layer ACT of the transistor TR from the bottom. However, the present disclosure is not limited thereto, and the light blocking pattern BML may be omitted. The lower metal layer 110 may contain a material that blocks light. For example, the lower metal layer 110 may be made of an opaque metal material that blocks transmission of light.

The buffer layer 161 may be disposed on the lower metal layer 110. The buffer layer 161 may be disposed to cover the entire surface of the first substrate SUB1 where the lower metal layer 110 is disposed. The buffer layer 161 may serve to protect a plurality of transistors from moisture permeating through the first substrate SUB1 that is susceptible to moisture permeation.

The semiconductor layer 120 is disposed on the buffer layer 161. The semiconductor layer 120 may include the active layer ACT of the transistor TR. The active layer ACT of the transistor TR may be disposed to overlap the light blocking pattern BML of the lower metal layer 110 as described above in the third direction DR3.

The semiconductor layer 120 may include polycrystalline silicon, monocrystalline silicon, an oxide semiconductor, or the like. In one or more embodiments, when the semiconductor layer 120 contains polycrystalline silicon, the polycrystalline silicon may be formed by crystallizing amorphous silicon. When the semiconductor layer 120 contains polycrystalline silicon, the active layer ACT of the transistor TR may include a plurality of doping regions doped with impurities and channel regions disposed therebetween. In one or more embodiments, the semiconductor layer 120 may contain an oxide semiconductor. The oxide semiconductor may be, for example, indium tin oxide (ITO), indium zinc oxide (IZO), indium gallium oxide (IGO), indium zinc tin oxide (IZTO), indium gallium zinc oxide (IGZO), indium gallium tin oxide (IGTO), indium gallium zinc tin oxide (IGZTO) or the like.

A gate insulating layer 162 may be disposed on the semiconductor layer 120 and the buffer layer 161. The gate insulating layer 162 may function as a gate insulating layer of the transistor. The gate insulating layer 162 may be formed as a multilayer in which inorganic layers including an inorganic material, for example, at least one of silicon oxide (SiOx), silicon nitride (SiNx) or silicon oxynitride (SiOxNy) are alternately stacked.

The first conductive layer 130 may be disposed on the gate insulating layer 162. The first conductive layer 130 may include a gate electrode GE of the transistor TR. The gate electrode GE may be disposed to overlap the channel region of the active layer ACT in the third direction DR3.

A first interlayer insulating layer 163 may be disposed on the first conductive layer 130 and the gate insulating layer 162. The first interlayer insulating layer 163 may be disposed to cover the gate electrode GE. The first interlayer insulating layer 163 may function as an insulating layer between the first conductive layer 130 and other layers disposed thereon to protect the first conductive layer 130.

A second conductive layer 140 may be disposed on the first interlayer insulating layer 163. The second conductive layer 140 may include a drain electrode SD1 of the transistor TR and a source electrode SD2 of the transistor TR.

The drain electrode SD1 and the source electrode SD2 of the transistor TR may be electrically connected to both ends of the active layer ACT of the transistor TR through contact holes penetrating the first interlayer insulating layer 163 and the gate insulating layer 162. Further, the source electrode SD2 of the transistor TR may be electrically connected to the light blocking pattern BML of the lower metal layer 110 through another contact hole penetrating the first interlayer insulating layer 163, the gate insulating layer 162, and the buffer layer 161.

A second interlayer insulating layer 164 may be disposed on the second conductive layer 140 and the first interlayer insulating layer 163. The second interlayer insulating layer 164 may be disposed to cover the drain electrode SD1 of the transistor TR and the source electrode SD2 of the transistor TR. The second interlayer insulating layer 164 may function as an insulating layer between the second conductive layer 140 and other layers disposed thereon, and may protect the second conductive layer 140.

A third conductive layer 150 may be disposed on the second interlayer insulating layer 164. The third conductive layer 150 may include a first voltage line VL1, a second voltage line VL2, and a conductive pattern CDP.

The first voltage line VL1 may overlap at least a part of the drain electrode SD1 of the transistor TR in the third direction DR3. A high potential voltage (or a first source voltage) supplied to the transistor TR may be applied to the first voltage line VL1.

The second voltage line VL2 may be electrically connected to the second electrode 220 through the second electrode contact hole CTS penetrating a via layer 166 and a passivation layer 165 to be described below. A low potential voltage (or a second source voltage) lower than the high potential voltage supplied to the first voltage line VL1 may be applied to the second voltage line VL2. That is, the high potential voltage (or the first power voltage) supplied to the transistor TR may be applied to the first voltage line VL1, and the low potential voltage (or the second power voltage) lower than the high potential voltage supplied to the first voltage line VL1 may be applied to the second voltage line VL2.

The conductive pattern CDP may be electrically connected to the source electrode SD2 of the transistor TR. The conductive pattern CDP may be electrically connected to the source electrode SD2 of the transistor TR through the contact hole penetrating the second interlayer insulating layer 164. Further, the conductive pattern CDP may be electrically connected to the first electrode 210 through a first electrode contact hole CTD that penetrates the via layer 166 and the passivation layer 165, which will be described later. The transistor TR may transmit the first source voltage applied from the first voltage line VL1 to the first electrode 210 through the conductive pattern CDP.

The passivation layer 165 may be disposed on the third conductive layer 150 and the second interlayer insulating layer 164. The passivation layer 165 may be disposed to cover the third conductive layer 150. The passivation layer 165 may serve to protect the third conductive layer 150.

Each of the buffer layer 161, the first gate insulating layer 162, the first interlayer insulating layer 163, the second interlayer insulating layer 164, and the passivation layer 165 described above may be formed of a plurality of inorganic layers stacked in an alternating manner. For example, the buffer layer 161, the gate insulating layer 162, the first interlayer insulating layer 163, the second interlayer insulating layer 164, and the passivation layer 165 described above may be formed as a double layer formed by stacking, or a multilayer formed by alternately stacking, inorganic layers including at least one of silicon oxide (SiOx), silicon nitride (SiNx), or silicon oxynitride (SiOxNy). However, the present disclosure is not limited thereto, and the buffer layer 161, the gate insulating layer 162, the first interlayer insulating layer 163, the second interlayer insulating layer 164, and the passivation layer 165 described above may be formed as a single inorganic layer containing the above-described insulating material.

The via layer 166 may be disposed on the passivation layer 165. The via layer 166 may include an organic insulating material, for example, an organic material such as polyimide (PI). The via layer 166 may function to flatten a surface. Accordingly, the top surface (or the surface) of the via layer 166, on which the light emitting element layer to be described later is disposed, may be substantially flat regardless of a shape or presence of a pattern disposed thereunder.

The light emitting element layer may be disposed on the circuit element layer. The light emitting element layer may be disposed on the via layer 166. The light emitting element layer may further include a third bank 400 disposed on the via layer 166.

The third bank 400 may be disposed on the via layer 166 in the emission area EMA (the first emission area EMA1 in FIG. 8). The third bank 400 may be disposed directly on one surface of the via layer 166. The third bank 400 may have a structure in which at least a part of the first bank 400 protrudes upward (e.g., one side in the third direction DR3) with respect to one surface of the via layer 166. The protruding part of the third bank 400 may have an inclined side surface. The third bank 400 may serve to change the traveling direction of the light emitted from the light emitting element ED toward the inclined side surface of the third bank 400 to an upward direction (e.g., a display direction).

The third bank 400 may include a first sub-bank 410 and a second sub-bank 420 spaced from each other. The first sub-bank 410 and the second sub-bank 420, which are spaced from each other, may provide a space in which the light emitting element ED is disposed, while assisting the function of a reflective partition wall that changes the traveling direction of the light emitted from the light emitting element ED to the display direction.

Although it is illustrated in the drawing that the side surface of the third bank 400 is include in a linear shape, the present disclosure is not limited thereto. For example, the side surface (or outer surface) of the third bank 400 may have a semicircular or semi-elliptical shape. In one or more embodiments, the third bank 400 may include an organic insulating material such as polyimide (PI), but is not limited thereto.

The electrode layer 200 may be disposed on the via layer 166 on which the first bank 400 is formed. In the emission area EMA, the electrode layer 200 may be disposed on the first bank 400, and in the non-emission area BA, the electrode layer 200 may be disposed on the via layer 166 exposed by the first bank 400.

In the emission area EMA (the first emission area EMA1 in FIG. 8), the first electrode 210 may be disposed on the first sub-bank 410, and the second electrode 220 may be disposed on the second sub-bank 420. The first electrode 210 may extend outward from the first sub-bank 410 and may also be disposed on the via layer 166 exposed by the first sub-bank 410. Similarly, the second electrode 220 may extend outward from the second sub-bank 420 and may also be disposed on the via layer 166 exposed by the second sub-bank 420. The first electrode 210 and the second electrode 220 may face (e.g., may oppose) each other in a separation region between the first sub-bank 410 and the second sub-bank 420. The via layer 166 may be exposed in the region where the first electrode 210 and the second electrode 220 are spaced from each other and face (e.g., oppose) each other.

The first electrode 210 may be spaced from the first electrode 210 of another first sub-pixel SPX1 adjacent thereto in the second direction DR2 with the separation portion ROP interposed therebetween in the sub-region SA (the first sub-region SA1 in FIG. 8). Similarly, the second electrode 220 may be spaced from the second electrode 220 of another first sub-pixel SPX1 adjacent thereto in the second direction DR2 with the separation portion ROP interposed therebetween in the sub-region SA (the first sub-region SA1 in FIG. 8). Therefore, the first electrode 210 and the second electrode 220 may expose the via layer 166 at the separation portion ROP of the sub-region SA (the first sub-region SA1 in FIG. 8).

The first electrode 210 may be electrically connected to the conductive pattern CDP of the circuit element layer CCL through the first electrode contact hole CTD penetrating the via layer 166 and the passivation layer 165. For example, the first electrode 210 may be in contact with the top surface of the conductive pattern CDP exposed by the first electrode contact hole CTD. The first source voltage applied from the first voltage line VL1 may be transmitted to the first electrode 210 through the conductive pattern CDP.

The second electrode 220 may be electrically connected to the second voltage line VL2 of the circuit element layer through the second electrode contact hole CTS penetrating the via layer 166 and the passivation layer 165. For example, the second electrode 220 may be in contact with the top surface of the second voltage line VL2 exposed by the second electrode contact hole CTS. The second source voltage applied from the second voltage line VL2 may be transmitted to the second electrode 220.

The electrode layer 200 may include a conductive material having high reflectivity. For example, the electrode layer 200 may include a metal such as silver (Ag), copper (Cu), or aluminum (Al) as a material having high reflectivity, or may include an alloy including aluminum (Al), nickel (Ni), lanthanum (La), and the like. The electrode layer 200 may reflect the light emitted from the light emitting element ED and traveling toward the side surface of the third bank 400 in the upward direction of each sub-pixel SPX.

However, the present disclosure is not limited thereto, and the electrode layer 200 may further include a transparent conductive material. For example, the electrode layer 200 may include a material such as ITO, IZO, and ITZO. In one or more embodiments, the electrode layer 200 may have a structure in which at least one transparent conductive material and at least one metal layer having high reflectivity are stacked, or may be formed as one layer including them. For example, the electrode layer 200 may have a stacked structure of ITO/Ag/ITO, ITO/Ag/IZO, ITO/Ag/ITZO/IZO, or the like.

The first insulating layer 510 may be disposed on the via layer 166 on which the electrode layer 200 is formed. The first insulating layer 510 may protect the electrode layer 200 while insulating the first electrode 210 from the second electrode 220.

The first insulating layer 510 may include an inorganic insulating material. For example, the first insulating layer 510 may include at least one of inorganic insulating materials such as silicon oxide (SiOx), silicon nitride (SiNx), silicon oxynitride (SiOxNy), aluminum oxide (AlxOy), and aluminum nitride (AlN). The first insulating layer 510 made of an inorganic material may have a surface shape reflecting the pattern shape of the electrode layer 200 disposed thereunder. That is, the first insulating layer 510 may have a stepped structure according to the shape of the electrode layer 200 disposed under the first insulating layer 510. For example, the first insulating layer 510 may include a stepped structure in which its top surface is partially recessed in a region where the first electrode 210 and the second electrode 220 face (e.g., oppose) each other while being spaced from each other. Accordingly, the top surface of the first insulating layer 510 disposed on the first electrode 210 and the second electrode 220 may be at a height higher than the height of the top surface of the first insulating layer 510 disposed on the via layer 166 on which the first electrode 210 and the second electrode 220 are not disposed. In the present disclosure, a height of a top surface of an arbitrary layer may be relatively compared based on a height measured from a flat reference surface (e.g., the top surface of the via layer 166) that does not have a lower stepped structure.

The first insulating layer 510 may include an opening forming the first contact portion CT1 partially exposing the top surface of the first electrode 210 and an opening forming the second contact portion CT2 partially exposing the top surface of the second electrode 220 in the sub-region SA (the first sub-region SA1 in FIG. 8). The first electrode 210 may be electrically connected to the first contact electrode 710 through the first contact portion CT1 penetrating the first insulating layer 510 and the second insulating layer 520 in the sub-region SA (the first sub-region SA1 in FIG. 8), and the second electrode 220 may be electrically connected to the second contact electrode 720 through the second contact portion CT2 penetrating the first insulating layer 510, the second insulating layer 520, and the third insulating layer 530 in the sub-region SA.

The first insulating layer 510 may not be disposed at the separation portion ROP positioned in the sub-region SA (the first sub-region SA1 in FIG. 8). The first insulating layer 510 may expose one surface of the via layer 166 at the separation portion ROP of the sub-region SA together with the first electrode 210 and the second electrode 220.

The first bank 610 may be disposed on the first insulating layer 510.

The plurality of light emitting elements ED may be arranged in the emission area EMA. The plurality of light emitting elements ED may not be disposed in the sub-region SA. The plurality of light emitting elements ED may be disposed on the first insulating layer 510 between the first sub-bank 410 and the second sub-bank 420. The plurality of light emitting elements ED may be disposed between the first electrode 210 and the second electrode 220 on the first insulating layer 510.

The second insulating layer 520 may be disposed on the light emitting element ED, the first insulating layer 510, and the first bank 610. The second insulating layer 520 may include the opening forming the first contact portion CT1 partially exposing the top surface of the first electrode 210 and the opening forming the second contact portion CT2 partially exposing the top surface of the second electrode 220 in the sub-region SA (the first sub-region SA1 in FIG. 8).

The second insulating layer 520 may not be disposed at the separation portion ROP positioned in the sub-region SA (the first sub-region SA1 in FIG. 8). The second insulating layer 520 may expose one surface of the via layer 166 at the separation portion ROP of the sub-region SA together with the first insulating layer 510, the first electrode 210, and the second electrode 220.

The first contact electrode 710 may be in contact with each of one end of the light emitting element ED exposed by the second insulating layer 520 and one surface of the first electrode 210 exposed by the first contact portion CT1. For example, the first contact electrode 710 may be in contact with one end of the light emitting element ED exposed by the second insulating layer 520 in the emission area EMA (the first emission area EMA1 in FIG. 8). Further, the first contact electrode 710 may be in contact with one surface of the first electrode 210 through the first contact portion CT1 penetrating the first insulating layer 510 and the second insulating layer 520 in the sub-region SA (the first sub-region SA1 in FIG. 8).

The third insulating layer 530 may be disposed on the second insulating layer 520 on which the first contact electrode 710 is formed. The third insulating layer 530 may completely cover the first contact electrode 710. The third insulating layer 530 may cover the first contact portion CT1 in the sub-region SA (the first sub-region SA1 in FIG. 8), and may include the opening forming the second contact portion CT2.

The third insulating layer 530 may not be disposed at the separation portion ROP positioned in the sub-region SA (the first sub-region SA1 in FIG. 8). The third insulating layer 530 may expose one surface of the via layer 166 at the separation portion ROP of the sub-region SA together with the first insulating layer 510, the second insulating layer 520, the first electrode 210, and the second electrode 220.

The second contact electrode 720 may be in contact with each of the other end of the light emitting element ED exposed by the second insulating layer 520 and the third insulating layer 530 and one surface of the second electrode 220 exposed by the second contact portion CT2. For example, the second contact electrode 720 may be in contact with the other end of the light emitting element ED exposed by the second insulating layer 520 and the third insulating layer 530 in the emission area EMA (the first emission area EMA1 in FIG. 8). Further, the second contact electrode 720 may be in contact with one surface of the second electrode 220 through the second contact portion CT2 penetrating the first insulating layer 510, the second insulating layer 520, and the third insulating layer 530 in the sub-region SA (the first sub-region SA1 in FIG. 8).

Each of the first contact electrode 710 and the second contact electrode 720 may include a conductive material. For example, each of the first contact electrode 710 and the second contact electrode 720 may include ITO, IZO, ITZO, aluminum (Al), or the like. As one example, each of the first contact electrode 710 and the second contact electrode 720 may include a transparent conductive material. Because each of the first contact electrode 710 and the second contact electrode 720 includes a transparent conductive material, light emitted from the light emitting element ED may pass through the first contact electrode 710 and the second contact electrode 720 to travel toward the first electrode 210 and the second electrode 220, and may be reflected from the surfaces of the first electrode 210 and the second electrode 220.

The second bank 620 may be disposed on the third insulating layer 530.

The second bank 620 may be disposed between the emission area EMA and the sub-region SA. The second bank 620 may not overlap the separation portion ROP of the sub-region SA.

The second bank 620 may include an opening for partitioning the emission area EMA and the sub-region SA to divide (e.g., to separate) the emission area EMA and the sub-region SA. The protection layer 800 and/or the wavelength control layer CWL may be disposed in the opening partitioned by the second bank 620 and overlapping the emission area EMA. For example, the protection layer 800 and the first wavelength conversion pattern WCL1 may be disposed on the third insulating layer 530 in the first emission area EMA1.

The protection layer 800 and/or the wavelength control layer CWL may not be disposed in the sub-region SA (the first sub-region SA1 in FIG. 8).

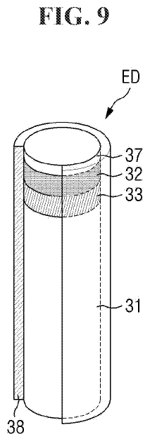

FIG. 9 is a schematic perspective cutaway view of a light emitting element according to one or more embodiments.

Referring to FIG. 9, the light emitting element ED which is a particulate element may have a rod or cylindrical shape having a suitable aspect ratio (e.g., a predetermined aspect ratio). The length of the light emitting element ED may be larger than the diameter of the light emitting element ED, and the aspect ratio may be 6:5 to 100:1, but the present disclosure is not limited thereto.

The light emitting element ED may have a size of a nanometer scale (equal to or greater than 1 nm and less than 1 μm) to a micrometer scale (equal to or greater than 1 μm and less than 1 mm). In one or more embodiments, both the diameter and the length of the light emitting element ED may be on a nanometer scale, or on a micrometer scale. In some other embodiments, the diameter of the light emitting element ED may be on a nanometer scale, while the length of the light emitting element ED may be on a micrometer scale. In one or more embodiments, some of the light emitting elements ED may have a diameter and/or length on a nanometer scale, while some others of the light emitting elements ED may have a diameter and/or length on a micrometer scale.

In one or more embodiments, the light emitting element ED may be an inorganic light emitting diode. The inorganic light emitting diode may include a plurality of semiconductor layers. For example, the inorganic light emitting diode may include a first conductivity type (e.g., n-type) semiconductor layer, a second conductivity type (e.g., p-type) semiconductor layer, and an active semiconductor layer interposed therebetween. The active semiconductor layer may receive holes and electrons from the first conductivity type semiconductor layer and the second conductivity type semiconductor layer, respectively, and the holes and electrons that have reached the active semiconductor layer may be coupled to emit light.

In one or more embodiments, the above-described semiconductor layers may be sequentially stacked along one direction, which is a length direction of the light emitting element ED. As shown in FIG. 9, the light emitting element ED may include a first semiconductor layer 31, an element active layer 33, and a second semiconductor layer 32 that are sequentially stacked in one direction. The first semiconductor layer 31, the element active layer 33, and the second semiconductor layer 32 may be the first conductivity type semiconductor layer, the active semiconductor layer, and the second conductivity type semiconductor layer described above, respectively.

The first semiconductor layer 31 may be doped with a first conductivity type dopant. The first conductivity type dopant may be Si, Ge, Sn, or the like. In one or more embodiments, the first semiconductor layer 31 may be n-GaN doped with n-type Si.

The second semiconductor layer 32 may be spaced from the first semiconductor layer 31 with the element active layer 33 interposed therebetween. The second semiconductor layer 32 may be doped with a second conductivity type dopant such as Mg, Zn, Ca, Se, Ba, or the like. In one or more embodiments, the second semiconductor layer 32 may be p-GaN doped with p-type Mg.

The element active layer 33 may include a material having a single or multiple quantum well structure. As described above, the element active layer 33 may emit light by coupling of electron-hole pairs according to an electrical signal applied through the first semiconductor layer 31 and the second semiconductor layer 32.

In one or more embodiments, the element active layer 33 may have a structure in which semiconductor materials having large band gap energy and semiconductor materials having small band gap energy are alternately stacked, and may include other Group III to V semiconductor materials according to the wavelength band of the emitted light.

Light emitted from the element active layer 33 may be emitted not only to both end surfaces of the light emitting element ED in the length direction, but also to the outer peripheral surface (or outer surface or side surface) of the light emitting element. That is, the directionality of light emitted from the element active layer 33 is not limited to one direction.

The light emitting element ED may further include an element electrode layer 37 disposed on the second semiconductor layer 32. The element electrode layer 37 may be in contact with the second semiconductor layer 32. The element electrode layer 37 may be an ohmic contact electrode. However, the element electrode layer 37 is not limited thereto, and may be a Schottky contact electrode.

The element electrode layer 37 may be disposed between the semiconductor layer 32 and a contact electrode 700 and may serve to reduce resistance when the both ends of the light emitting element ED are electrically connected to the contact electrode 700 to apply an electrical signal to the first and second semiconductor layers 31 and 32. The element electrode layer 37 may include at least one of aluminum (Al), titanium (Ti), indium (In), gold (Au), silver (Ag), indium tin oxide (ITO), indium zinc oxide (IZO), or indium tin zinc oxide (ITZO). The element electrode layer 37 may include an n-type or p-type doped semiconductor material.

The light emitting element ED may further include an element insulating film 38 around (e.g., surrounding) the outer surfaces (e.g., the outer peripheral or circumferential surfaces) of the first semiconductor layer 31, the second semiconductor layer 32, and the element active layer 33 and/or the element electrode layer 37. The element insulating film 38 may be disposed to surround at least the outer surface (e.g., the outer peripheral or circumferential surface) of the element active layer 33 and may extend in one direction in which the light emitting element ED extends. The element insulating film 38 may function to protect the members. Because the element insulating film 38 is made of materials having insulating properties, it is possible to prevent an electrical short circuit that may occur when the element active layer 33 directly contacts an electrode through which an electric signal is transmitted to the light emitting element ED. Further, because the element insulating film 38 protects the outer surfaces (e.g., the outer peripheral or circumferential surfaces) of the first and second semiconductor layers 31 and 32 including the element active layer 33, it is possible to prevent degradation in luminous efficiency.

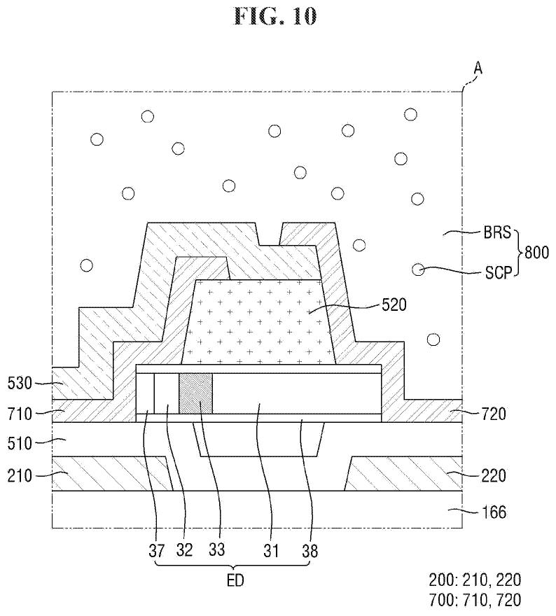

FIG. 10 is an enlarged cross-sectional view illustrating an example of area A of FIG. 8.

Referring to FIG. 10, the light emitting element ED may extend in a direction parallel to one surface of the first substrate SUB1. The plurality of semiconductor layers included in the light emitting element ED may be sequentially disposed along the direction parallel to the top surface of the first substrate SUB1 (or the top surface of the via layer 166). For example, the first semiconductor layer 31, the element active layer 33, and the second semiconductor layer 32 of the light emitting element ED may be sequentially arranged in the direction parallel to the top surface of the first substrate SUB1.

For example, in the light emitting element ED, the first semiconductor layer 31, the element active layer 33, the second semiconductor layer 32, and the element electrode layer 37 may be sequentially formed in the direction parallel to the top surface of the first substrate SUB1 in cross-sectional view across both ends of the light emitting element ED.

The light emitting element ED may be disposed such that one end thereof is located on the first electrode 210 and the other end thereof is located on the second electrode 220. However, the present disclosure is not limited thereto, and the light emitting element ED may be disposed such that one end thereof is located on the second electrode 220 and the other end thereof is located on the first electrode 210.

The second insulating layer 520 may be disposed on the light emitting element ED. The second insulating layer 520 may be disposed to be around (e.g., surround) the outer surface (e.g., the outer peripheral or circumferential surface) of the light emitting element ED. The second insulating layer 520 may be around (e.g., may surround) the outer surface (e.g., the outer peripheral or circumferential surface) of the element insulating film 38 of the light emitting element ED.

The first contact electrode 710 may be disposed on the first electrode 210 and one end of the light emitting element ED. The first contact electrode 710 may extend from one end of the light emitting element ED toward the second insulating layer 520 to be disposed on one sidewall of the second insulating layer 520 and the top surface of the second insulating layer 520. The first contact electrode 710 may be disposed on the top surface of the second insulating layer 520 while at least partially exposing the top surface of the second insulating layer 520.

The first contact electrode 710 may be in contact with one end of the light emitting element ED exposed by the second insulating layer 520. For example, the first contact electrode 710 may be disposed to be around (e.g., to surround) (or to be in contact with) one end surface (e.g., the element electrode layer 37) of the light emitting element ED exposed by the second insulating layer 520. The first contact electrode 710 may be in contact with the element insulating film 38 of the light emitting element ED.

The third insulating layer 530 may be disposed on the first contact electrode 710. The third insulating layer 530 may be disposed to completely cover the first contact electrode 710. The third insulating layer 530 may be disposed to completely cover one sidewall and the top surface of the second insulating layer 520, but may not be disposed on the other sidewall of the second insulating layer 520. One end of the third insulating layer 530 may be aligned with the other sidewall of the second insulating layer 520 in parallel.

The second contact electrode 720 may be disposed on the second electrode 220 and the other end of the light emitting element ED. The second contact electrode 720 may extend from the other end of the light emitting element ED toward the second insulating layer 520 to be also disposed on the other sidewall of the second insulating layer 520 and the top surface of the third insulating layer 530.

The second contact electrode 720 may be in contact with one end of the light emitting element ED exposed by the second insulating layer 520 and the third insulating layer 530. For example, the second contact electrode 720 may be disposed to be around (e.g., to surround) (or to be in contact with) the other end surface of the light emitting element ED exposed by the second insulating layer 520 and the third insulating layer 530. The second contact electrode 720 may be in contact with the element insulating film 38 of the light emitting element ED.

In this embodiment, the first contact electrode 710 and the second contact electrode 720 are formed on the different layers with the third insulating layer 530 interposing therebetween. Accordingly, a step for fabricating the display device 1 is added, which may decrease the fabrication process efficiency of the display device 1, but the reliability of the display device 1 can be improved. For example, because the first contact electrode 710 and the second contact electrode 720 are formed in the different layers and the third insulating layer 530 is further interposed therebetween, it is possible to reduce or minimize a problem in which the first contact electrode 710 and the second contact electrode 720 are short-circuited during the fabrication process of the display device 1.

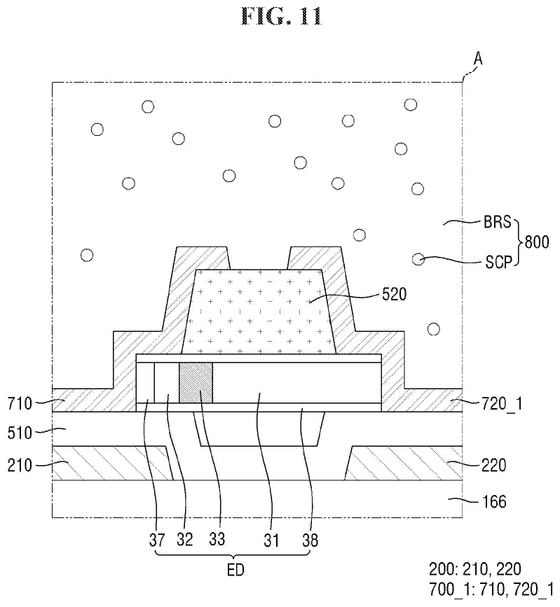

FIG. 11 is an enlarged cross-sectional view illustrating another example of area A of FIG. 8.

Referring to FIG. 11, the display device 1 according to the present embodiment is different from the embodiment of FIG. 10 in that a contact electrode 700_1 includes the first contact electrode 710 and a second contact electrode 720_1 that are formed on the same layer, and the third insulating layer 530 is omitted.

For example, a contact electrode 700_1 may include the first contact electrode 710 and the second contact electrode 720_1 that are formed at the same layer. The first contact electrode 710 and the second contact electrode 7201 may be spaced from each other with the second insulating layer 520 disposed on the light emitting element ED interposed therebetween. The first contact electrode 710 and the second contact electrode 720_1 may be disposed on the sidewalls of the second insulating layer 520 disposed on the light emitting element ED, and the top surface of the second insulating layer 520 may be exposed.

The first contact electrode 710 and the second contact electrode 720_1 may be formed on the same layer and may include the same material. That is, the first contact electrode 710 and the second contact electrode 720_1 may be concurrently (e.g., simultaneously) formed in one mask process. Accordingly, an additional mask process for forming the first contact electrode 710 and the second contact electrode 720_1 is not required, so that the fabrication process efficiency of the display device 1 can be improved.

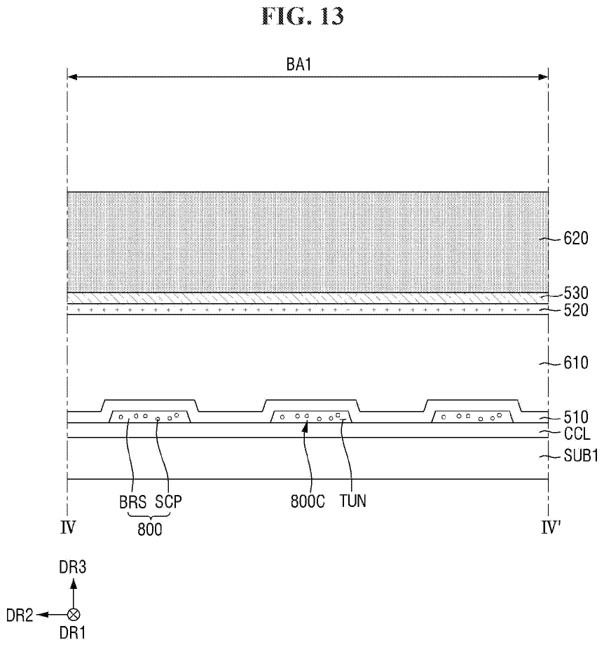

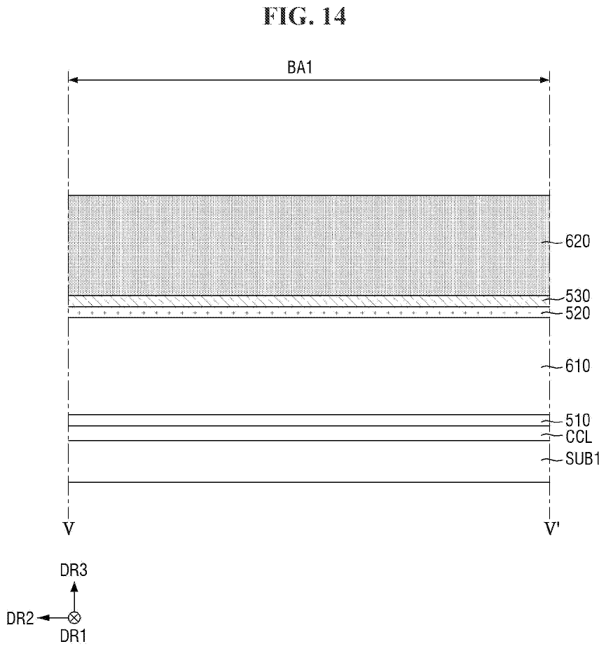

FIG. 12 is an enlarged cross-sectional view illustrating an example of a first emission area, a second emission area, and a first non-emission area. FIG. 13 is a cross-sectional view illustrating an example taken along the line IV-IV′ of FIG. 5. FIG. 14 is a cross-sectional view illustrating an example taken along the line V-V′ of FIG. 5.

Referring to FIGS. 12 to 14, the second bank 620 may partially overlap the first and second openings OP1 and OP2 penetrating the first to third insulating layers 510, 520, and 530. The width of the second bank 620 in the first direction DR1 may be greater than the width, in the first direction DR1, of the first insulating layer 510, the second insulating layer 520, the third insulating layer 530, and the first bank 610 disposed in the first non-emission area BA1. Accordingly, the second bank 620 may cover the sidewalls of the first to third insulating layers 510, 520, and 530 that form the first opening OP1 and the second opening OP2.

A part of the first insulating layer 510 disposed in the first non-emission area BA1 may be spaced from the top surface of the via layer 166. For example, a part of the first insulating layer 510 overlapping the passage TUN positioned in the first non-emission area BA1 may face (e.g., may oppose) the top surface of the via layer 166 while being spaced apart therefrom, thereby forming the passage TUN spatially connecting the first emission area EMA1 to the second emission area EMA2. The passage TUN may overlap the first and second banks 610 and 620 disposed in the first non-emission area BA1, and may refer to a space that is between the top surface of the via layer 166 and the first and second banks 610 and 620 that are spaced from the top surface of the via layer 166 by a suitable distance (e.g., a predetermined distance).

In one or more embodiments, as shown in FIG. 13, the passage TUN may be the region partitioned by the top surface of the via layer 166 and the bottom surface of the first insulating layer 510 disposed in the first non-emission area BA1, and the side surface of the first insulating layer 510.

In one or more embodiments, the first insulating layer 510 disposed in the second non-emission area BA2 in which the passage TUN is not formed may be in direct contact with the top surface of the via layer 166 as shown in FIG. 14.

The first opening OP1 penetrating the first to third insulating layers 510, 520, and 530 may be positioned in the boundary region between the first emission area EMA1 and the first non-emission area BA1, and the second opening OP2 penetrating the first to third insulating layers 510, 520, and 530 may be positioned in the boundary region between the second emission area EMA2 and the first non-emission area BA1. The first and second openings OP1 and OP2 may be openings exposing the passage pattern PT to a chemical material for removing the passage pattern PT in a process of removing the passage pattern PT to form the passage TUN during the fabrication process of the display device 1 to be described later.

The protection layer 800 may be interposed between the light emitting element layer and the wavelength conversion layer WCL. The protection layer 800 according to the present embodiment may include a first area 800A disposed in the first emission area EMA1, a second area 800B disposed in the second emission area EMA2, and a third area 8000 disposed in a part of the first non-emission area BA1.

The first area 800A of the protection layer 800 may be disposed in the first emission area EMA1. The first area 800A of the protection layer 800 may be disposed in the opening that is partitioned by the second bank 620 and overlaps the first emission area EMA1. The first area 800A of the protection layer 800 may be in contact with the sidewall of the second bank 620. The first area 800A of the protection layer 800 may overlap a first wavelength conversion pattern WCL1 in the third direction DR3.

The second area 800B of the protection layer 800 may be disposed in the second emission area EMA2. The second area 800B of the protection layer 800 may be disposed in the opening that is partitioned by the second bank 620 and overlaps the second emission area EMA2. The second area 800B of the protection layer 800 may be in contact with the sidewall of the second bank 620. The second area 800B of the protection layer 800 may overlap a second wavelength conversion pattern WCL2 in the third direction DR3.

The third area 8000 of the protection layer 800 may be disposed between the first area 800A of the protection layer 800 and the second area 800B of the protection layer 800. The third area 8000 of the protection layer 800 may be disposed between the first area 800A of the protection layer 800 and the second area 800B of the protection layer 800 to connect them. The third area 8000 of the protection layer 800 may be integrated with the first area 800A of the protection layer 800 and the second area 800B of the protection layer 800.

The third area 8000 of the protection layer 800 may be disposed in the first non-emission area BA1. The third area 8000 of the protection layer 800 may fill the passage TUN. Accordingly, the third area 8000 of the protection layer 800 may have the same pattern as the pattern of the passage TUN. That is, the third area 8000 of the protection layer 800 may have patterns extending in the first direction DR1 and spaced from each other in the second direction DR2.

Accordingly, the third area 8000 of the protection layer 800 may be in contact with the bottom surface of the first insulating layer 510, the side surface of the first insulating layer 510, and the top surface of the via layer 166 that define the passage TUN. The third area 8000 of the protection layer 800 may be in contact with the bottom surface of the second bank 620 or the bottom surface of the first insulating layer 510.

Each of the first area 800A of the protection layer 800 and the second area 800B of the protection layer 800 may not overlap the first bank 610 in the third direction DR3. The third area 8000 of the protection layer 800 may overlap each of the first and second banks 610 and 620 in the third direction DR3. The third area 8000 of the protection layer 800 may not overlap the first and second wavelength conversion patterns WCL1 and WCL2 in the third direction DR3.

Hereinafter, a method of fabricating the display device 1 will be described.

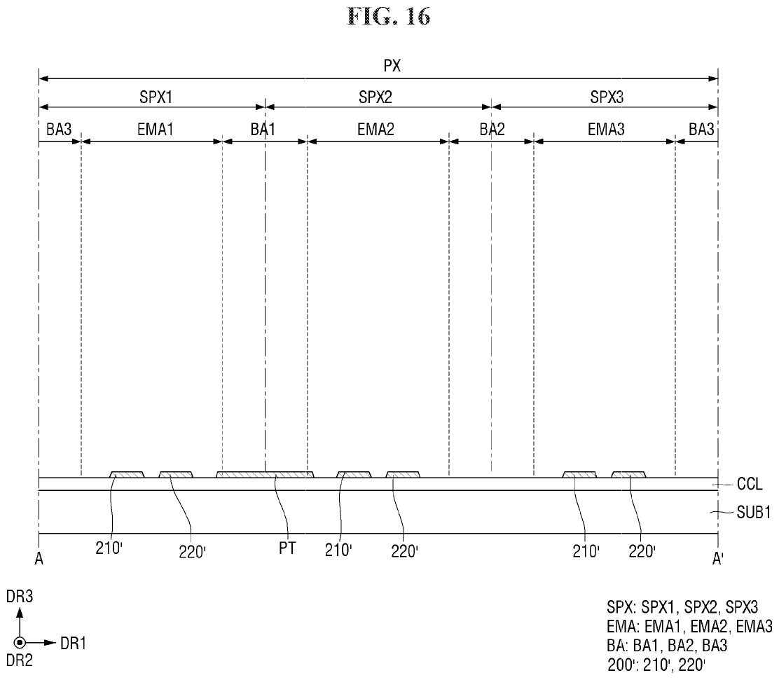

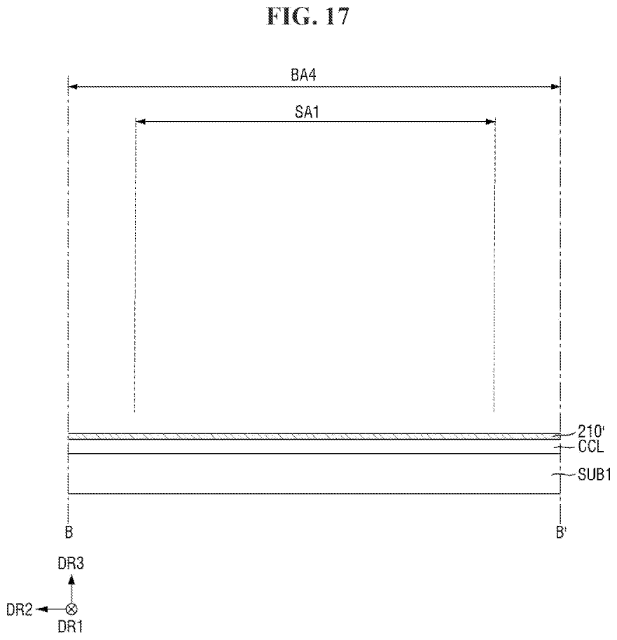

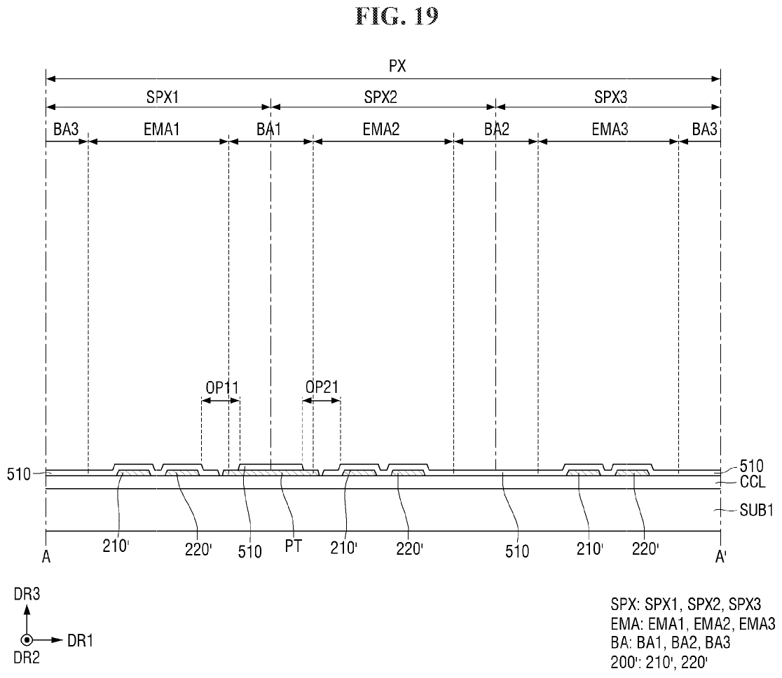

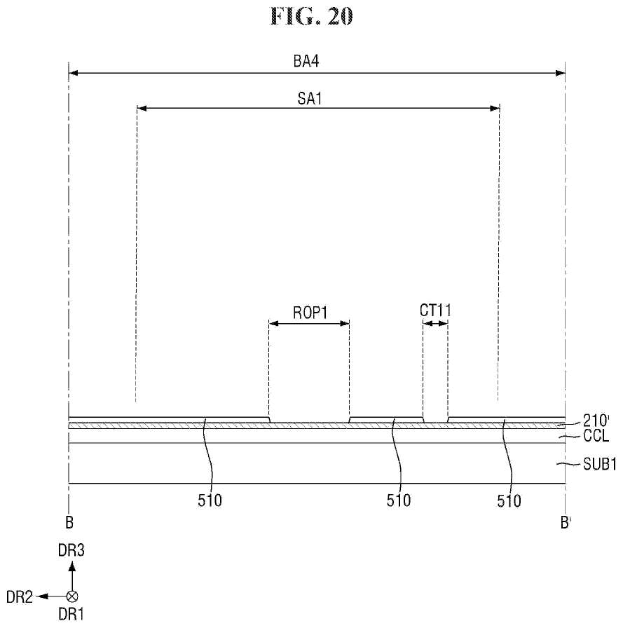

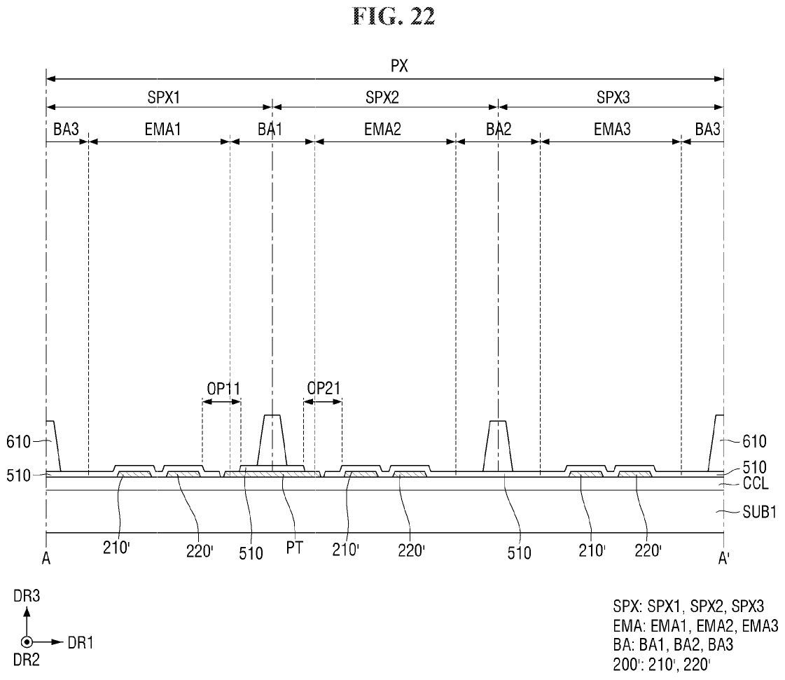

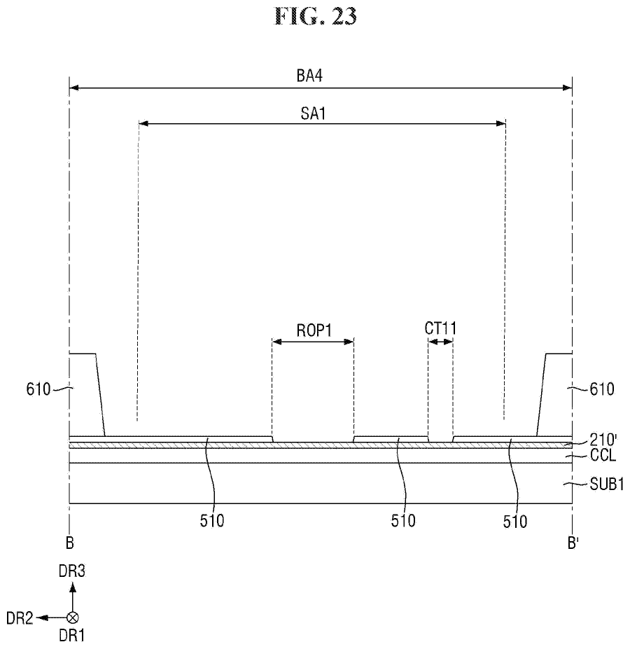

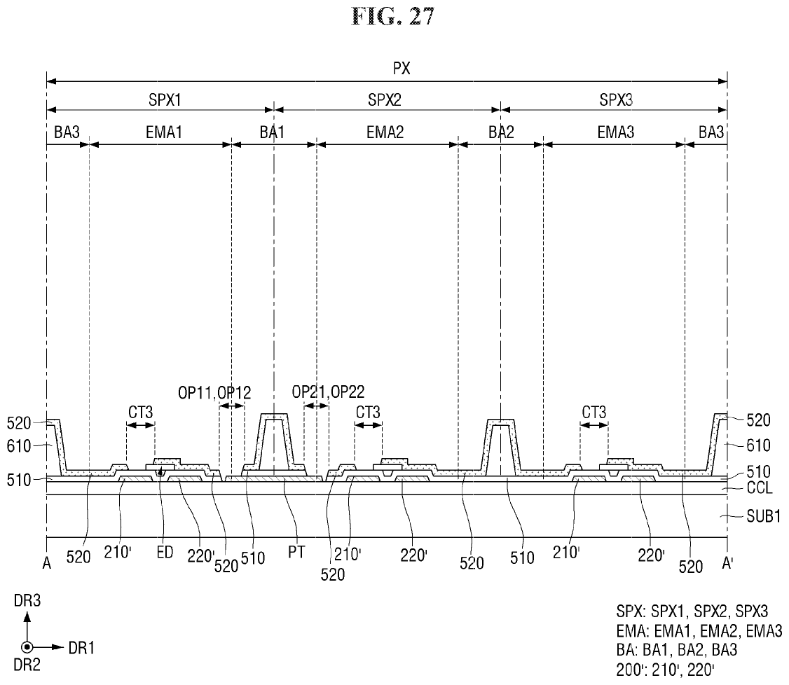

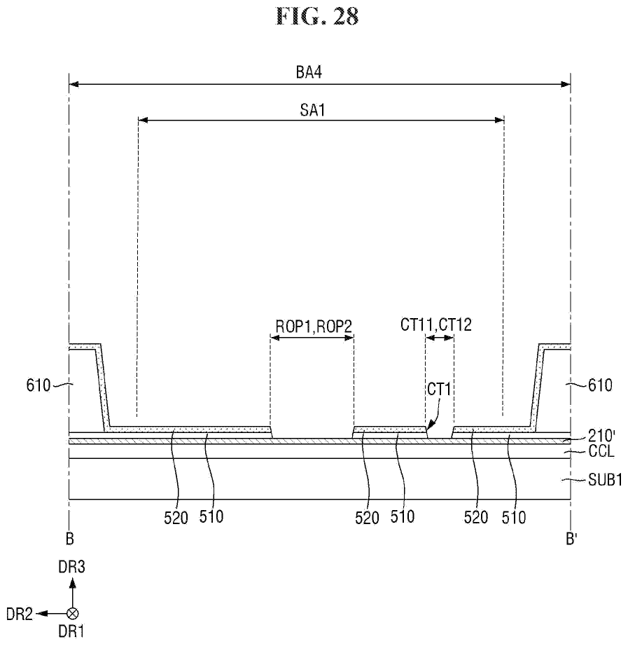

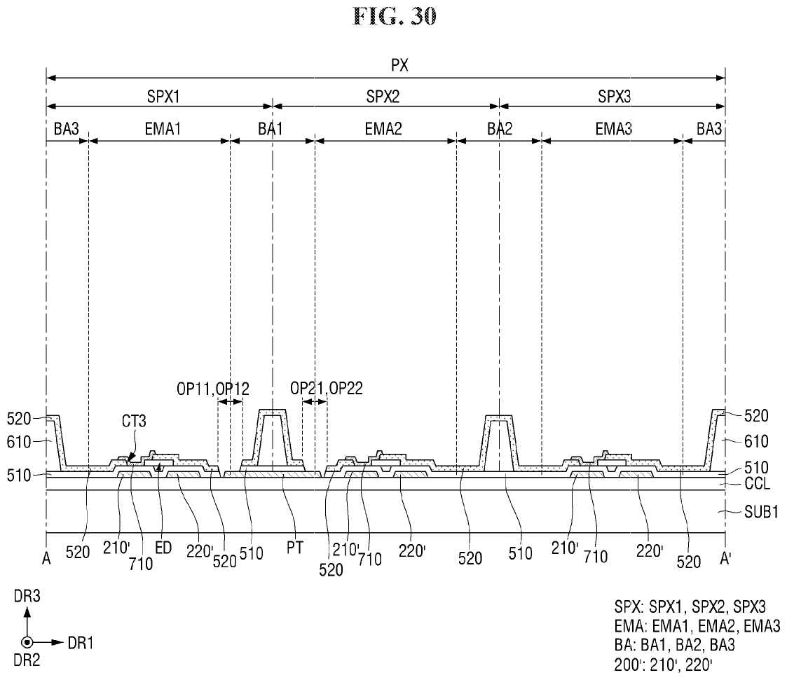

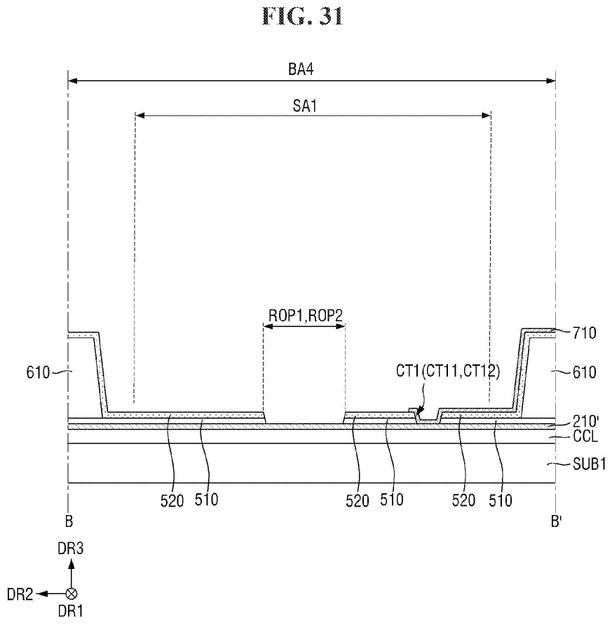

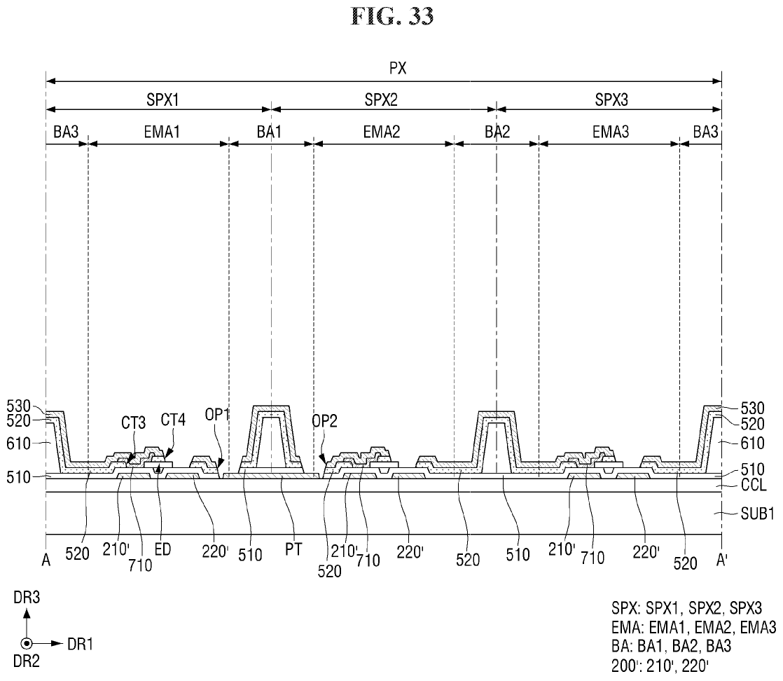

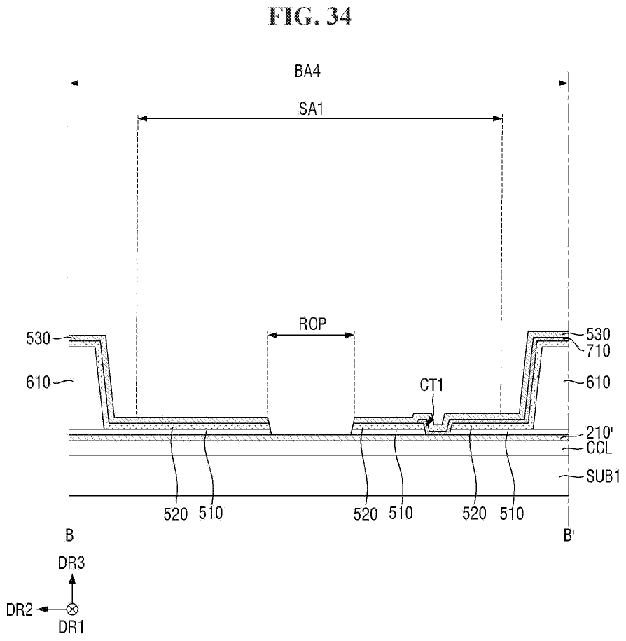

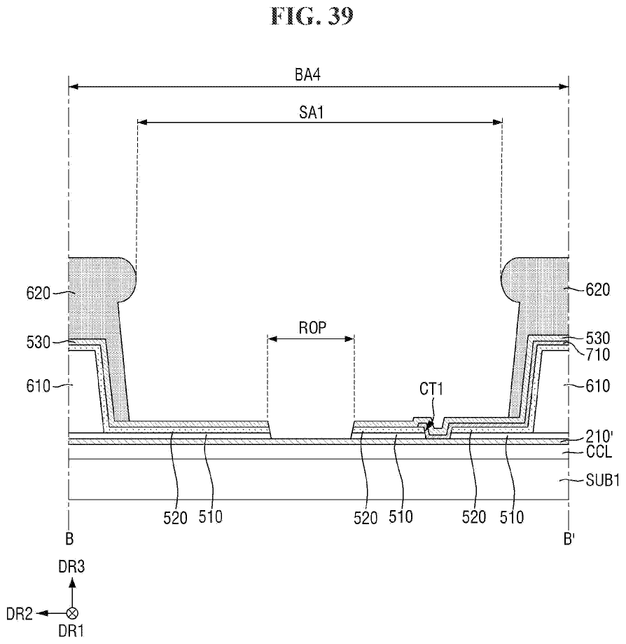

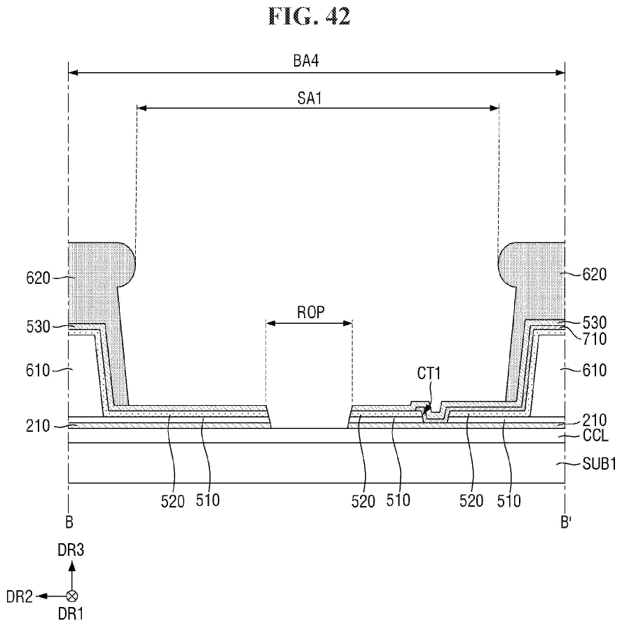

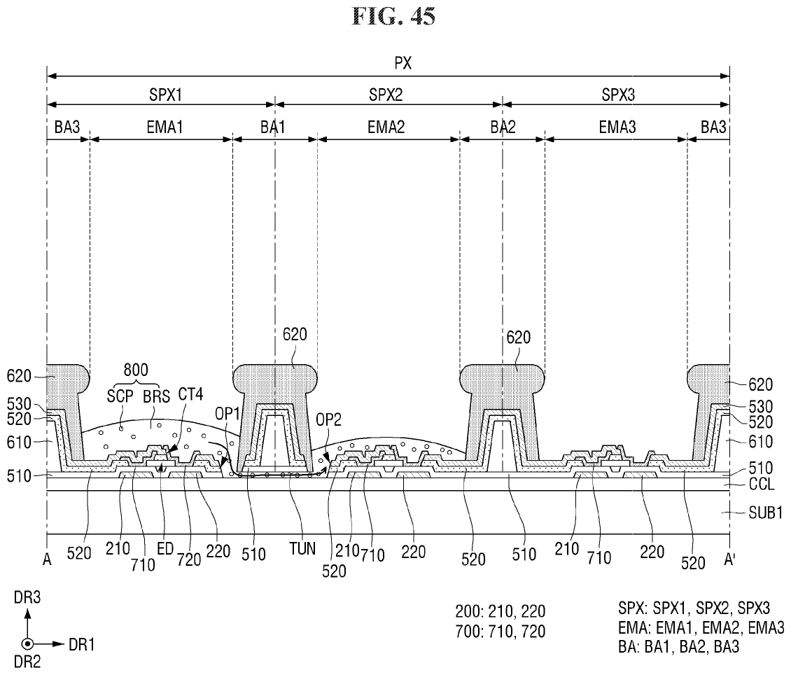

FIGS. 15 to 56 are plan layout views and cross-sectional views illustrating individual process steps of a method of fabricating a display device according to one or more embodiments.

First, referring to FIGS. 15 to 17, the patterned alignment line 200′ and the passage pattern PT are formed on the first substrate SUB1 on which the circuit element layer CCL is formed.

An alignment signal for aligning the plurality of light emitting elements ED may be applied to the alignment line 200′. The alignment signal may be applied to the alignment line 200′, and an electric field may be generated between a plurality of alignment lines included in the alignment line 200′.

The patterned alignment line 200′ may include the plurality of alignment lines that are spaced from each other. For example, the alignment line 200′ may include a first alignment line 210′ and a second alignment line 220′.

The first alignment line 210′ and the second alignment line 220′ may be disposed across the emission area EMA and the sub-region SA of each sub-pixel SPX. The first alignment line 210′ and the second alignment line 220′ may extend along the second direction DR2, and may be spaced from each other in the first direction DR1 on the circuit element layer CCL. The first alignment line 210′ and the second alignment line 220′ may be disposed in each column of each sub-pixel SPX. For example, the same first and second alignment lines 210′ and 220′ may be disposed in the sub-pixels SPX positioned in the same column, and different first and second alignment lines 210′ and 220′ may be disposed in the sub-pixels SPX positioned in different columns.

The first alignment line 210′ and the second alignment line 220′ may correspond to the first electrode 210 and the second electrode 220 that are described above, and may extend in the second direction DR2 to be connected to the sub-pixel SPX adjacent thereto in the second direction DR2 in the sub-region SA.

The passage pattern PT may be disposed between the first emission area EMA1 and the second emission area EMA2. The passage pattern PT may be disposed in the first non-emission area BA1. Both ends of the passage pattern PT may be disposed to overlap the first emission area EMA1 and the second emission area EMA2 in the first non-emission area BA1, respectively. The passage pattern PT may not be disposed in the second non-emission area BA2 and the third non-emission area BA3.

The passage pattern PT may have a planar shape extending in the first direction DR1. The width of the passage pattern PT in the first direction DR1 may be greater than the width of the first non-emission area BA1 in the first direction DR1. A plurality of passage patterns PT may be provided, and the plurality of passage patterns PT may be disposed to be spaced from each other along the second direction DR2.

The patterned alignment line 200′ and the passage pattern PT may be formed by the same mask process. For example, an electrode layer material layer is deposited on the circuit element layer CCL. The electrode layer material layer may include the same material as the material of the above-described electrode layer 200. On the other hand, in one or more embodiments, in the deposition process of the electrode layer material layer, the electrode layer material layer may be deposited into the first electrode contact hole CTD (see FIG. 8) and the second electrode contact hole CTS (see FIG. 8) penetrating the via layer 166 (see FIG. 8) and the passivation layer 165 (see FIG. 8) and connected to the conductive pattern CDP (see FIG. 8) disposed thereunder and the second voltage line VL2 (see FIG. 8).

Subsequently, a photoresist layer is coated on the material layer for the electrode layer, a photoresist pattern is formed through exposure and development, and then the material layer for the electrode layer is etched by using the photoresist pattern as an etching mask. Thereafter, the photoresist pattern is removed by a strip or ashing process to form the patterned alignment line 200′ and the passage pattern PT shown in FIGS. 15 to 17.

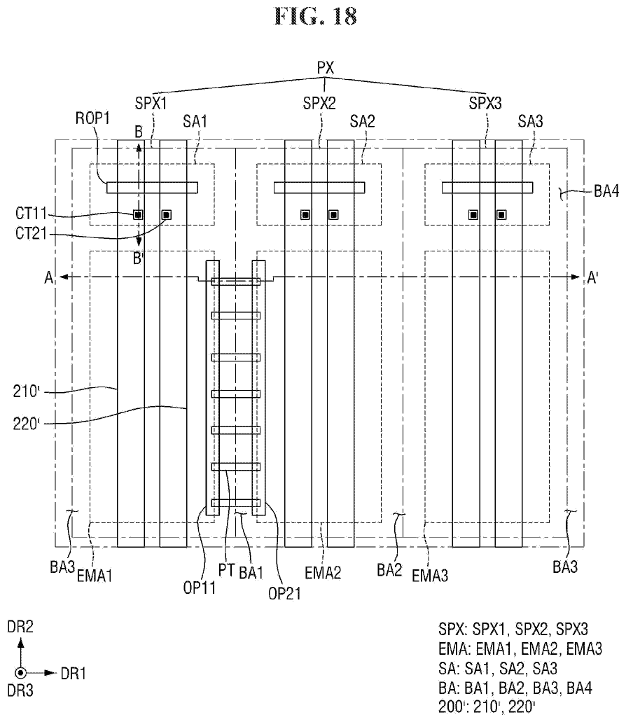

Next, referring to FIGS. 18 to 20, the patterned first insulating layer 510 is formed on the circuit element layer CCL on which the alignment line 200′ and the passage pattern PT are formed. The first insulating layer 510 may include a plurality of openings CT11, CT21, ROP1, OP11, and OP21. The plurality of openings CT11, CT21, ROP1, OP11, and OP21 included in the first insulating layer 510 may be formed in one mask process. For example, a first insulating layer material layer is deposited on the entire circuit element layer CCL on which the alignment line 200′ and the passage pattern PT are formed. Next, a photoresist pattern exposing a part of the alignment line layer 200′ and both ends of the passage pattern PT may be formed on the first insulating layer material layer, and the first insulating layer material layer may be etched using the photoresist pattern as an etching mask to form the plurality of openings CT11, CT21, ROP1, OP11, and OP21 exposing a part of the alignment line 200′ and both ends of the passage pattern PT as shown in FIGS. 18 to 20.

The first insulating layer 510 may include the plurality of openings OP11, OP21, CT11, CT21, and ROP1. The plurality of openings OP11, OP21, CT11, CT21, and ROP1 included in the first insulating layer 510 may include the plurality of openings CT11, CT21, and ROP1 exposing a part of the alignment line 200′ and the plurality of openings OP11 and OP21 exposing both ends of the passage pattern PT.

For example, the first insulating layer 510 may include the opening OP11 exposing one end of the passage pattern PT in the boundary region between the first emission area EMA1 and the first non-emission area BA1. Further, the first insulating layer 510 may include the opening OP21 exposing the other end of the passage pattern PT in the boundary region between the second emission area EMA2 and the first non-emission area BA1. The planar shapes of the openings OP11 and OP21 of the first insulating layer 510 exposing both ends of the plurality of passage patterns PT may extend in the second direction DR2 to expose both ends of the plurality of passage patterns PT. Accordingly, both ends of the plurality of passage patterns PT may be exposed by the openings OP11 and OP21 of the first insulating layer 510.

The first insulating layer 510 may include the plurality of openings CT11, CT21, and ROP1 partially exposing the alignment line 200′ in the sub-region SA. The first insulating layer 510 may include the openings CT11 and CT21 partially exposing the alignment line 200′ in a region overlapping the first and second contact portions CT1 and CT2. The first insulating layer 510 may further include the opening ROP1 partially exposing the alignment line 200′ in a region overlapping the separation portion ROP.

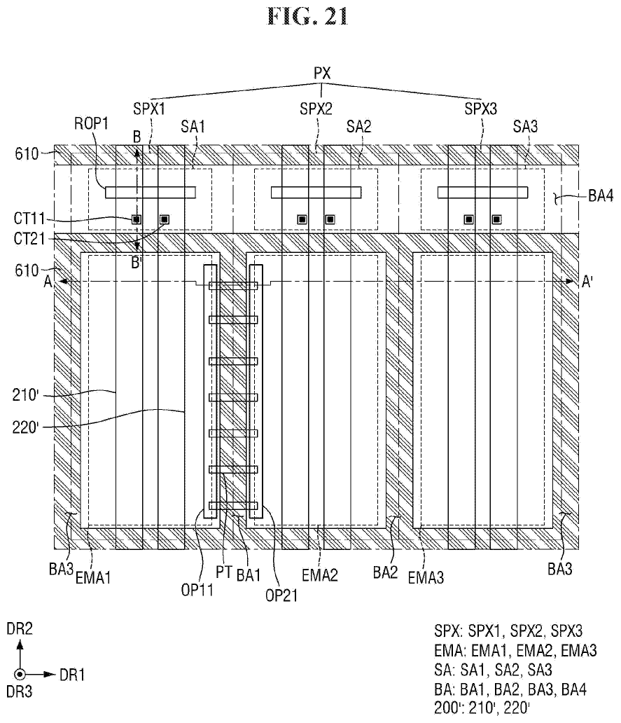

Next, referring to FIGS. 21 to 23, the patterned first bank 610 is formed on the first insulating layer 510. For example, the first bank 610 may include an organic insulating material. In this case, the patterned first bank 610 may be formed by coating a first organic material layer on the first insulating layer 510 and performing exposure and development.

The first bank 610 may be formed along the boundaries of the first to third emission areas EMA1, EMA2, and EMA3. The first bank 610 may be disposed in the first to third non-emission areas BA1, BA2, and BA3. The first bank 610 may be further disposed in the fourth non-emission area BA4 between the sub-region SA and the emission area EMA of each sub-pixel SPX.

In one or more embodiments, the width in the first direction DR1 of the first bank 610 disposed in the first to third non-emission areas BA1, BA2 and BA3 may be smaller than the width of the passage pattern PT in the first direction DR1. Accordingly, both ends of the passage pattern PT may be exposed by the first bank 610.

The first bank 610 may be disposed to be around (e.g., to surround) the emission areas EMA of the sub-pixels SPX so that the ink in which the plurality of light emitting elements ED are dispersed is sprayed into the emission area EMA without being mixed with the adjacent sub-pixel SPX in the inkjet printing process for aligning the light emitting elements ED. In addition, the first bank 610 may be disposed in the fourth non-emission area BA4 between the sub-region SA and the emission area EMA of each sub-pixel SPX to prevent the ink from being sprayed to the sub-region SA.

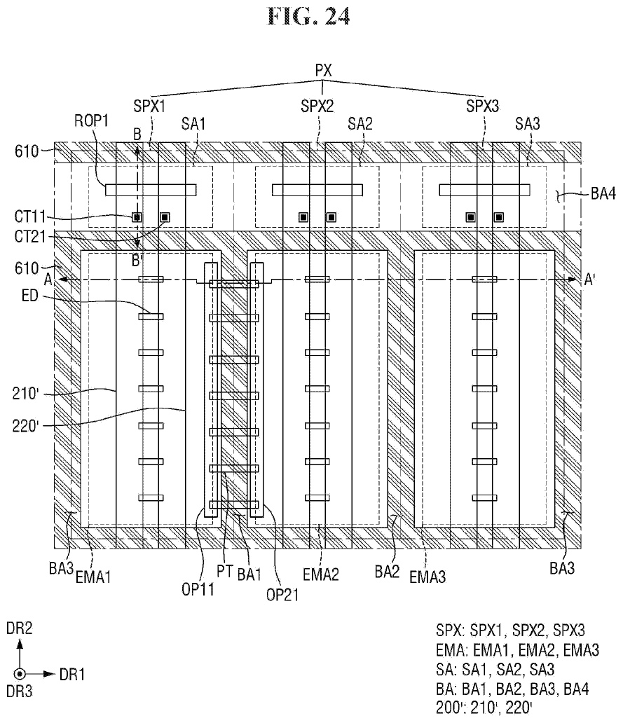

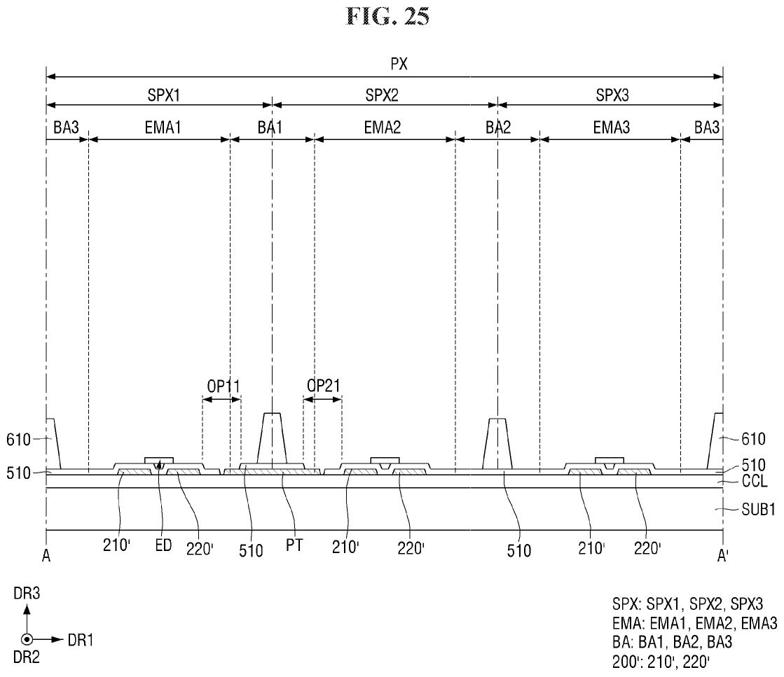

Next, referring to FIGS. 24 and 25, the plurality of light emitting elements ED are disposed on the alignment line 200′ in the emission area EMA of each sub-pixel SPX.

The plurality of light emitting elements ED may be disposed between the first alignment line 210′ and the second alignment line 220′ in the emission area EMA of each sub-pixel SPX. As described above, the light emitting element ED may have a shape extending in one direction, and the plurality of light emitting elements ED may be arranged between the first alignment line 210′ and the second alignment line 220′ such that one ends thereof are disposed on the first alignment line 210′ and the other ends thereof are disposed on the second alignment line 220′.

The process of arranging the plurality of light emitting elements ED may include spraying ink in which the plurality of light emitting elements ED are dispersed to the emission area EMA of each sub-pixel SPX, and aligning the plurality of light emitting elements ED on the alignment line 200′ by applying the alignment signal to the alignment line 200′. For example, the plurality of light emitting elements ED may be sprayed onto the alignment line 200′ disposed in the emission area EMA while being dispersed in the ink. In one or more embodiments, the plurality of light emitting elements ED may be prepared while being dispersed in the ink, and may be sprayed onto the alignment line 200′ by the printing process using an inkjet printing apparatus. The ink sprayed using the inkjet printing apparatus may be mounted on the first insulating layer 510 in the emission area EMA of each sub-pixel SPX surrounded by the first bank 610.

When the ink in which the light emitting elements ED are dispersed is sprayed, the alignment signal may be applied to the alignment line 200′. For example, a first alignment signal may be applied to the first alignment line 210′, and a second alignment signal may be applied to the second alignment line 220′. When the first alignment signal and the second alignment signal are applied to the first alignment line 210′ and the second alignment line 220′, respectively, an electric field may be generated between the first alignment line 210′ and the second alignment line 220′. The light emitting elements ED dispersed in the ink may receive a dielectrophoretic force induced by the electric field generated between the first alignment line 210′ and the second alignment line 220′, and may be aligned such that both ends thereof are positioned on the first alignment line 210′ and the second alignment line 220′ on the first insulating layer 510 while the orientations and positions thereof are being changed by the dielectrophoretic force.

In one or more embodiments, the first alignment line 210′ and the second alignment line 220′ may extend along the second direction DR2 to be disposed across the plurality of sub-pixels SPX arranged in the same column. That is, because the first alignment line 210′ and the second alignment line 220′ are disposed across the plurality of sub-pixels SPX arranged in the same column, the same alignment signal may be applied to the plurality of sub-pixels SPX disposed in the same column. Accordingly, the alignment process of the light emitting elements ED of the plurality of sub-pixels SPX arranged in the same column may be performed by applying the same alignment signal to the first alignment line 210′ and the second alignment line 220′ without applying the alignment signal for aligning the plurality of light emitting elements ED for each sub-pixel SPX.

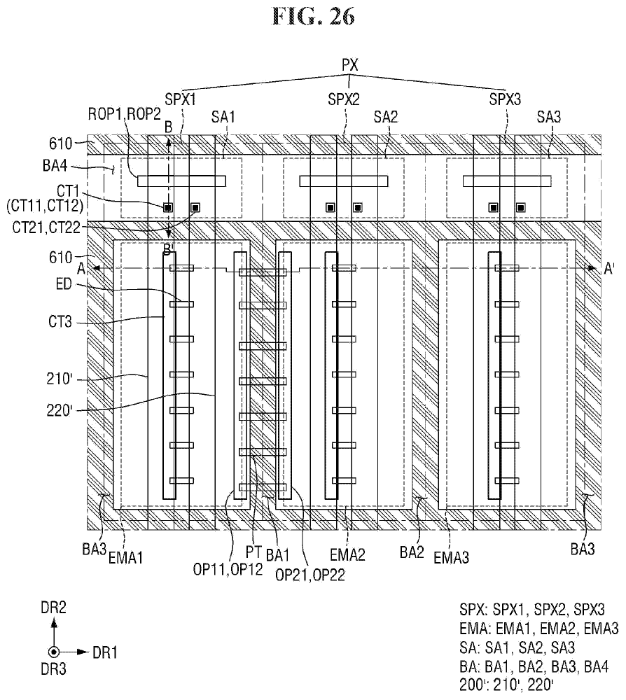

Next, referring to FIGS. 26 to 28, the patterned second insulating layer 520 is formed on the first insulating layer 510 on which the light emitting elements ED are formed and on the light emitting elements ED. The first insulating layer 510 may include a plurality of openings CT12, CT22, ROP2, OP12, and OP22. The plurality of openings CT12, CT22, ROP2, OP12, and OP22 included in the second insulating layer 520 may be formed in one mask process. For example, a second insulating layer material layer is deposited on the entire first insulating layer 510 on which the light emitting elements ED are aligned. Next, a photoresist pattern overlapping the plurality of openings CT11, CT21, ROP1, OP11 and OP21 included in the first insulating layer 510 and exposing a part of the alignment line layer 200′ and both ends of the passage pattern PT may be formed on the second insulating layer material layer, and the second insulating layer material layer may be etched using the photoresist pattern as an etching mask to form the plurality of openings CT12, CT22, ROP2, OP12, and OP22 exposing a part of the alignment line 200′ and both ends of the passage pattern PT as shown in FIGS. 26 to 28.

The first insulating layer 510 may include a plurality of openings OP12, OP22, CT12, CT22, ROP2, and CT3. The plurality of openings OP12, OP22, CT12, CT22, ROP2, and CT3 included in the first insulating layer 510 may include the plurality of openings CT12, CT22, and ROP2 exposing a part of the alignment line 200′, the plurality of openings OP12 and OP22 exposing both ends of the passage pattern PT, and the opening CT3 exposing one end of the light emitting element ED.

For example, the second insulating layer 520 may include the opening OP12 exposing one end of the passage pattern PT in the boundary region between the first emission area EMA1 and the first non-emission area BA1, and overlapping the opening OP11 of the first insulating layer 510. Further, the first insulating layer 510 may include the opening OP22 exposing the other end of the passage pattern PT in the boundary region between the second emission area EMA2 and the first non-emission area BA1, and overlapping the opening OP21 of the first insulating layer 510. The planar shapes of the openings OP12 and OP22 of the second insulating layer 520 exposing both ends of the plurality of passage patterns PT may be substantially the same as those of the openings OP11 and OP21 of the first insulating layer 510. Therefore, the openings OP12 and OP22 of the second insulating layer 520 may extend in the second direction DR2 to expose both ends of the plurality of passage patterns PT. Accordingly, both ends of the plurality of passage patterns PT may be exposed by the openings OP12 and OP22 of the second insulating layer 520. The openings OP12 and OP22 of the second insulating layer 520 may form the first opening OP1 and the second opening OP2 exposing both ends of the passage pattern PT together with the openings OP11 and OP21 of the first insulating layer 510.

The second insulating layer 520 may include the plurality of openings CT12, CT22, and ROP2 partially exposing the alignment line 200′ in the sub-region SA. The second insulating layer 520 may include openings CT12 and CT22 overlapping the openings CT11 and CT21 of the first insulating layer 510 and partially exposing the alignment line 200′. The second insulating layer 520 may further include the opening ROP2 overlapping the opening ROP1 of the first insulating layer 510 and partially exposing the alignment line 200′.

The opening CT12 of the second insulating layer 520 and the opening CT11 of the first insulating layer 510 that are disposed in the sub-region SA and expose a part of the alignment line 200′ may form the first contact portion CT1.

The opening ROP2 of the second insulating layer 520 and the opening ROP1 of the first insulating layer 510 that are disposed in the sub-region SA and expose another part of the alignment line 200′ may form the separation portion ROP.

The second insulating layer 520 may include the opening CT3 exposing one end of the light emitting element ED in the emission area EMA. The second insulating layer 520 may cover the other end of the light emitting element ED and may expose one end of the light emitting element ED in the emission area EMA.

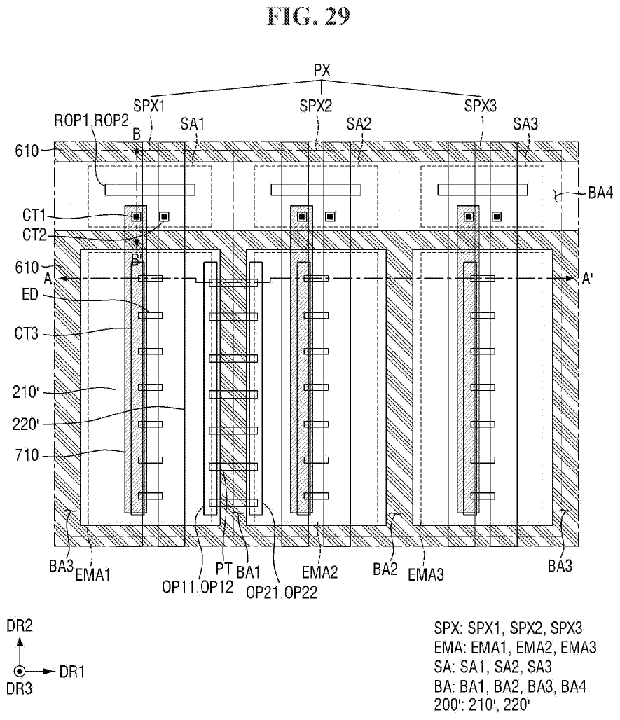

Next, referring to FIGS. 29 to 31, the first contact electrode 710 is formed on the second insulating layer 520. The first contact electrode 710 is formed by depositing a first contact electrode material layer on the entire second insulating layer 520. The first contact electrode material layer may include the same material as the above-described first contact electrode 710. The first contact electrode material layer may cover one end of the light emitting element ED exposed by the opening CT3 of the second insulating layer 520 in the emission area EMA. Further, the first contact electrode material layer may cover a part of the top surface of the first alignment line 210′ exposed by the first contact portion CT1 penetrating the first insulating layer 510 and the second insulating layer 520 in the sub-region SA.

Next, a photoresist pattern is formed by coating a photoresist layer on the first contact electrode material layer and performing exposure and development and, then, the first contact electrode material layer is etched using the photoresist pattern as an etching mask. Thereafter, the photoresist pattern is removed by a strip or ashing process to form the first contact electrode 710 shown in FIGS. 29 to 31.

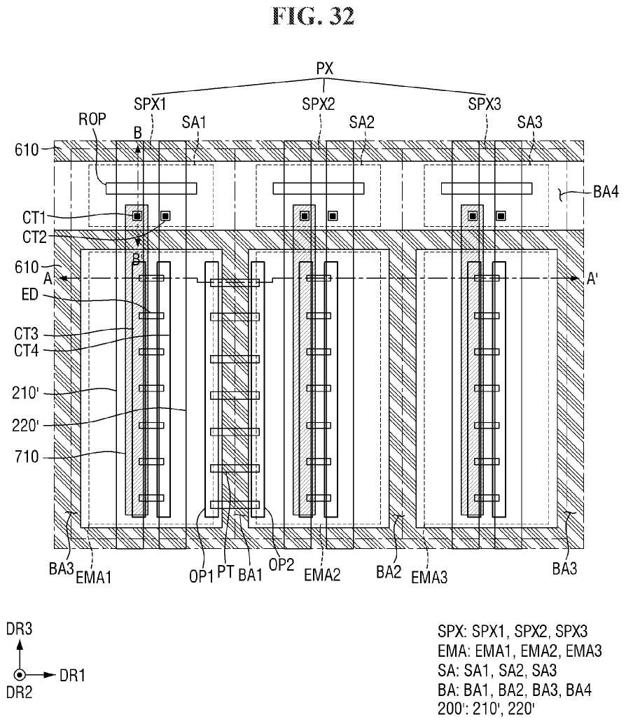

Next, referring to FIGS. 32 to 34, the patterned third insulating layer 530 is formed on the second insulating layer 520 on which the first contact electrode 710 is formed. The third insulating layer 530 may include a plurality of openings. The plurality of openings included in the third insulating layer 530 may be formed in one mask process. For example, a third insulating layer material layer is deposited on the entire second insulating layer 520 on which the first contact electrode 710 is formed. Next, a photoresist pattern overlapping the first opening OP1, the second opening OP2, the second contact portion CT2, and the separation portion ROP and exposing a part of the alignment line layer 200′ and both ends of the passage pattern PT may be formed on the third insulating layer material layer, and the third insulating layer material layer may be etched using the photoresist pattern as an etching mask to form the plurality of openings CT2, ROP, OP1, and OP2 exposing a part of the alignment line 200′ and both ends of the passage pattern PT as shown in FIGS. 32 to 34.

The third insulating layer 530 may include an opening forming the separation portion ROP partially exposing the first alignment line 210′ and the second alignment line 220′ of the alignment line 200′ in the sub-region SA. The third insulating layer 530 may further include the opening forming the second contact portion CT2 partially exposing the second alignment line 220′ in the sub-region SA. The third insulating layer 530 may cover the first contact portion CT1 partially exposing the first alignment line 210′ and the first contact electrode 710 in the sub-region SA.

The third insulating layer 530 may include the opening forming the first opening OP1 exposing one end of the passage pattern PT in the boundary region between the first emission area EMA1 and the first non-emission area BA1. The third insulating layer 530 may include the opening forming the second opening OP2 exposing the other end of the passage pattern PT in the boundary region between the second emission area EMA2 and the first non-emission area BA1.

The third insulating layer 530 may include an opening CT4 exposing the other end of the light emitting element ED in the emission area EMA. In the emission area EMA, the third insulating layer 530 may cover one end of the light emitting element ED together with the second insulating layer 520, and may expose the other end of the light emitting element ED.

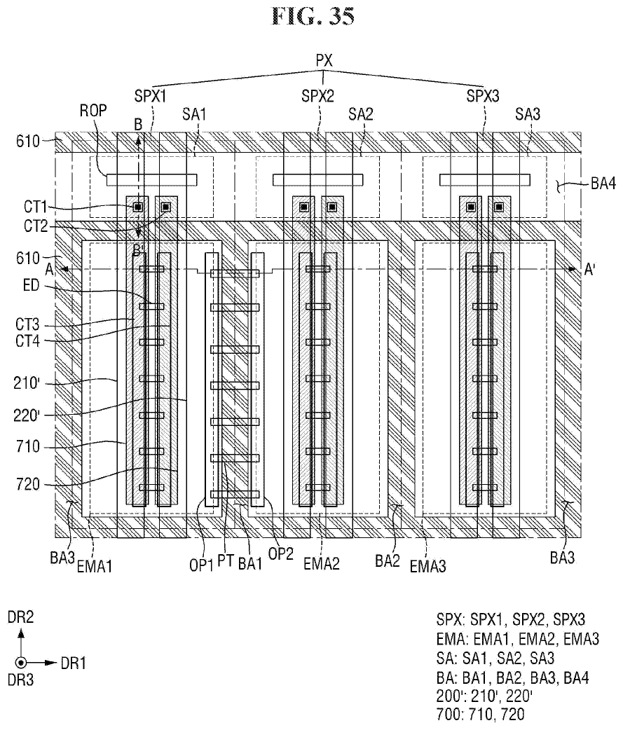

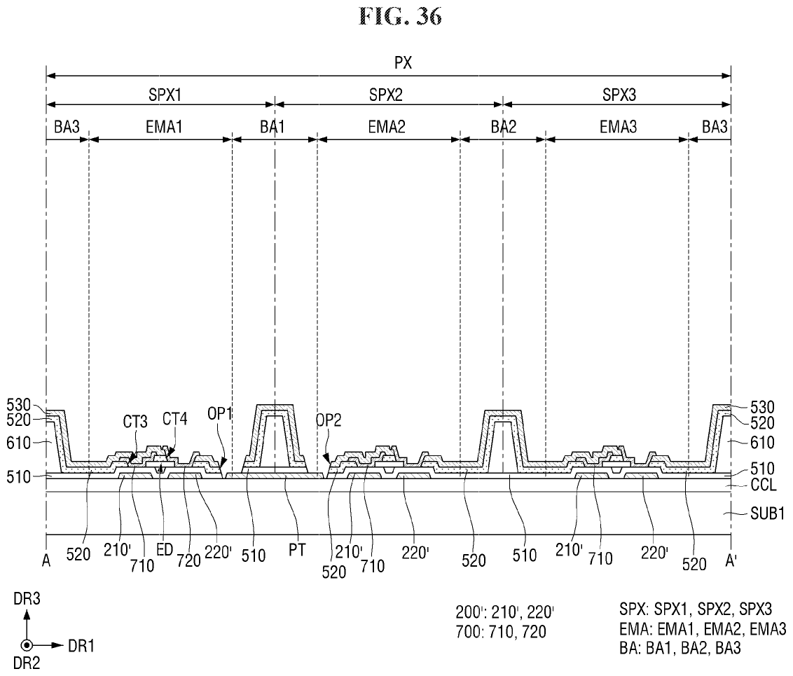

Next, referring to FIGS. 35 and 36, the second contact electrode 720 is formed on the third insulating layer 530. The second contact electrode 720 is formed by depositing a second contact electrode material layer on the entire third insulating layer 530. The second contact electrode material layer may include the same material as the above-described second contact electrode 720. The second contact electrode material layer may cover the other end of the light emitting element ED exposed by the opening CT4 penetrating the third insulating layer 530 and the second insulating layer 520 in the emission area EMA. Further, the second contact electrode material layer may partially cover the top surface of the second alignment line 220′ exposed by the second contact portion CT2 penetrating the first insulating layer 510, the second insulating layer 520, and the third insulating layer 530 in the sub-region SA.

Next, a photoresist pattern is formed by coating a photoresist layer on the second contact electrode material layer and performing exposure and development and, then, the second contact electrode material layer is etched using the photoresist pattern as an etching mask. Thereafter, the photoresist pattern is removed by a strip or ashing process to form the second contact electrode 720 shown in FIGS. 35 and 36.

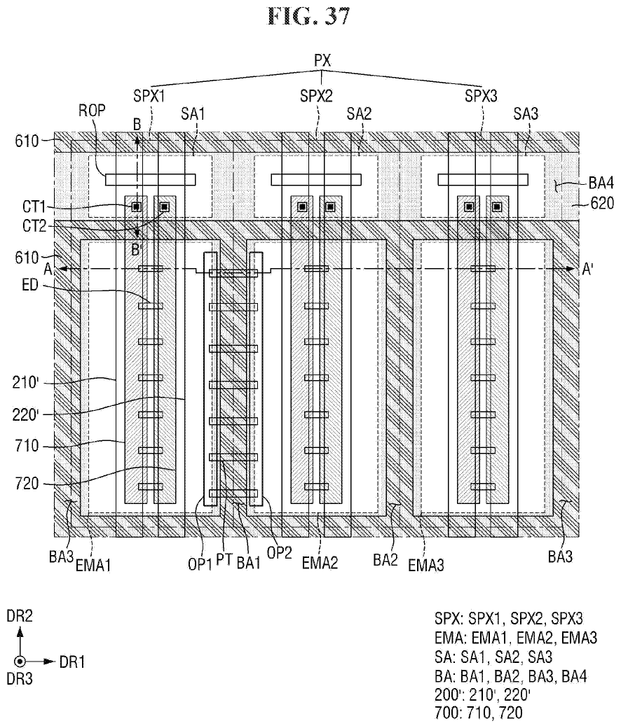

Next, referring to FIGS. 37 to 39, the patterned second bank 620 is formed on the third insulating layer 530 on which the second contact electrode 720 is formed. For example, the second bank 620 may include a photosensitive organic material, but the present disclosure is not limited thereto. The second bank 620 may further include a light blocking material. In one or more embodiments, the second bank 620 may include a negative sensitizer (e.g., a photosensitizer).

The second bank 620 may have liquid repellency. The second bank 620 may include a material having liquid repellency (or a liquid repellent material), although not limited thereto. The second bank 620 may contain any compound having liquid repellency, e.g., a fluorine-based compound, a siloxane-based compound, or the like, but is not limited thereto. Because the second bank 620 has liquid repellency, the second bank 620 may stably locate an ink composition at a desired position by preventing the ink from overflowing to the adjacent sub-pixel SPX in the case of forming the wavelength control layer CWL using the inkjet printing process for spraying an ink containing a material contained in the wavelength control layer CWL during the fabrication process of the display device 1.

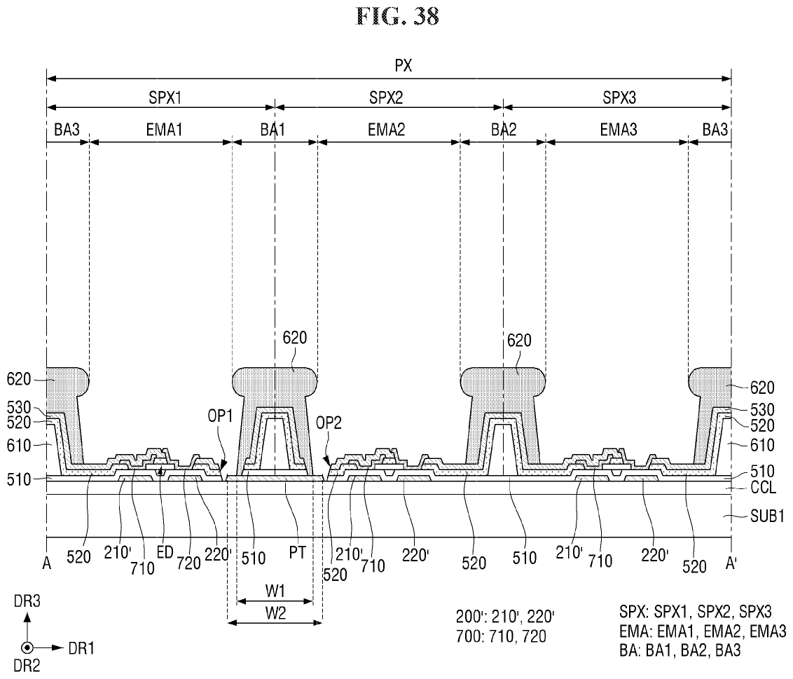

The patterned second bank 620 may be formed by coating the second organic material layer and then performing exposure and development. In one or more embodiments, the second organic material layer may include a negative sensitizer. When the second organic material layer includes a negative sensitizer, a relatively large amount of light is irradiated to the upper portion of the second organic material layer than to the lower portion thereof during the exposure process, so that the lower portion of the second organic material layer is removed relatively more compared to the upper portion thereof during the developing process. Accordingly, as shown in FIG. 38, the second bank 620 in which the width of the upper portion is greater than that of the lower portion may be formed. However, the present disclosure is not limited thereto, and the second organic material layer may include a positive sensitizer.

In one or more embodiments, a width W1 in the first direction DR1 of the bottom surface of the second bank 620 disposed in the first to third non-emission areas BA1, BA2, and BA3 may be smaller than a width W2 in the first direction DR1 of the passage pattern PT. Accordingly, both ends of the passage pattern PT may be exposed by the second bank 620.

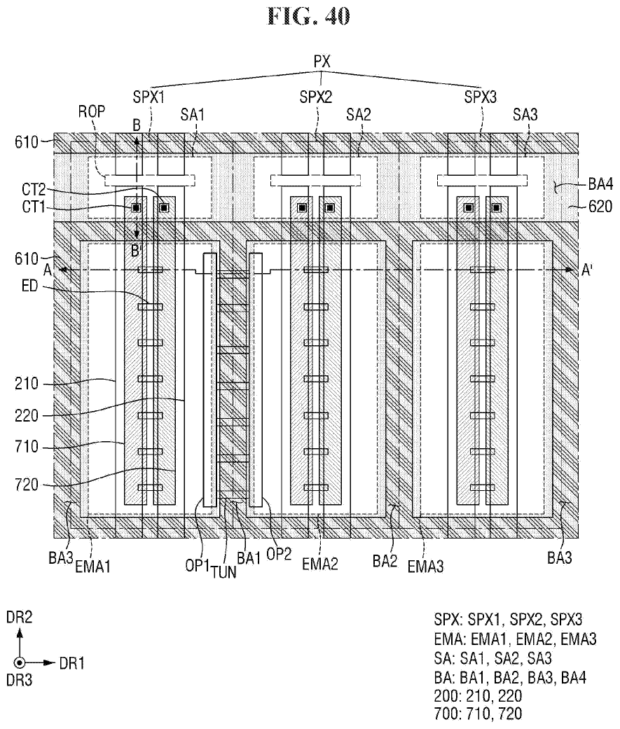

Next, referring to FIGS. 40 to 42, a part of the alignment line 200 and the passage pattern PT exposed by the separation portion ROP are removed.

For example, the first electrode 210 and the second electrode 220 are formed by performing a process of disconnecting the first alignment line 210′ from the second alignment line 220′. The first electrode 210 and the second electrode 220 separated from each other are formed by the process of partially removing the first alignment line 210′ and the second alignment line 220′ exposed by the separation portion ROP penetrating the first to third insulating layers 510, 520, and 530 in the sub-region SA.

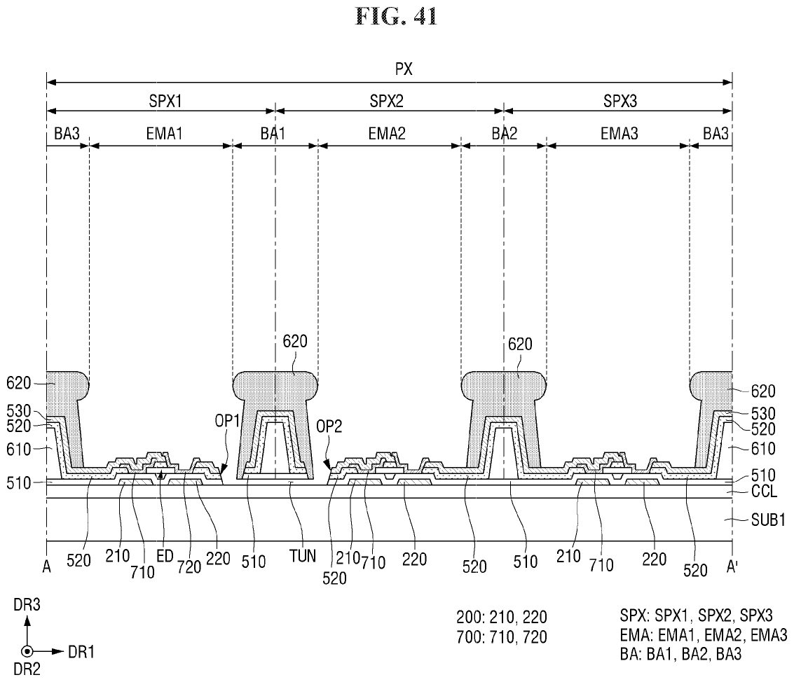

In one or more embodiments, in this process, both ends of the passage pattern PT may be exposed by the first and second openings OP1 and OP2 penetrating the first to third insulating layers 510, 520, and 530 in the boundary between the first non-emission area BA1 and the first emission area EMA1 and the boundary between the first non-emission area BA1 and the second emission area EMA2. Accordingly, the passage pattern PT may also be removed by a material that partially removes the first alignment line 210′ and the second alignment line 220′. Accordingly, as shown in FIG. 41, the passage pattern PT disposed in the first non-emission area BA1 may be removed to form the passage TUN that is the space between the first insulating layer 510 and the circuit element layer CCL disposed in the non-emission area BA1. The passage TUN may spatially connect the first emission area EMA1 to the second emission area EMA2.

The process of disconnecting the first and second alignment lines 210′ and 220′ and the process of removing the passage pattern PT may be concurrently (e.g., simultaneously) performed by the same process without an additional process. Therefore, an additional process for forming the passage TUN is unnecessary, which makes it possible to prevent a decrease in the efficiency of the fabrication process of the display device 1.

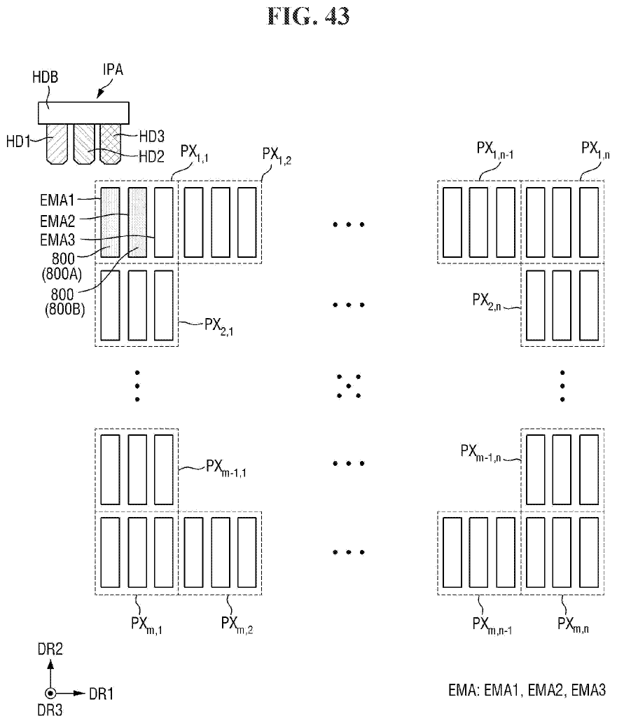

Next, referring to FIGS. 43 to 49, the protection layer 800 is formed in the first and second emission areas EMA1 and EMA2. The process of forming the protection layer 800 may be performed by an inkjet printing method using the inkjet printing apparatus.

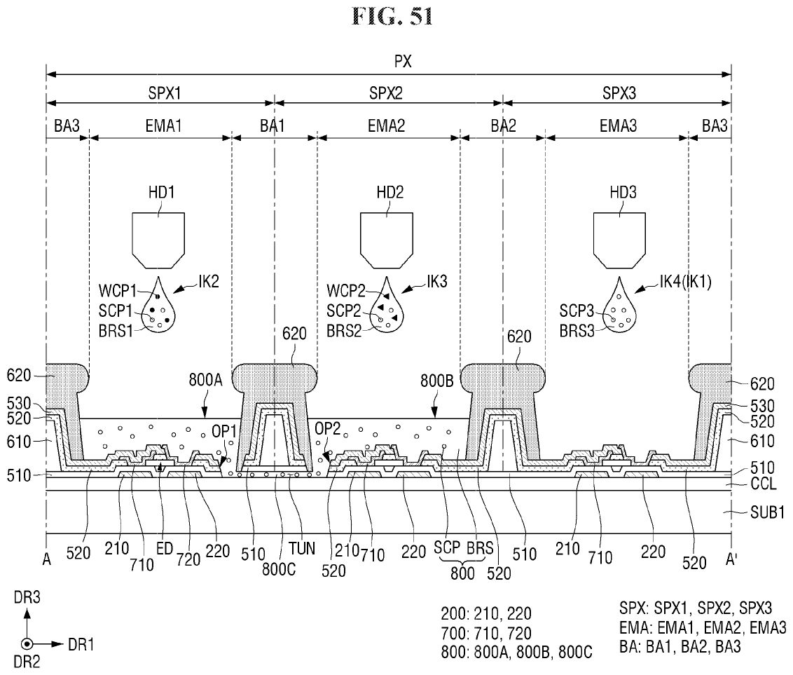

For example, the inkjet printing apparatus may include a print head unit IPA. The print head unit IPA may include a head base HDB and first to third inkjet nozzles HD1, HD2, and HD3 disposed under the head base HDB. The first inkjet nozzle HD1 may be a nozzle for spraying an ink IK2 (see FIG. 51) containing the material contained in the first wavelength conversion pattern WCL1, the second inkjet nozzle HD2 may be a nozzle for spraying an ink IK3 (see FIG. 51) containing the material contained in the second wavelength conversion pattern WCL2, and the third inkjet nozzle HD3 may be a nozzle for spraying an ink IK1 containing the material contained in the protection layer 800. The ink IK1 sprayed by the third inkjet nozzle HD3 protection layer may include substantially the same material as that of the light transmission pattern TPL. Accordingly, the third inkjet nozzle HD3 may be a nozzle for spraying an ink IK4 (see FIG. 51) containing the material contained in the light transmission pattern TPL.

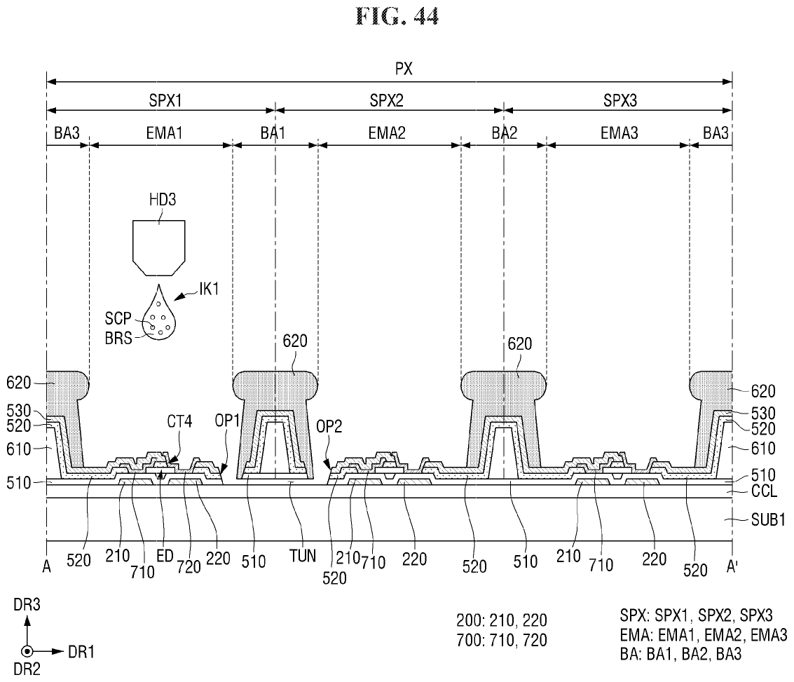

Referring to FIGS. 43 and 44, the third inkjet nozzle HD3 of the print head unit IPA is disposed above the first emission area EMA1 of a pixel PX_{1,1} disposed in 1X1. Next, the first ink IK1 is sprayed to the first emission area EMA1 of the pixel PX_{1,1} disposed in 1X1 using the third inkjet nozzle HD3. The first ink IK1 ejected (e.g., sprayed) from the third inkjet nozzle HD3 may include the same material as that of the protection layer 800. For example, the first ink IK1 ejected (e.g., sprayed) from the third inkjet nozzle HD3 may include a solvent including the same material as that of the base resin BRS and the scatterers SCP dispersed in the solvent.

When the first ink IK1 is sprayed to the first emission area EMA1, the first ink IK1 may flow from the first emission area EMA1 toward the second emission area EMA2 through the passage TUN where the bottom surface of the first insulating layer 510 and the top surface of the circuit element layer CCL face (e.g., oppose) each other while being spaced from each other and the first emission area EMA1 and the second emission area EMA2 are spatially connected. Accordingly, although the first ink IK1 is sprayed only to the first emission area EMA1, the protection layer 800 may also be formed in the second emission area EMA2.

In accordance with the fabrication process of the display device 1 according to the present embodiment, in the process of forming the protection layer 800 in the first emission area EMA1 and the second emission area EMA2 using the third inkjet nozzle HD3, the process of moving the third inkjet nozzle HD3 from the position above the first emission area EMA1 to the position above the second emission area EMA2 and then ejecting the first ink IK1 to the second emission area EMA2 may be omitted. Accordingly, the number of times of ejection of the inkjet printing process may be reduced, so that the fabrication process time of the display device 1 may be shortened. Accordingly, the fabrication process efficiency of the display device 1 may be improved.

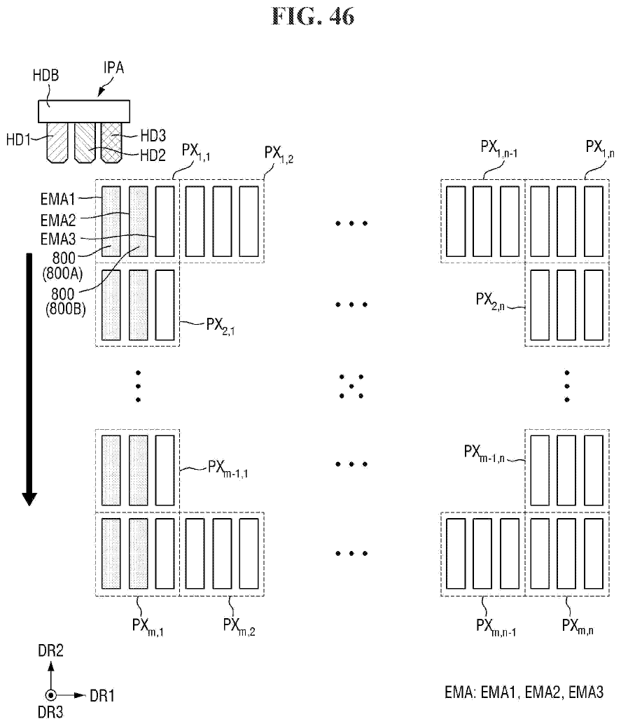

Then, referring to FIG. 46, the print head unit IPA is moved along an opposite direction to the second direction DR2, and the first ink IK1 is sprayed to the first emission areas EMA1 of the plurality of pixels PX_{2,1} to PX_{m,1} arranged in the first column. Accordingly, the protection layer 800 may be formed in each of the first emission area EMA1 and the second emission area EMA2 of the plurality of pixels PX_{2,1} to PX_{m,1} arranged in the first column.

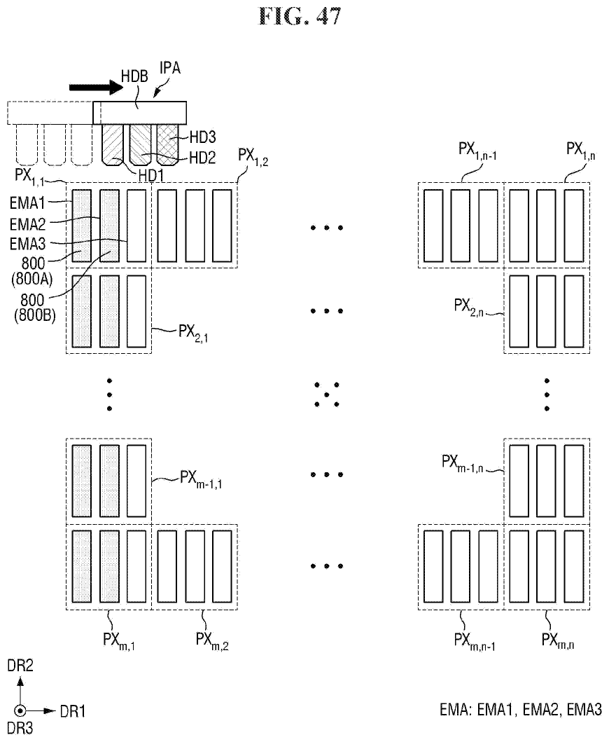

Then, referring to FIG. 47, the print head unit IPA is moved along the first direction DR1 to locate the third inkjet nozzle HD3 of the print head unit IPA to the position above the first emission area EMA1 of the pixel PX_{1,2} disposed in 1X2.

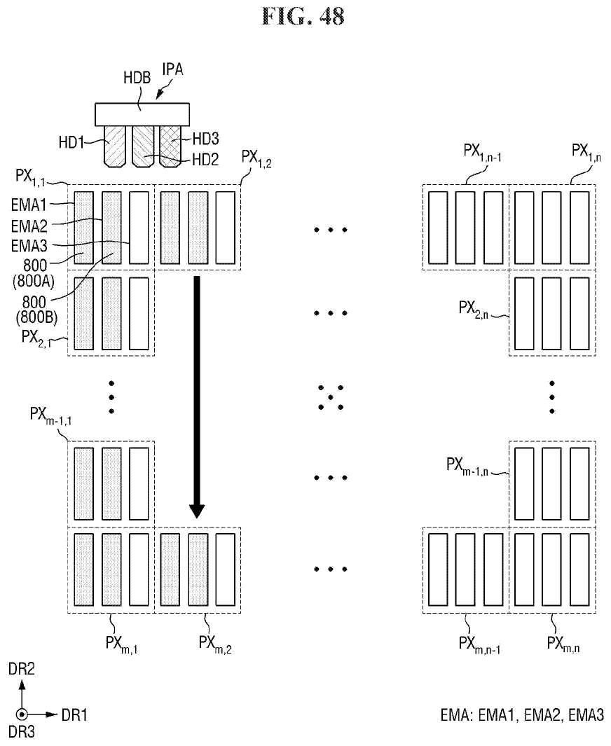

Next, referring to FIG. 48, the print head unit IPA is moved along the opposite direction to the second direction DR2, and the first ink IK1 is sprayed to the first emission areas EMA1 of the plurality of pixels PX_{1,2} to PX_{m,2} arranged in the second column. Accordingly, the protection layer 800 may be formed in each of the first emission area EMA1 and the second emission area EMA2 of the plurality of pixels PX_{1,2} to PX_{m,2} arranged in the second column.

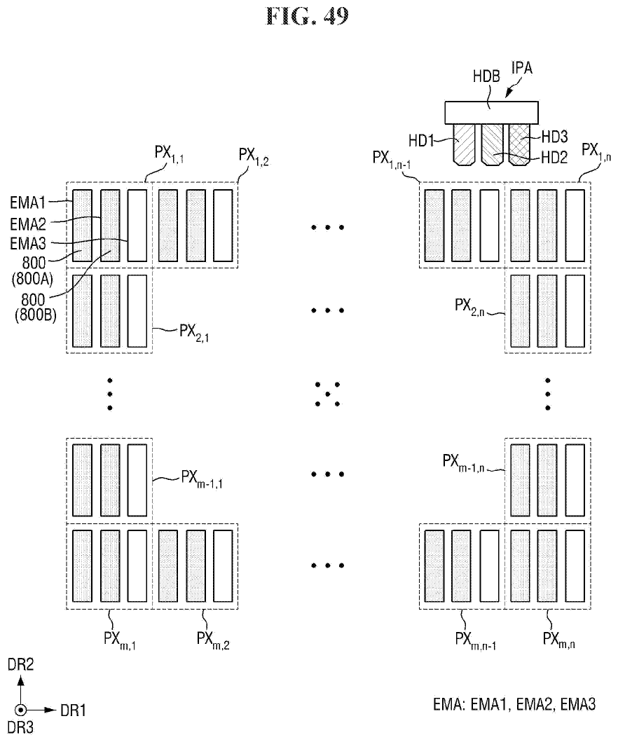

By repeating this process, as shown in FIG. 49, the protection layer 800 may be formed in each of the first emission area EMA1 and the second emission area EMA2 of the plurality of pixels PX_{1,n} to PX_{m,n} arranged in an n^{th} column.

Next, the first ink IK1 sprayed to the first and second emission areas EMA1 and EMA2 is cured to form the protection layer 800. In one or more embodiments, the process of curing the first ink IK1 may be performed using a light irradiation device or the like. For example, the light irradiation device may include a UV lamp or the like.

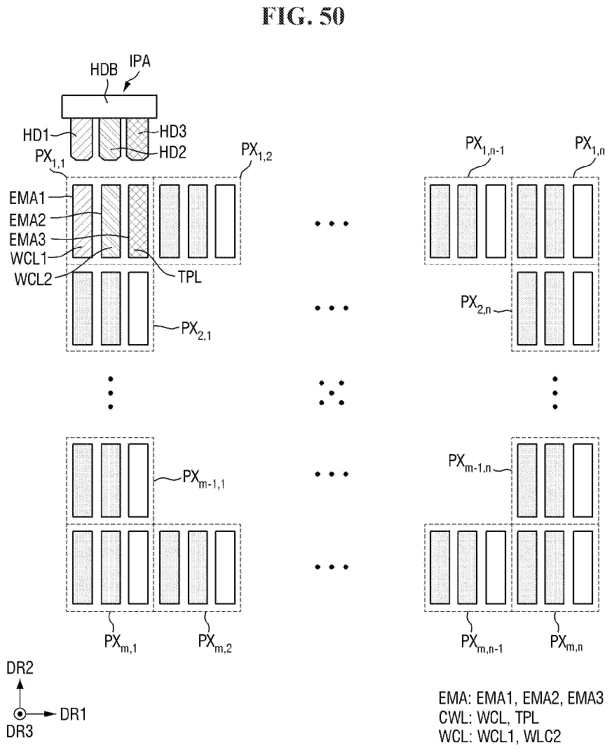

Next, referring to FIGS. 50 to 56, the wavelength control layer CWL is formed in the first to third emission areas EMA1, EMA2, and EMA3. The process of forming the wavelength control layer CWL may be performed by the inkjet printing method using the inkjet printing apparatus. For example, the process of forming the wavelength control layer CWL may be performed using the same inkjet printing apparatus as that used in the process of forming the above-described protection layer 800. Accordingly, the inkjet printing apparatus used in the process of forming the wavelength control layer CWL may include the print head unit IPA including the first to third inkjet nozzles HD1, HD2, and HD3.

First, referring to FIGS. 50 and 51, the print head unit IPA is disposed above the pixel PX_{1,1} disposed in 1X1. For example, the first inkjet nozzle HD1 of the print head unit IPA is disposed to correspond to the position above the first emission area EMA1 of the pixel PX_{1,1} disposed in 1X1, the second inkjet nozzle HD2 thereof is disposed to correspond to the position above the second emission area EMA2 of the pixel PX_{1,1} disposed in 1X1, and the third inkjet nozzle HD3 thereof is disposed to correspond to the position above the third emission area EMA3 of the pixel PX_{1,1} disposed in 1X1.

Next, the second ink IK2, the third ink IK3, and the fourth ink IK4 are sprayed to the first emission area EMA1, the second emission area EMA2, and the third emission area EMA3 of the pixel PX_{1,1} disposed in 1X1 using the first to third inkjet nozzles HD1, HD2, and HD3, respectively.

As described above, the second ink IK2 ejected (e.g., sprayed) from the first inkjet nozzle HD1 may contain the same material as that contained in the first wavelength conversion pattern WCL1. For example, the second ink IK2 may include a solvent containing the same material as the first base resin BRS1, the first scatterers SCP1 dispersed in the solvent, and the first wavelength conversion material WCP1 dispersed in the solvent. The third ink IK3 ejected (e.g., sprayed) from the second inkjet nozzle HD2 may contain the same material as the material contained in the second wavelength conversion pattern WCL2. For example, the third ink IK3 may include a solvent including the same material as the second base resin BRS2, the second scatterers SCP2 dispersed in the solvent, and the second wavelength conversion material WCP2 dispersed in the solvent. The fourth ink IK4 ejected (e.g., sprayed) from the third inkjet nozzle HD3 may contain the same material as the material contained in the light transmission pattern TPL. For example, the fourth ink IK4 may include a solvent including the same material as the third base resin BRS3, and the third scatterers SCP3 dispersed in the solvent. As described above, in one or more embodiments, the fourth ink IK4 may be substantially the same as the first ink IK1.

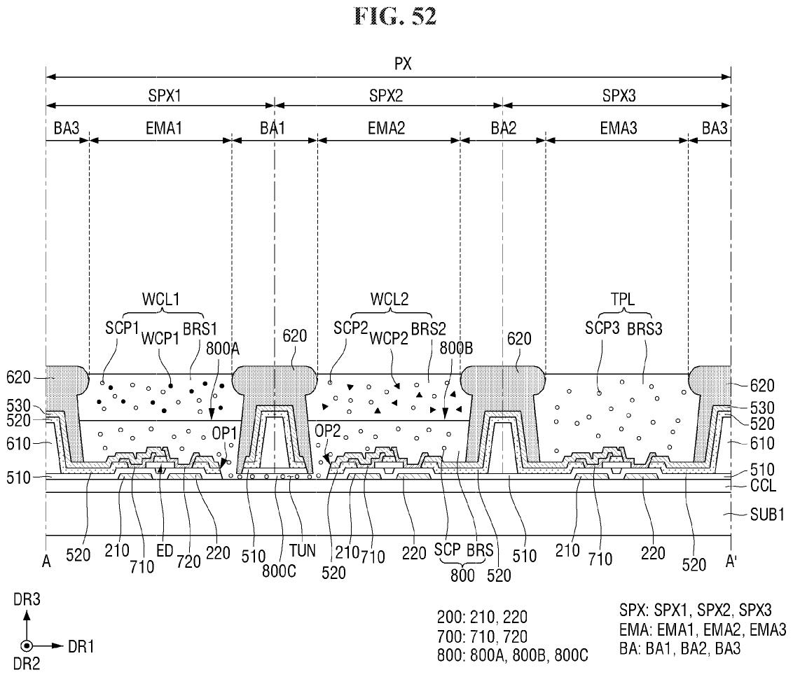

Due to this process, as shown in FIG. 52, the wavelength control layer CWL may be formed in each of the first to third emission areas EMA1, EMA2, and EMA3 exposed by the second bank 620. For example, the first wavelength conversion pattern WLC1 may be formed in the first emission area EMA1, the second wavelength conversion pattern WCL2 may be formed in the second emission area EMA2, and the light transmission pattern TPL may be formed in the third emission area EMA3. The second to fourth inks IK2, IK3, and IK4 ejected to form the first wavelength conversion pattern WLC1, the second wavelength conversion pattern WCL2, and the light transmission pattern TPL may be concurrently (e.g., simultaneously) ejected using the first to third inkjet nozzles HD1, HD2, and HD3 of the print head unit IPA.

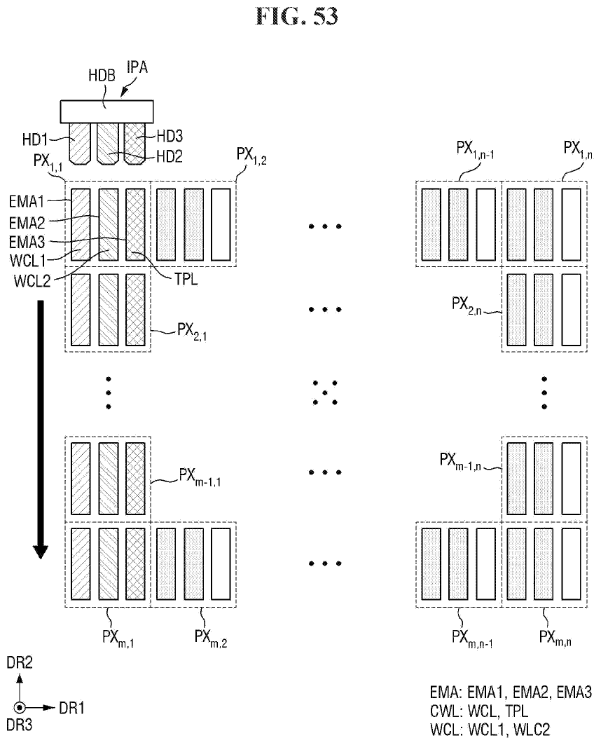

Next, referring to FIG. 53, the print head unit IPA is moved along the opposite direction to the second direction DR2, and the second to fourth inks IK2, IK3, and IK4 are sprayed to the first to third emission areas EMA1, EMA2, and EMA3 of the plurality of pixels PX_{2,1} to PX_{m,1} arranged in the first column, respectively. Accordingly, the wavelength control layers CWL corresponding to the first to third emission areas EMA1, EMA2, and EMA3 of the plurality of pixels PX_{2,1} to PX_{m,1} arranged in the first column may be formed.

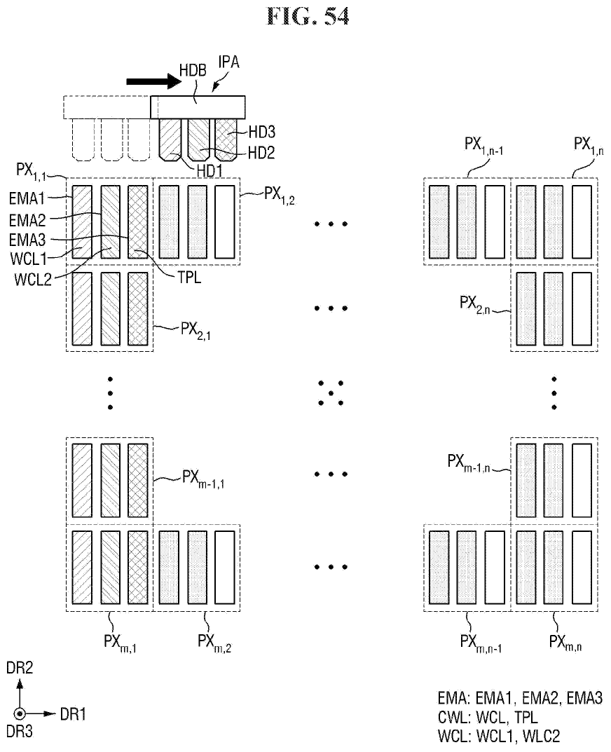

Then, referring to FIG. 54, the print head unit IPA is moved along the first direction DR1, and the first to third inkjet nozzles HD1, HD2, and HD3 of the print head unit IPA are disposed to respectively correspond to the positions above the first to third emission areas EMA1, EMA2, and EMA3 of the pixel PX_{1,2} disposed in 1X2.

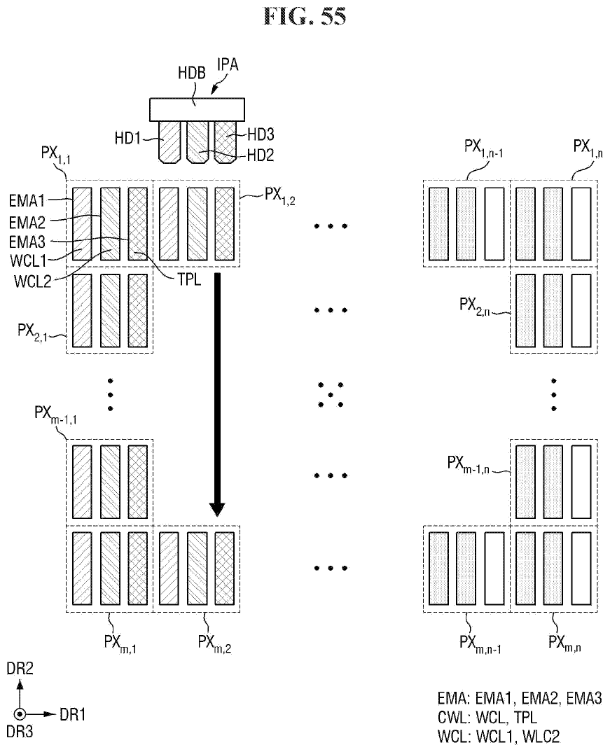

Next, referring to FIG. 55, the print head unit IPA is moved along the opposite direction to the second direction DR2, and the second to fourth inks IK2, IK3, and IK4 are sprayed to the first to third emission areas EMA1, EMA2, and EMA3 of the plurality of pixels PX_{1,2} to PX_{m,2} arranged in the second column. Accordingly, the wavelength control layers CWL corresponding to the first to third emission areas EMA1, EMA2, and EMA3 of the plurality of pixels PX_{1,2} to PX_{m,2} arranged along the second column may be formed.

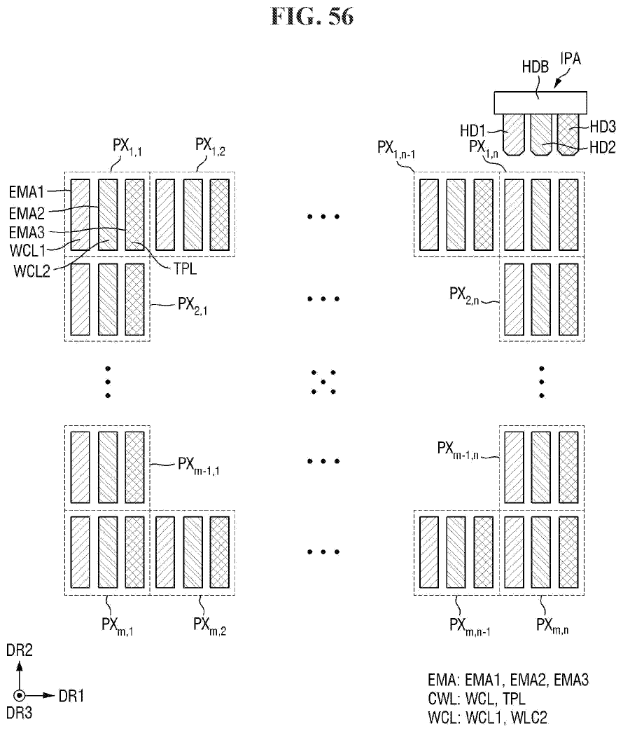

By repeating this process, as shown in FIG. 56, the wavelength control layers CWL corresponding to the first to third emission areas EMA1, EMA2, and EMA3 of the plurality of pixels PX_{1,n} to PX_{m,n} arranged in the n^{th} column may be formed.

Next, the second to fourth inks IK2, IK3, and IK4 sprayed to the first to third emission areas EMA1, EMA2, and EMA3 are cured to form the wavelength control layer CWL. In one or more embodiments, the process of curing the second to fourth inks IK2, IK3, and IK4 may be performed using a light irradiation device or the like. For example, the light irradiation device may include a UV lamp or the like.

Hereinafter, other embodiments will be described. In the following embodiments, a description of the same components as those of the above-described embodiment will be omitted or simplified, and differences will be mainly described.

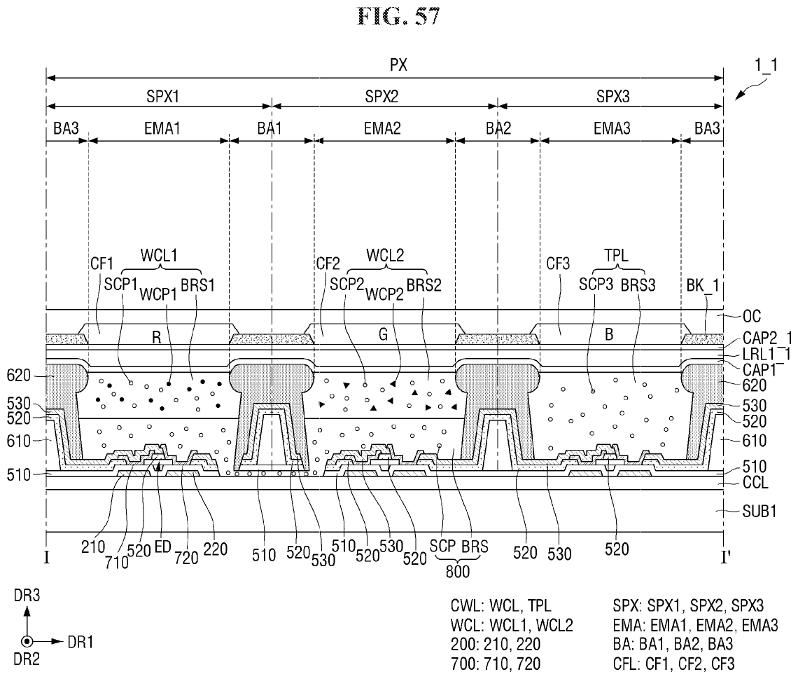

FIG. 57 is a cross-sectional view illustrating an example of a display device taken along the line I-I′ of FIGS. 4 and 5.

Referring to FIG. 57, the color filter layer CFL is directly disposed on a second capping layer CAP2_1 disposed on a first low refractive layer LRL1_1, so that a display device 1_1 may not require an additional substrate for the color filter layer CFL. Accordingly, the thickness of the display device 1_1 may be relatively reduced.

For example, the first low refractive layer LRL1_1 is disposed on the first capping layer CAP1, and may have a substantially flat surface. The second capping layer CAP2_1 may be disposed on the first low refractive layer LRL1_1. A light blocking member BK_1 may be disposed on the second capping layer CAP2_1. The light blocking member BK_1 may be disposed in the non-emission area BA on the second capping layer CAP2_1.

The color filter layer CFL may be disposed on the second capping layer CAP2_1 exposed by the light blocking member BK_1.

A passivation layer OC may be disposed on the color filter layer CFL. The passivation layer OC may serve to prevent oxygen or moisture from permeating into the wavelength control layer CWL and the light emitting element layer disposed thereunder. To this end, the passivation layer OC may include at least one inorganic layer. The passivation layer OC may be disposed to cover the lower color filter layer CFL, the wavelength control layer CWL, the light emitting element layer, and the circuit element layer CCL that are disposed thereunder.

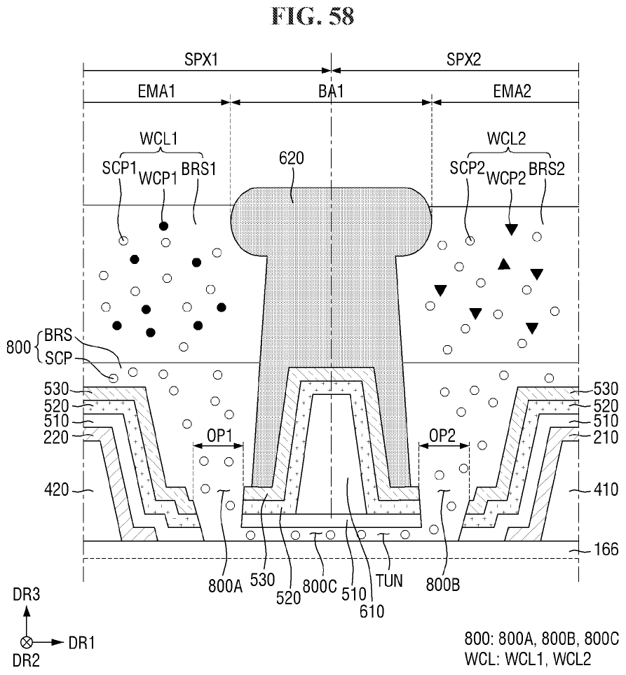

FIG. 58 is an enlarged cross-sectional view illustrating another example of the first emission area, the second emission area, and the first non-emission area.

Referring to FIG. 58, the second bank 620 according to the present embodiment may be disposed on the top surface of the third insulating layer 530. The bottom surface of the second bank 620 may not overlap the first opening OP1 and the second opening OP2 in the third direction DR3. Accordingly, the second bank 620 may be aligned more inward than the sidewalls of the first to third insulating layers 510, 520, and 530 forming the first opening OP1 and the second opening OP2. Accordingly, the second bank 620 may expose the sidewalls of the first to third insulating layers 510, 520, and 530 forming the first opening OP1 and the second opening OP2 without covering them.

However, the aspects of the present disclosure are not restricted to those set forth herein. The above and other aspects of the present disclosure will become more apparent to one of daily skill in the art to which the present disclosure pertains by referencing the claims, with equivalents thereof to be included therein.

What is claimed is:

1. A display device comprising a pixel comprising a first sub-pixel configured to emit a first color light and a second sub-pixel configured to emit a second color light different from the first color light, the display device comprising:
a substrate comprising an emission area and a non-emission area surrounding the emission area;
a bank in the non-emission area on the substrate;
a first electrode and a second electrode in each of the first sub-pixel and the second sub-pixel on the substrate;
a light emitting element between the first electrode and the second electrode in the emission area;
a wavelength conversion layer on the light emitting element in the emission area; and
a protection layer on the substrate,
wherein the protection layer comprises:
a first area in the emission area and located between the wavelength conversion layer and the light emitting element; and
a second area in the non-emission area and located between the substrate and the bank.

2. The display device of claim 1, wherein the emission area comprises a first emission area of the first sub-pixel and a second emission area of the second sub-pixel,
wherein the non-emission area comprises a first non-emission area between the first emission area and the second emission area,
wherein the first area of the protection layer comprises a first portion in the first emission area and a second portion in the second emission area, and
wherein the second area of the protection layer is located in the first non-emission area.

3. The display device of claim 2, wherein the second area of the protection layer is located between the first portion of the protection layer and the second portion of the protection layer, and
wherein the second area of the protection layer connects the first portion of the protection layer to the second portion of the protection layer.

4. The display device of claim 2, wherein the wavelength conversion layer comprises a first wavelength conversion pattern in the first emission area and a second wavelength conversion pattern in the second emission area.

5. The display device of claim 2, wherein the pixel further comprises a third sub-pixel configured to emit a third color light that is different from the first color light and the second color light,
wherein the emission area further comprises a third emission area of the third sub-pixel,
wherein the non-emission area further comprises a second non-emission area between the third emission area and the second emission area, and
wherein the protection layer is not located in the second non-emission area.

6. The display device of claim 5, further comprising a light transmission pattern in the third emission area,
wherein the light transmission pattern comprises a same material as that of the protection layer.

7. The display device of claim 1, wherein the first area of the protection layer and the second area of the protection layer are integrated.

8. The display device of claim 1, wherein the protection layer comprises a base resin and scatterers dispersed in the base resin, and
wherein the scatterer has a refractive index different from that of the base resin.

9. A display device comprising:
a substrate comprising an emission area and a non-emission area, the emission area comprising a first emission area and a second emission area, and the non-emission area comprising a first non-emission area between the first emission area and the second emission area;
a first electrode and a second electrode located in each of the first emission area and the second emission area and spaced from each other on the substrate;
a plurality of light emitting elements in each of the first emission area and the second emission area and located between the first electrode and the second electrode;
a bank in the non-emission area and comprising an opening exposing each of the first emission area and the second emission area;
a first wavelength conversion pattern on the light emitting element in the first emission area;
a second wavelength conversion pattern on the light emitting element in the second emission area;
a first protection layer between the light emitting element and the first wavelength conversion pattern in the first emission area;
a second protection layer between the light emitting element and the second wavelength conversion pattern in the second emission area; and
a third protection layer spatially connecting the first emission area to the second emission area and located in a passage located in the first non-emission area.

10. The display device of claim 9, wherein the first protection layer, the second protection layer, and the third protection layer comprise a same material.

11. The display device of claim 10, wherein the first protection layer, the second protection layer, and the third protection layer are integrated.

12. The display device of claim 10, wherein each of the first protection layer, the second protection layer, and the third protection layer comprises a base resin and scatterers dispersed in the base resin, and
wherein the scatterer has a refractive index different from that of the base resin.

13. The display device of claim 9, wherein the third protection layer connects the first protection layer to the second protection layer.

14. The display device of claim 9, wherein the passage comprises a plurality of passages in the first non-emission area.

15. The display device of claim 9, wherein the passage is a separation space between the substrate and the bank.

16. The display device of claim 9, wherein the third protection layer overlaps a bottom surface of the bank, and
wherein the first protection layer and the second protection layer do not overlap the bottom surface of the bank.

17. A method of fabricating a display device comprising a first sub-pixel configured to emit a first color light and a second sub-pixel configured to emit a second color light, the method comprising:
preparing a substrate comprising an emission area and a non-emission area, the emission area comprising a first emission area of the first sub-pixel and a second emission area of the second sub-pixel, and the non-emission area surrounding the emission area and comprising a first non-emission area between the first emission area and the second emission area;
forming a first pattern in the first non-emission area;
forming a bank in the non-emission area; and
removing the first pattern,
wherein the bank in the first non-emission area exposes both ends of the first pattern.

18. The method of claim 17, wherein in the removing of the first pattern, a passage that is a separation space between the substrate and the bank is formed.

19. The method of claim 18, wherein the passage spatially connects the first emission area to the second emission area.

20. The method of claim 19, further comprising forming a protection layer in each of the first emission area and the second emission area,
wherein the forming of the protection layer in each of the first emission area and the second emission area comprises spraying an ink onto the first emission area.

21. The method of claim 20, wherein the ink sprayed onto the first emission area flows to the second emission area through the passage.
